(19) United States
(12) Patent Application Publication
(10) Pub. No.: US 2021/0164345 A1
(43) Pub. Date: Jun. 3, 2021

(54) A Flow Simulation and Transient Well Analysis Method Based on Generalized Tube Flow and Percolation Coupling

(71) Applicant: Xi'an Huaxian Petroleum Technology Co., Ltd, Xi'an City, Shaanxi Province (CN)

(72) Inventors: Jiaen Lin, Xi'an City, Shaanxi Province (CN); Hui He, Xi'an City, Shaanxi Province (CN); Zhangying Han, Xi'an City, Shaanxi Province (CN)

(21) Appl. No.: 17/047,386

(22) PCT Filed: Apr. 30, 2020
(86) PCT No.: PCT/CN2020/088309

§ 371 Date: Oct. 13, 2020

(30) Foreign Application Priority Data
May 6, 2019 (CN) 201910370524.2

(51) Int. Cl. E21B 47/12; E21B 47/26

(52) U.S. Cl. CPC E21B 47/138; E21B 47/26

(57) ABSTRACT

This invention discloses a multi-phase flow simulation analysis method based on generalized mobility, which comprises the following steps: S1: The generalized mobility describes fluid flow laws in different subset of study area by using the generalized mobility models with the same form; S2: On the basis of generalized mobility, the multi-component multi-phase flow simulation equations are established. Through solving the above mentioned multi-component multi-phase flow simulation equations, the pressure, temperature, saturation, and mole percentage of each component and each phase of multicomponent multiphase flow fluids in study area are obtained; S3: The corresponding application software are formed by using the established multi-component multi-phase flow simulation and analysis equations. The invention plays an important role in solving the single and multi-well flow simulation of complex multicomponent multiphase flow reservoirs, multi-well interference analysis, deliverability analysis, transient pressure analysis, transient rate analysis, transient temperature analysis, well test design, and permanent downhole monitoring data analysis.

### TECHNICAL FIELD OF THE INVENTION

This invention involves various fluid flow simulation and fluid injection and production engineering fields and the like of oil, gas, water, carbon dioxide, chemical agents, microbial agents, water vapors, blood, etc, which is specific to a flow simulation and transient well analysis methods based on generalized tube flow and percolation coupling.

### BACKGROUND OF THE INVENTION

The flow of underground fluids in continuous porous media is called percolation flow, while the free flow of fluids in wellbore, pipes, large fractures, large holes, cavities, caves, fracture caves, karst caves, caverns, channels and so on is called tube flow. In the process of fluid flowing from porous medium area into or out of tube area, the fluid flow laws change from percolation flow to tube flow or from tube flow to percolation flow. The problem of this kind of percolation and tube flow existing at the same time is called tube flow-percolation coupling. It is obvious that the tube flow-percolation coupling is common in the industry of oil and gas exploration and production, groundwater exploitation, underground gas storage, geothermal exploitation.

The Darcy's Law is widely used in the percolation theory. Darcy's law was created by French engineer Henry Darcy in 1856 through his experiments. It becomes the basic law of percolation mechanics because of its advantages of simple proportional linear function, clear physical concept, and easy solving solutions. It is widely used in underground hydraulics and underground oil and gas percolation mechanics. At present, most of the theoretical models of continuous media in oil and gas reservoirs are based on Darcy's law. In addition to Darcy's percolation law, the Hagen-Poisenille laminar-pipe flow formula (1838) is also a linear flow law. However, with the deep practical study, it is found that Darcy percolation law is limited in a certain range of application. The percolation law will become nonlinear beyond the range. The motion equations (or formulas) that are commonly used for describing the nonlinear flow include Irmay (1968)'s low-speed non-Darcy formula, Swartzendruber (1962)'s low-speed non-Darcy formula. Yanzhang Huang (1997)'s low-speed non-Darcy formula; Forchheimer (1901)'s high-speed non-Darcy formula. Barree-Conway (2004)'s high-speed non-Darcy formula; Dexuan Dai (,2019)'s power law non-Newton formula, Yifeng Teng (2016)'s Bingham fluid formula; Jiali Ge (1982)'s stress sensitive index formula; Darcy-Weisbach (1845)'s formula; Navier-Stokes equation for free flow in cavities (Navier, 1827; Stokes, 1845), Stokes-Brinkman equation (Brinkman, 1949), Brinkman-Farchheimer equation (Demin Liu, 2017).

On the basis of the actual situations, the above 2 linear and 12 commonly used nonlinear flow laws can be used independently (that is, the whole reservoir follows a single flow law) or they can also be used in combination (different flow laws are applied in different regions or at different scales in the whole reservoirs). The independent application situation is relatively simple, such as using the Darcy percolation model to characterize the entire homogeneous sandstone reservoirs. The homogeneous heavy oil reservoirs can be characterized by power law model. The homogeneous low permeability reservoirs can be characterized by low-speed non-Darcy models. The combined use of above flow laws is relatively complex. For example, three composite distribution areas of polymer, water and oil are formed around an injection well in the reservoir of water drive before polymer drive. The flow laws of the polymer region are characterized by the non-Newtonian fluid models, while the flow laws of the water and oil regions are characterized by the Darcy percolation model, which is a percolation-percolation composite flow between different regions. In the process of oil and gas well production, it is a typical tube flow-percolation coupling flow between formation and wellbore. The spatial structures of naturally fracture-cavern reservoirs with nonhomogeneous vugs and fractures are complex, the medium space scale span is large and the heterogeneity is serious. The fluid flow laws in this kind of oil and gas reservoir are very complicated. It includes both multi-porosity medium percolation and free flow of large holes. The flow of fluids in fracture-caves reservoirs is a complex tube flow (free flow)-percolation coupling.

Compared with the percolation-percolation composite flow, the problems of tube flow (free flow)-percolation coupling are much more complicated. Up to now, five kinds of approaches have been proposed for the theoretical study of “tube flow (free flow)-percolation coupling models”.

The first category is dual, triple and multi-porosity models based on Darcy's law, which are mainly used for the reservoirs with relatively uniform distribution and relatively small scales of porous media. In the past 50 years, the industry has continuously published such achievements, and has published the large number of such papers. Representative technical achievements: (1) dual porosity media model with pseudo-steady cross flow created by Warren and Root (1963), which was considered that the fractured reservoir is composed of two groups of parallel continuous systems of fracture and matrix. There are two kinds of pressures of fracture fluid and matrix fluid at every point in the space. In the two flow fields, they meet Darcy's law and ignore the influence of gravity. The two systems are connected by transfering flow function. (2) A model of unsteady inter porosity flow in dual porous media is established by Jia Yinglan (2013), which divided carbonate reservoir into matrix system and vug system. The vug in the vug system is assumed to be spherical and evenly distributed in the matrix system. The matrix system was connected by the wellbore, and the fluid in the matrix can flow directly into the wellbore. The fluid in the spherical karst vug can flow into the wellbore only with the aid of the matrix. (3) Triple porosity model created by Ciqun Liu (1981), Wu Yushu and Jiali Ge (1983) and Yushu Wu et al (2007) through dividing the types of media into three types: fracture, vug and matrix. (4) Multi-medium model with high speed non Darcy seepage created by Wenguang Feng and Jiali Ge (1985). (5) The dual permeability model of triple porous media constructed by Chang Xuejun (2004), Camacho-V et al. (2005). Gomez (2014) et al., which not only considers the cross flow between the two media, but also considers that both the vugs and natural fractures are connected with the wellbore, and the fluids in the vugs and natural fractures can flow directly into the wellbore, Compared with the triple porosity medium single permeability model constructed by other people above, only the natural fractures are connected with the wellbore, and the fluid in the natural fractures can flow directly into the wellbore, while the fluid in the matrices and the vugs can flow into the wellbore only with the help of the natural fractures, and there is cross flow between the matrices and the vugs, the matrices and the natural fractures, as well as between the vugs and the natural fractures.

The second category is continuous-discrete medium composite models established by combining both the permeable flow regions that possess the permeable characteristics and the tube flow regions that possess free flow as the composite regions (blocks) that conforms to the Darcy percolation flow. Its core idea is to treat the tube flow (free flow) region as a permeable area with high permeability and large porosity. Representative technical achievements: (1) Fuxiang Zhang et al. (2009) and yizhao Wan et al. (2015) used irregular regions with high permeability, high porosity (blocks) to describe fractures or caverns with different shapes and large scales, in which the fluid flow in fractures or caverns still belongs to the domain of percolation. (2) Fangfang Chen et al. (2015) established a new numerical well test analysis model with wells drilled outside the holes, in which the flow of caverns and other regions of the reservoirs is all percolation with satisfying Darcy's law, (3) Kuchuk and Biryukov (2012), Zeng and Zhao (2012) studied regular (or irregular) fracture models with discrete (or continuous) media in heterogeneous reservoirs, in which the matrix blocks are considered as Darcy percolation, whereas fractures are constructed as boundary conditions using the idea of “source function”. Models of the second category is relatively simple, which can better reflect the geological dynamic features of fractures or caves in reservoirs, and have good consistency with the actual production condition.

The third category is the discrete fracture-cave models with combinations of different fractures and caves established through combing the isopotential body models of tube flow (free flow) based on material balance and the percolation channel models of connecting isopotential body based on Darcy percolationt. Representative technical results: (1) For large-scale fractured vuggy reservoirs, Xiaolong Peng et al. (2008), Lijun Zhang et al. (2010), Baohua Chang et al. (2011), and Baojiang Duan et al. (2012) established a fractured vuggy models of psedo-steady flow between karst vuggy and karst vuggy through fractures, in which it is considered that the pressure change propagates rapidly, and the shape of fracture vuggy has no effect on the pressure change. (2) Yu Xiong et al. (2018) considered the fluid flow in the fractures as unsteady flow on the basis of the previous work, and constructed the corresponding fracture cavern model of the well drilled in large scale fractures. (3) Yonghui Wu et al. (2018) also divided the fracture cavern reservoirs into rock block systems (including matrix, micro fractures, and micro caves), fractures, karst cave systems. Fractures and caverns are embedded in the rock block system and are interconnected. The fluid flows in the rock block system is characterized by a triple porosity model. The fluid flows in the fracture system is Darcy percolation, which is characterized by Darcy percolation model. The fluid flow in the caverns is pseudo-steady flow, which is characterized by the isopotential body model. The models of the third category are easy to be constructed and solved, and the calculation speed of the model is fast, and the volume of the fractures and caverns can be calculated. (4) Wei Pang et al. (2019) based on the energy conservation equation (Bernoulli equation) of fluid flow in the wellbore and karst cave, gave the relationship between the bottom hole pressure and karst cave pressure, and on this basis, constructed the well test interpretation model with a well drilled in a large karst cave. However, in the process of simplifying the energy conservation equation. Wei Pang et al. (2019) ignored the flow velocity of the fluid in the cave, so the cave is essentially an isopotential body. This kind of isopotential model is easy to construct and solve. At the same time, the calculation speed of the model is not only fast, but also can calculate the parameters such as the volume of the fractured caves.

The fourth category is the Darcy-Navier-Stokes coupling model of tube flow (free flow)-percolation established based on Darcy percolation and free flow. Representative technical achievements: (1) Aiming at carbonate fracture and cavern reservoirs, Layton et al. (2003). Mu et al. (2007), Xueli Liu et al. (2007), Xiaolong Peng et al. (2007), Jun Yao et al. (2010), Yajun Li et al. (2011), Na Zhang et al. (2015), Akanni et al. (2017) treat the fluid flow in large-scale fractures and caverns as free flow. Based on the Beavers-Joseph boundary conditions, the fluid flow in fractures and matrix is described by using the Navier-Stokes equation as flow law. (2) Chaoqin Huang et al. (2010) established a macroscopic flow mathematical model of discrete fracture and cave network based on the Brinkam equation, which is the empirical equation proposed by Brinkman considering the terms of fluid viscous shear stress of Navier-Stokes equations on the basis of the Darcy formula in 1974. (3) Popov et al. (2009) proposed to use Stokes Brinkman equation to describe the flow in the fracture cavern media based on the fact, i.e. the caverns are often filled with different degrees. (4) Based on the idea and method of discrete fracture model (Baca, 1984), Dongyan et al. (2013) constructed the multi-stage fracturing horizontal well coupling flow model, the main idea of which is to use Darcy's law to describe the flow law of the fluid in the reservoir and fractures, and Hagen Poiscuille's law to describe the flow law of the fluid in the horizontal well bores. The model of the fourth category is currently the most accurate model describing the tube flow (free flow)-percolation coupling and is able to be used for simulation calculations of various complex fluid flow laws.

The fifth category is based on the Darcy-Weisbach (1845) formula. The corresponding equivalent permeability or equivalent percolation coefficient or converted percolation coefficient are defined by changing the formula into the form of “Darcy's law” to achieve the unification of percolation, laminar tube flow and turbulent tube flow, and then realize the flow simulation of tube flow-percolation coupling. Collins et al. (1991) and Shuhong Vu et al. (1999) built up the equivalent permeability model for laminar flow, turbulent flow and transition flow in horizontal wellbore, which simplified and reduced the coupling complexity between formation percolation and horizontal wellbore tube flow. In the field of groundwater exploitation, in order to overcome the difficult problem of coupling flow between different tube flows and formation water percolation in a wellbore-formation system, Chongxi Chen (1994) proposed the concept of converted (laminar) percolation coefficient for turbulent flow in wellbore (with 4 flow zones) for the first time. At the same time, the expressions of converted (laminar) percolation coefficients of four turbulent flow zones are given, which transformed the tube flow law into a linear law and solved the difficult problem in tube flow-percolation coupling. Based on the concept of converted (laminar flow) percolation coefficient, Chongxi Chen (1995) developed the groundwater flow model of karst pipe-fracture-pore triple porous media. Yanlin Zhao (2014) also established the nonlinear percolation-tube flow coupling model for water inrush in pressure-bearing karst caves based on the converted percolation coefficient. The results of Chongxi Chen (1994, 1995) and Yanlin Zhao et al. (2014) so far are the unique tube flow-percolation coupling model applied to the reservoirs on the basis of equivalent percolation coefficient. It should be noticed that the above concept of “equivalent permeability” is relative to the pressure gradient and mainly used in the field of oil and gas extraction engineering. The concepts of “equivalent percolation coefficient” and “converted percolation coefficient” have the exact same physical meaning, except that the names are different. These two concepts are relative to the hydraulic gradient and mainly used in the field of hydraulic geological engineering. The model of the fifth category can use a unified flow law to represent the flow states in different zones of percolation, laminar flow and turbulence flow, which makes the construction and solution of the model equations relatively simple.

The first category of models is simple to construct and solve, but the main problem is that the model is not suitable when there are large-scale cavities in the reservoir and the distribution of different media in the reservoir is not uniform. The modeling process of the second category of models is complex and costly, which is not conducive to the widespread application. The third category of models cannot be used to determine the geometric size of the karst caves, which is the poor adaptability to the long-strip or strip-type flow system, so that the flow capacity of the large-scale karst caverns cannot be obtained. The fourth category of models is mainly used in numerical forward modeling because of its complex process and large amount of computation. At present, most of the research of models of this category assume that the fluid is incompressible steady flow, but the fluid in the real oil, gas and water reservoir is compressible or slightly compressible unstable flow. In addition, it is very difficult to construct the model because the serious heterogeneities of the oil and gas fractured cave reservoirs exist, both percolation and tube flow exist, and the tube flow-percolation coupling boundary cannot be obtained accurately. The fifth category of models has long been mainly used to realize the simple coupling cases related to wellbore and formation based on equivalent permeability or equivalent percolation coefficient or converted percolation coefficient, and tube flow (free flow)-percolation coupling flow simulation within the reservoir is solely limited in the field of underground hydraulics with published finite application, No achievements have been published in the fields of numerical simulation of oil and gas reservoirs, transient pressure well test analysis, deliverability test analysis, multi-well interference test analysis, rate production data analysis, transient temperature well test analysis, and permanent downhole monitoring data analysis. In addition, the fifth category method is only limited to the Newtonian fluid percolation, laminar flow, and turbulent flow, but not used to consider the non-Newtonian characteristics of the fluid, non-isothermal flow, diffusion and adsorption desorption effects and so on.

At present, there is no uniform motion equation expression of describing flow law of underground oil, gas, and water. In the coupling problem of various complex reservoirs and various types of wellbores, it is necessary to construct different governing equations and coupling conditions based on various types of reservoir and wellbore conditions, which complicates the construction and solution of the models.

### SUMMARY OF THE INVENTION

The main goal of this invention is to provide a flow simulation and transient well analysis method based on generalized tube flow and percolation coupling, which can be used to overcome various types of complicated tube flow and percolation coupling problems in underground reservoirs.

The technical scheme of the invention is as follows:

This invention provides a flow simulation and transient well analysis method based on generalized tube flow and percolation coupling, which is comprised of the following steps:

S1: Based on defining the generalized mobility, fluid flow laws in different subset of study area are characterized by using the generalized mobility models with the same form;

S2: On the basis of generalized mobility, the multi-component multi-phase flow governing equations are established by considering convection term, diffusion term, accumulation term, adsorption term, and source/sink term. Then a whole set of multi-component multi-phase flow simulation equations are created through combining energy conservation equation, auxiliary equations with saturation and capillary pressure, initial saturation equation, initial pressure equation, initial temperature equation, phase equilibrium equation, and boundary condition equations: The pressure, temperature and saturation of multi-phase fluid as well as the mole percentage of each component in each phase at any point in the study areas are obtained by solving the above mentioned multi-component multi-phase flow simulation equation;

S3: The corresponding application software are formed by using the established multi-component multi-phase flow simulation and analysis equations.

Furthermore, Step S1 is as follows:

S11: For any type of fluid motion equation, if it can be written as v=−λ∇p, λ is called generalized mobility, where v denotes the fluid flow velocity, ∇p denotes the pressure gradient, and the generalized mobility λ is a function of space position and time;

S12 The general mobility models with the same form are used to characterize the flow laws of fluid in the tube flow area of wellbores, pipes, fractures, vugs, holes, cavities, caves, fracture caves, karst caves and caverns, and the percolation area of porous media.

Furthermore, Step S2 is as follows:

S2: The generalized mobility of three-dimensional multi-phase flow

$${λ}_{k} = [ \begin{matrix}{λ}_{k , xx} ( x , t ) & {λ}_{k , xy} ( x , t ) & {λ}_{k , xz} ( x , t ) \\ {λ}_{k , yx} ( x , t ) & {λ}_{k , yy} ( x , t ) & {λ}_{k , yz} ( x , t ) \\ {λ}_{k , zx} ( x , t ) & {λ}_{k , zy} ( x , t ) & {λ}_{k , zz} ( x , t )\end{matrix} ] ,$$

where k=1, 2, . . . , nₚ, nₚ denotes the total phase number, x denotes space position, t denotes time, 9 components of generalized mobility λ_{k,xx}, λ_{k,xy}, λ_{k,xz}, λ_{k,yx}, λ_{k,yy}, λ_{k,yz}, λ_{k,zx}, λ_{k,zy}, λ_{k,zz} are all functions of space position x and time t;

S22: Rewriting the three-dimensional multi-phase flow motion equation into a standard form vₖ=−λₖ∇pₖ by applying three-dimensional multi-phase flow generalized mobility, wherc k=1, 2, . . . , nₚ, nₚ denotes the total phase number,

$$∇ = {( \frac{\partial }{\partial x} , \frac{\partial }{\partial y} , \frac{\partial }{\partial z} )}^{T}$$

is Hamilton operator, vₖ is fluid velocity of k-phase, pₖ is pressure of k-phase;

S23: Multi-component multi-phase flow simulation equation

The multi-component multi-phase flow equations considering convection term, diffusion term, accumulation term, adsorption term, and source/sink term are written as:

Component governing equation:

$$[ ∇ \cdot {\sum }_{k = 1}^{{n}_{p}} ( {ρ}_{k} {C}_{ik} {λ}_{k} ∇ {ρ}_{k} ) ] + [ ∇ \cdot {\sum }_{k = 1}^{{n}_{p}} ( {φρ}_{k} {S}_{k} {D}_{ik} ∇ {C}_{ik} ) ] = \frac{\partial }{\partial t} [ φ {\sum }_{k = 1}^{{n}_{p}} ( {ρ}_{k} {S}_{k} {C}_{ik} ) ] + \frac{\partial }{\partial t} [ ( 1 - φ ) {ρ}_{r} {V}_{i} ] + {\sum }_{k = 1}^{{n}_{p}} {C}_{ik} {q}_{k} , \\ ( x , t ) ∈ Ω \times ( 0 , {t}_{max} ] , i = 1 , 2 , … , {n}_{c}$$

Energy conservation equation:

$$[ ∇ \cdot {\sum }_{k = 1}^{{n}_{p}} ( {π}_{k} {ρ}_{k} {λ}_{k} ∇ {ρ}_{k} ) ] + [ ∇ \cdot κ ∇ T ] = \frac{\partial }{\partial t} [ φ {\sum }_{k = 1}^{{n}_{p}} ( {ρ}_{k} {S}_{k} {U}_{k} ) ] + \frac{\partial }{\partial t} [ ( 1 - φ ) {ρ}_{r} {U}_{r} ] + {\sum }_{k = 1}^{{n}_{p}} {π}_{k} {q}_{k} , \\ ( x , t ) ∈ Ω \times ( 0 , {t}_{max} ]$$

Auxiliary equations with saturation and capillary pressure:

Saturation equation

$${\sum }_{k = 1}^{{n}_{p}} {S}_{k} = 1 , ( x , t ) ∈ Ω \times ( 0 , {t}_{max} ]$$

Capillary pressure equation at α-β phase interface

p_{cαβ}(S_{w})=p_{α}−p_{β},(x,t)∈Ω×(0,T],α=1, . . . ,nₚ;β=1, . . . ,nₚ

Phase equilibrium equation:

The phase equilibrium constant of component i in α and β phase:

K_{iαβ}=C_{iα}/C_{iβ},α=, . . . ,nₚ;β=1, . . . ,nₚ;i=1, . . . ,n_{c}

Mole percentage normalization condition of components in each phase:

$${\sum }_{i = 1}^{{n}_{c}} {C}_{ik} = 1 , k = 1 , … , {n}_{p}$$

The total mole percent of component i:

$${Z}_{i} = {\sum }_{k = 1}^{{n}_{p}} {C}_{ik} , i = 1 , … , {n}_{c}$$

Normalization conditions for ratio of moles of each phase to the whole system:

$${\sum }_{i = 1}^{{n}_{c}} = 1 , k = 1 , … , {n}_{p} \qquad$$

Boundary Condition Equation:

Boundary condition equation of pressure for each phase

$$( {c}_{k , 1} {p}_{k} + {c}_{k , 2} {λ}_{k} \frac{\partial {p}_{k}}{\partial {n}^{\partial Ω}} ) = {g}_{k} ( x , t ) , ( x , t ) ∈ \partial Ω \times ( 0 , {t}_{max} ] , k = 1 , … , {n}_{p}$$

Boundary condition equation of temperature

$$( {d}_{1} T + {d}_{2} κ \frac{\partial T}{\partial {n}^{δΩ}} ) = w ( x , t ) , ( x , t ) ∈ \partial Ω \times ( 0 , {t}_{max} ]$$

Initial saturation equation:

Initial saturation equation of each phase Sₖ(x,0)=lₖ(x), x∈Ω,k=1, . . . ,nₚ

Initial pressure equation:

Initial pressure equation of each phase

pₖ(x,0)=ƒₖ(x),x∈Ω,k=1, . . . ,nₚ

Initial temperature equation:

T(x,0)=τ(x),x∈Ω

Variable symbols description in multi-component multi-phase flow simulation analysis equations: ϕ is porosity, which is the function of average pressure p̅, %; n_{c} is the total component number, dimensionless; nₚ is the total phase number, dimensionless; λₖ is the generalized mobility of k-phase, m²/(Pa·s); ρₖ, ρᵣ are densities of k-phase and rock, kg/m³; πₖ is enthalpy of k phase, J/kg; Uₖ, Uᵣ are internal energy of k-phase and rock, J/kg; Vᵢ is adsorption amount of component i, dimensionless; Sk is the k-phase saturation; t is time, s; tₘₐₓ is the maximum of time, s; pₖ is the k-phase pressure, Pa; lₖ is the k-phase initial saturation distribution function; qₖ is the source/sink term of k-phase, kg/(m³·s); ƒₖ is the k-phase initial pressure distribution function, Pa; K_{iαβ} is the phase equilibrium constant of component i in α and β phase, dimensionless; Cᵢₖ is the mole percent of component i in k-phase, dimensionless; Dᵢₖ is the diffusion coefficient of component i in k-phase, m²/s; Zᵢ is the total mole percent of component i, dimensionless; [symbol] is the ratio of k-phase to the whole system, dimensionless; gₖ is the boundary functions of k-phase on reservoir boundary, dimensionless; w is boundary function of temperature on reservoir boundary, dimensionless; τ is the initial temperature distribution function of reservoirs, K; p_{cαβ} is the capillary pressure at α-β phase interface, Pa; Ω is reservoir space; ∂Ω is reservoir boundary including internal boundary and outer boundary; c_{k,1} is the pressure term coefficients of k-phase on reservoir boundary, 1/Pa; c_{k,2} is the k-phase coefficients of derivative terms along the outer normal direction on reservoir boundary condition, s/m; d₁ is the temperature term coefficient on reservoir boundary, 1/K; d₂ is temperature coefficients of derivative terms along the outer normal direction on reservoir boundary condition, s·m²/J; κ is coefficient of the thermal conductivity, J/(m·s·K); n^{∂Ω} is the outer normal direction on reservoir boundary, m; ∇ is the Hamilton operator; ∂ is the partial derivative sign;

S24: The analytical solution algorithms of above multi-component multi-phase flow simulation equations include direct solving method, Laplace transformation, Fourier transformation, and orthogonal transformation method; Their numerical methods include finite difference method, finite volume method, boundary element method, and finite element method; After solving, the pressure, temperature, and saturation in multi-phase flow are obtained, including the pressure, temperature, saturation, and mole percent of each component in each phase at any time and at any position in the study area.

Furthermore, Step S3 is as follows:

S31: The application software described above includes 5 main parts: data pre-processing system, numerical simulation system, analytical analysis system, and analysis results output system, data input and output management system, etc. Its analysis process includes reservoir definition, setting of initial and boundary conditions, wellbore and fracture setting, numerical simulator selection or fluid type and composition setting, generalized mobility model definition, grid design of numerical simulation, wellbore storage model setting, flow period and regime definition, coordinate transformation, setting of models and their type curve analysis, parameter adjustment and history fitting, dynamic prediction;

S32: The application software described above can be used for single and multi-well flow simulation of complex multi-component multi-phase flow reservoirs, multi-well interference analysis, deliverability analysis (i.e. steady well test analysis), transient pressure analysis (i.e. unsteady pressure well test analysis), transient rate analysis (i.e. production data analysis or rate decline analysis), transient temperature analysis (i.e. unsteady temperature analysis), well test design, and permanent downhole monitoring data analysis. The complex multi-component multi-phase flow reservoirs mentioned above include all types of fluid reservoirs, reservoirs with fluid injection, underground gas storage, ground water reservoirs, geothermal reservoirs, etc.

### Beneficial Effects of the Invention as the Following

This invention simplifies the application of complex problems by defining generalized mobility, and realizes a wider application. Compared with the definition of equivalent permeability or equivalent percolation coefficient or converted percolation coefficient, it has a great improvement in the depth and breadth of application. The concept of generalized mobility has a wider range than the traditional concept. Generalized mobility covers generalized permeability or equivalent permeability or equivalent percolation coefficient or converted percolation coefficient, and is able to adapt to more complex applications. This invention extends the application of generalized permeability or equivalent permeability or equivalent percolation coefficient or converted percolation coefficient, etc. In addition, generalized mobility can be used to further define the parameters (fluid flow coefficient or transmissibility, pressure transmitting coefficient, etc.) related to fluid flow capacity and reservoir conductivity, so that the application scope of these parameters can be expanded.

In solving the problems of single well and multi well flow simulation analysis of complex reservoir with multi-component and multi-phase flow, inter well interference analysis, productivity analysis, transient pressure analysis (i.e. unsteady pressure well test analysis), transient flow analysis (i.e. production data analysis or production decline analysis), transient temperature analysis, well test design and downhole permanent monitoring, the modeling methods of this invention with defining the generalized mobility is more efficient than the methods of the first to the fourth categories mentioned above. At the same time, this invention realizes more and more complex models and methods compared with the fifth category method described above, and extends the application scope of the fifth category method described above.

The above mentioned complex multi-component multi-phase flow reservoirs include all types of reservoirs with fluid injection, underground gas storage, groundwater reservoirs, geothermal reservoirs, etc. The fluid can be a single phase of multi-component oil/gas/water and their multi-phase combinations, or it can be Newtonian fluid and non-Newtonian fluid. The compressibility of the fluid and rock as well as the transient flow characteristics are considered. The invention can unify different linear and nonlinear fluid motion equations by applying generalized mobility, so that for oil and gas reservoirs unified governing equations are able to be constructed by using the same form of motion equations in different regions and different scales. Therefore, it is more convenient to discretize the models, which reduces the complexity of the coupling problem and makes the model solution simple and unified.

Meanwhile, the invention can be used not only for the modeling of numerical simulation of pure cave system and large-scale fracture system, multi-well interference analysis, deliverability test analysis, transient pressure analysis, transient rate analysis, transient temperature analysis, and permanent downhole monitoring data analysis, it can also be used for well testing model constructions of fluid injection reservoirs with dominant Seepage flow channel. For the situation that fluid flow obeys linear flow laws or the generalized mobility is a constant, it is not necessary to pay attention to whether both tube flow (or free flow) and percolation exist at the same time so that the method of this invention can be applied for situations of either one of tube flow (or free flow) and percolation exists or both exist. Therefore, the modelling method of this invention could adapt to more complex reservoirs than conventional Darcy percolation modelling method.

This invention plays an important role for solving the problem of the single and multi-well flow simulation of complex multi-component multi-phase flow reservoirs, multi-well interference analysis, deliverability analysis, transient pressure analysis, transient rate analysis, transient temperature analysis, well test design, and permanent downhole monitoring data analysis.

### BRIEF DESCRIPTION OF THE DRAWINGS

FIG. 1 shows 18 types of basic structural units of a reservoir, which is provided by this invention. A complex reservoir can be formed through nesting, stacking and splicing of a plurality of basic reservoir structural units.

FIG. 2 shows 32 types of basic reservoir bodies, which is provided by this invention. One basic reservoir structural unit can be selected from one of 32 types of basic reservoirs. A complex reservoir can be formed through nesting, stacking and splicing of a plurality of basic reservoir structural units. Every basic reservoir structural unit can be selected from one of 32 types of basic reservoirs.

FIG. 3 is a schematic diagram of a complex reservoir model for tube flow and percolation coupling, which is provided in embodiment 1 of the invention. The whole reservoir space is consisted of four reservoir bodies and three different wells (wells may also be considered as a part of the reservoirs). Four reservoir bodies include two low-permeability reservoirs, one karst cave reservoir, and one high permeability reservoir; three wells include one inclined well, one vertical well, and one multi-segment fractured horizontal well. This is merely a kind of special case of the example.

FIG. 4 is an auxiliary plot of the product of the oil phase generalized mobility and the normal vector at the internal discrete control point, which is provided in embodiment 1 of the invention.

FIG. 5 is an auxiliary plot of the product of the water phase generalized mobility and the normal vector at the internal discrete control point, which is provided in embodiment 1 of the invention.

FIG. 6 is an auxiliary plot of the product of the gas phase generalized mobility and the normal vector at the internal discrete control point, which is provided in embodiment 1 of the invention.

FIG. 7 is an auxiliary plot of the product of the oil phase generalized mobility and the normal vector at the boundary discrete control point, which is provided in embodiment 1 of the invention.

FIG. 8 is an auxiliary plot of the product of the water phase generalized mobility and the normal vector at the boundary discrete control point, which is provided in embodiment 1 of the invention.

FIG. 9 is an auxiliary plot of the product of the gas phase generalized mobility and the normal vector at the boundary discrete control point, which is provided in embodiment 1 of the invention.

FIG. 10 is a schematic diagram of black oil model of oil/gas/water three-phase flow through treating the wellbore as inner boundary for a partially open vertical well located in a homogeneous reservoir, which is provided in embodiment 2 of the invention.

FIG. 11 is a schematic diagram of black oil model of oil/gas/water three-phase flow through treating the wellbore as reservoir for a partially open vertical well located in a homogeneous reservoir, which is provided in embodiment 3 of the invention.

FIG. 12 is a schematic diagram of oil phase flow model for a partially open vertical well located in a homogeneous reservoir through treating the wellbore as inner boundary, which is provided in embodiment 4 of the invention.

FIG. 13 is a schematic diagram of oil phase flow model for a partially open vertical well located in a homogeneous reservoir through treating the wellbore as reservoir, which is provided in embodiment 5 of the invention.

FIG. 14 is a schematic diagram of oil phase flow model for a fully open vertical well located in a homogeneous radial 2-zone composite reservoir through treating the wellbore as inner boundary, which is provided in embodiment 6 of the invention.

FIG. 15 is a schematic diagram of oil phase flow model for a fully open vertical well located in a homogeneous radial 2-zone composite reservoir through treating the wellbore as reservoir, which is provided in embodiment 7 of the invention.

FIG. 16 is a schematic diagram of a tube-shaped reservoir model, which is provided in embodiment 8 of the invention.

FIG. 17 is the typical pressure draw-down type curves of a tube-shaped reservoir model, which is provided in embodiment 8 of the invention. The typical characteristics include: \textcircled{1} early-stage of pressure derivative curve is parallel to the pressure difference curve with a ½ slope (linear flow); \textcircled{2} late-stage pressure derivative curve has a 1 slope (pseudo-steady flow).

FIG. 18 is the pressure build-up type curve corresponding to FIG. 17.

FIG. 19 is the typical pressure draw-down type curves corresponding to FIG. 17 with consideration of skin and wellbore storage effect. The early-stage pressure derivative curve overlaps with the pressure difference curves with a slope of 1. The pressure derivative curve then goes upward due to (positive) skin action.

FIG. 20 is a schematic diagram of a cylindrical reservoir model, which is provided in embodiment 9 of the invention.

FIG. 21 is the typical pressure draw-down type curves of a cylindrical reservoir model, which is provided in embodiment 9 of the invention. The typical characteristics include: \textcircled{1} early-stage of pressure derivative curve has a −½ slope (spherical flow); \textcircled{2} middle-stage pressure derivative curve has a 0 slope (radial flow); \textcircled{3} late-stage pressure derivative curve has a 1 slope (pseudo-steady flow).

FIG. 22 is the pressure build-up type curve corresponding to FIG. 21.

FIG. 23 is the typical pressure draw-down type curves corresponding to FIG. 21 with consideration of skin and wellbore storage effect. The early-stage pressure derivative curve overlaps with the pressure difference curves with a slope of 1. The pressure derivative curve then goes upward due to (positive) skin action.

FIG. 24 is the typical pressure draw-down type curves of a cylindrical reservoir model, which is provided in embodiment 9 of the invention. The typical characteristics include: \textcircled{1} early-stage of pressure derivative curve has a −½ slope (spherical flow); \textcircled{2} middle-stage pressure derivative curve has a ½ slope (linear flow); \textcircled{3} late-stage pressure derivative curve has a 1 slope (pseudo-steady flow).

FIG. 25 is the pressure build-up type curve corresponding to FIG. 24.

FIG. 26 is the typical pressure draw-down type curves corresponding to FIG. 24 with consideration of skin and wellbore storage effect. The early-stage pressure derivative curve overlaps with the pressure difference curves with a slope of 1. The pressure derivative curve then goes upward due to (positive) skin action.

FIG. 27 is a schematic diagram of a spherical reservoir model, which is provided in embodiment 10 of the invention.

FIG. 28 is the typical pressure draw-down type curves of a spherical reservoir model, which is provided in embodiment 10 of the invention. The typical characteristics include: (Dearly-stage of pressure derivative curve has a −½ slope (spherical flow); late-stage pressure derivative curve has a 1 slope (pseudo-steady flow).

FIG. 29 is the pressure build-up type curve corresponding to FIG. 28.

FIG. 30 is the typical pressure draw-down type curves corresponding to FIG. 28 with consideration of skin and wellbore storage effect. The early-stage pressure derivative curve overlaps with the pressure difference curves with a slope of 1. The pressure derivative curve then goes upward due to (positive) skin action.

FIG. 31 is a schematic diagram of a composite model of hollow cylinder and cylindrical reservoir, which is provided in embodiment 11 of this invention.

FIG. 32 is the typical pressure draw-down type curves of a composite model of hollow cylinder and cylindrical reservoir, which is provided in embodiment 11 of the invention. The typical characteristics is that pressure derivative curve successively shows a −½ slope (spherical flow), 0 slope (radial flow of cylindrical reservoir), the junction of cylindrical reservoir and hollow cylindrical reservoir goes upward (transition regime), 0 slope (radial flow of hollow cylindrical reservoir), 1 slope (pseudo-steady flow).

FIG. 33 is the pressure build-up type curve corresponding to FIG. 32.

FIG. 34 is the typical pressure draw-down type curves corresponding to FIG. 32 with consideration of skin and wellbore storage effect. The early-stage pressure derivative curve overlaps with the pressure difference curves with a slope of 1. The pressure derivative curve then goes upward due to (positive) skin action.

FIG. 35 is the typical pressure draw-down type curves of a hollow cylinder and cylindrical reservoir composite model, which is provided in embodiment 11 of the invention. The typical characteristics is that pressure derivative curve successively shows a −½ slope (spherical flow), 0 slope (radial flow of cylindrical reservoir), the junction of cylindrical reservoir and hollow cylindrical reservoir goes downward with a −½ slope (transient period), 0 slope (radial flow of hollow cylindrical reservoir), 1 slope (pseudo-steady flow).

FIG. 36 is the pressure build-up type curve corresponding to FIG. 35.

FIG. 37 is the typical pressure draw-down type curves corresponding to FIG. 35 with consideration of skin and wellbore storage effect. The early-stage pressure derivative curve overlaps with the pressure difference curves with a slope of 1. The pressure derivative curve then goes upward due to (positive) skin action.

FIG. 38 is a schematic diagram of a composite model of tube-shaped and spherical reservoir, which is provided in embodiment 12 of the invention.

FIG. 39 is the typical pressure draw-down type curves of tube-shaped and spherical reservoir composite model, which is provided in embodiment 12 of the invention. The typical characteristics include: \textcircled{1} early-stage of pressure derivative curve is parallel to the pressure difference curve with a ½ slope (linear flow); \textcircled{2} middle-stage pressure derivative curve goes downward; \textcircled{3} late-stage pressure derivative curve has a 1 slope (pseudo-steady flow).

FIG. 40 is the pressure build-up type curve corresponding to FIG. 39.

FIG. 41 is the typical pressure draw-down type curves corresponding to FIG. 39 with consideration of skin and wellbore storage effect. The early-stage pressure derivative curve overlaps with the pressure difference curves with a slope of 1. The pressure derivative curve then goes upward due to (positive) skin action.

FIG. 42 is the vertical well Blasingame type curves based on a cylindrical reservoir model, which is provided in embodiment 9 of the invention.

FIG. 43 is the vertical well Agarwal-Gardner type curves based on a cylindrical reservoir model, which is provided in embodiment 9 of the invention.

FIG. 44 is the vertical well NP1 type curves based on a cylindrical reservoir model, which is provided in embodiment 9 of the invention.

FIG. 45 is the vertical well Transient type curves based on a cylindrical reservoir model, which is provided in embodiment 9 of the invention.

FIG. 46 is the schematic diagram of a one-dimensional tube-shaped reservoir model, which is provided in embodiment 13 [high-speed non-Darcy flow regime I (0≤x≤X₁)+Darcy flow regime II (X₁≤x≤X₂)].

FIG. 47 is the generalized mobility type curves of Darcy flow regime II of a one-dimensional tube-shaped reservoir model, which is provided in embodiment 13 [high-speed non-Darcy flow regime I (0≤x≤X₁)+Darcy flow regime II (X₁≤x≤X₂)].

FIG. 48 is the generalized mobility type curves of Darcy flow regime II of a one-dimensional tube-shaped reservoir model, which is provided in embodiment 13 [β=0 in high-speed non-Darcy flow regime I becomes Darcy flow regime I (0≤x≤X₁)+Darcy flow regime II(X₁≤x≤X₂)].

FIG. 49 is the comparison plot between high-speed non-Darcy flow and Darcy flow of a one-dimensional tube-shaped reservoir model, which is provided in embodiment 13 (it becomes Darcy flow when β=0 in high-speed non-Darcy flow).

FIG. 50 is a generalized mobility variation type curve of transient temperature analysis model with oil single-phase flow, which is provided by embodiment 18: The larger the generalized mobility, the lower the position of temperature difference and temperature difference derivative curve.

### DETAILED DESCRIPTION OF EMBODIMENTS

The name of the invention is a flow simulation and transient well analysis method based on generalized tube flow and percolation coupling.

Through comparing the Hagen-Poiseuille (1839,1840) formula of laminar flow and tube flow with the Darcy formula of conventional percolation, it is found that there is no essential difference in mathematical expression form between the two formulas. They both are linear functions with positive proportion i.e. The average velocity of fluid is proportional to the pressure gradient. Fluid flow laws described by both laminar and tube flow formula and Darcy's conventional percolation formula is linear flow. However, Fluid flow laws, which is described by turbulent tube flow equation, Forchheimer (1901) binomial high-speed non-Darcy formula, power-law non-Newton formula, low-speed non-Darcy percolation equation, free flow Navier-Stokes equation, etc, is a nonlinear flow. In order to unify the linear flow and nonlinear flow and consider the anisotropy of the reservoir or others, this invention proposed that the fluid flow velocity of underground fluid flow motion equations are uniformly written as the product of the generalized mobility and the pressure gradient of the negative direction, which means

vₖ=−λₖ∇pₖ

where

$${λ}_{k} = [ \begin{matrix}{λ}_{k , xx} ( x , t ) & & {λ}_{k , xy} ( x , t ) & {λ}_{k , xz} ( x , t ) \\ {λ}_{k , yx} ( x , t ) & & {λ}_{k , yy} ( x , t ) & {λ}_{k , yz} ( x , t ) \\ {λ}_{k , zx} ( x , t ) & & {λ}_{k , zy} ( x , t ) & {λ}_{k , zz} ( x , t )\end{matrix} ]$$

is the generalized mobility of three-dimensional multi-phase flow [unit: m2/(Pa·s)]. where k=1, 2, . . . , nₚ, nₚ denotes the total phase number, x denotes space position, t denotes time, 9 components of generalized mobility λ_{k,xx}, λ_{k,xy}, λ_{k,xz}, λ_{k,yx}, λ_{k,yy}, λ_{k,yz}, λ_{k,zx}, λ_{k,zy}, λ_{k,zz} are all functions of space position x and time t.

$$∇ = {( \frac{\partial }{\partial x} , \frac{\partial }{\partial y} , \frac{\partial }{\partial z} )}^{T}$$

is Hamilton operator (unit: 1/m), vₖ is fluid velocity (m/s), pₖ is pressure (Pa).

Because the generalized mobility defined in this invention itself covers the concepts of generalized permeability or equivalent permeability, equivalent percolation coefficient or converted percolation coefficient, when solving some relatively simple practical problems, the use of these definitions can also achieve the similar effect of generalized mobility. If the parameters (such as fluid flow coefficient or transmissibility, pressure transmitting coefficient, etc.) related to fluid flow capacity and reservoir conductivity are defined by using the definition method of this invention, the application scope of the relevant parameters can be extended.

The invention can be applied to fluid types including multi-component oil/gas/water single-phase flow and multi-component multi-phase flow. The fluid types can be Newton and non-Newtonian. The flowing laws can be linear, non-linear, or locally linear and locally nonlinear.

The further detailed descriptions of this invention are given in following by combining with drawings. The following embodiments are described only for the purpose of illustration and not for any limitation to the scope of the present disclosure.

A flow simulation and transient well analysis method based on generalized tube flow and percolation coupling includes:

S1: Based on defining the generalized mobility, fluid flow laws in different subset of study area are characterized by using the generalized mobility models with the same form;

S2: On the basis of generalized mobility, the multi-component multi-phase flow governing equations are established by considering convection term, diffusion term, accumulation term, adsorption term, and source/sink term. Then a whole set of multi-component multi-phase flow simulation equations are created through combining energy conservation equation, auxiliary equations with saturation and capillary pressure, initial saturation equation, initial pressure equation, initial temperature equation, phase equilibrium equation, and boundary condition equations; The pressure, temperature and saturation of multi-phase fluid as well as the mole percentage of each component in each phase at any point in the study areas are obtained by solving the above multi-component multi-phase flow simulation equation;

S3: The corresponding application software are formed by using the established multi-component multi-phase flow simulation and analysis equations.

wherein S1 (Based on defining the generalized mobility, fluid flow laws in different subset of study area are characterized by using the same formed generalized mobility models) includes:

(1) For any type of fluid motion equation, if it can be written as v=−λ∇p, λ is called generalized mobility, where v denotes the fluid flow velocity, ∇p denotes the pressure gradient, and the generalized mobility λ is a function of space position and time.
(2) The general mobility models with the same form are used to characterize the flow laws of fluid in the tube flow area of wellbores, pipes, fractures, vugs, holes, cavities, caves, fracture caves, karst caves and caverns, and the percolation area of porous media.

wherein S2 (On the basis of generalized mobility, the multi-component multi-phase flow governing equations are established by considering convection term, diffusion term, accumulation term, adsorption term, and source/sink term. Then a whole set of multi-component multi-phase flow simulation equations are created through combining energy conservation equation, auxiliary equations with saturation and capillary pressure, initial saturation equation, initial pressure equation, initial temperature equation, phase equilibrium equation, and boundary condition equations; The pressure, temperature and saturation of multi-phase fluid as well as the mole percentage of each component in each phase at any point in the study areas are obtained by solving the above multi-component multi-phase flow simulation equation) includes:

(1) The generalized mobility of three-dimensional multi-phase flow

$${λ}_{k} = [ \begin{matrix}{λ}_{k , xx} ( x , t ) & & {λ}_{k , xy} ( x , t ) & {λ}_{k , xz} ( x , t ) \\ {λ}_{k , yx} ( x , t ) & & {λ}_{k , yy} ( x , t ) & {λ}_{k , yz} ( x , t ) \\ {λ}_{k , zx} ( x , t ) & & {λ}_{k , zy} ( x , t ) & {λ}_{k , zz} ( x , t )\end{matrix} ] ,$$

where k=1, 2, . . . , nₚ, nₚ denotes the total phase number, x denotes space position, t denotes time, 9 components of generalized mobility λ_{k,xx}, λ_{k,xy}, λ_{k,xz}, λ_{k,yx}, λ_{k,yy}, λ_{k,yz}, λ_{k,zx}, λ_{k,zy}, λ_{k,zz} are all functions of space position x and time t.

From the generalized mobility of three-dimensional multi-phase flow, it is easy to obtain the generalized mobility of two-dimensional multi-phase flow

$${λ}_{k} = [ \begin{matrix}{λ}_{k , xx} ( x , t ) & {λ}_{k , xy} ( x , t ) \\ {λ}_{k , yx} ( x , t ) & {λ}_{k , yy} ( x , t )\end{matrix} ] ,$$

where k=1, 2, . . . , nₚ, nₚ denotes the total phase number, x denotes space position, t denotes time, 4 components of generalized mobility λ_{k,xx}, λ_{k,xy}, λ_{k,yx}, λ_{k,yy}, are all functions of space position x and time t.

From the generalized mobility of three-dimensional multi-phase flow, it is easy to obtain the generalized mobility of one-dimensional multi-phase flow λₖ=λ_{k,xx}(x,t), where k=1, 2, . . . , nₚ, nₚ denotes the total phase number, x denotes space position, t denotes time.

Rewriting the three-dimensional multi-phase flow motion equation into a standard form vₖ=−λₖ∇pₖ by applying three-dimensional multi-phase flow generalized mobility, where k=1, 2, . . . , nₚ, nₚ denotes the total phase number,

$$∇ = {( \frac{\partial }{\partial x} , \frac{\partial }{\partial y} , \frac{\partial }{\partial z} )}^{T}$$

is Hamilton operator, vₖ is fluid velocity of k-phase, pₖ is pressure of k-phase.

Rewriting the two-dimensional multi-phase flow motion equation into a standard form vₖ=−λₖ∇pₖ by applying two-dimensional multi-phase flow generalized mobility, where k=1, 2, . . . , nₚ, nₚ denotes the total phase number.

$$∇ = {( \frac{\partial }{\partial x} , \frac{\partial }{\partial y} )}^{T}$$

is Hamilton operator, vₖ is fluid velocity of k-phase, pₖ is pressure of k-phase.

Rewriting the one-dimensional multi-phase flow motion equation into a standard form vₖ=λₖ∇pₖ by applying one-dimensional multi-phase flow generalized mobility, where k=1, 2, . . . , nₚ, nₚ denotes the total phase number,

$$∇ = \frac{\partial }{\partial x}$$

is Hamilton operator, vₖ is fluid velocity of k-phase, pₖ is pressure of k-phase.
(3) Multi-component multi-phase flow simulation equation

The multi-component multi-phase flow equations considering convection term, diffusion term, accumulation term, adsorption term, and source/sink term are written as:

Component governing equation:

$$[ ∇ \cdot {\sum }_{k = 1}^{{n}_{p}} ( {ρ}_{k} {C}_{ik} {λ}_{k} ∇ {p}_{k} ) ] + [ ∇ \cdot {\sum }_{k = 1}^{{n}_{p}} ( {φρ}_{k} {S}_{k} {D}_{ik} ∇ {C}_{ik} ) ] = \\ \frac{\partial }{\partial t} [ φ {\sum }_{k = 1}^{{n}_{p}} ( {ρ}_{k} {S}_{k} {C}_{ik} ) ] + \frac{\partial }{\partial t} [ ( 1 - φ ) {ρ}_{r} {V}_{i} ] + \\ {\sum }_{k = 1}^{{n}_{p}} {C}_{ik} {q}_{k} , ( x , t ) ∈ Ω \times ( 0 , {t}_{max} ] , i = 1 , 2 , ... , {n}_{c}$$

Energy conservation equation:

$$[ ∇ \cdot {\sum }_{k = 1}^{{n}_{p}} ( {}_{k} {ρ}_{k} {λ}_{k} ∇ {p}_{k} ) ] + [ ∇ \cdot κ ∇ T ] = \\ \frac{\partial }{\partial t} [ φ {\sum }_{k = 1}^{{n}_{p}} ( {ρ}_{k} {S}_{k} {U}_{k} ) ] + \frac{\partial }{\partial t} [ ( 1 - φ ) {ρ}_{r} {U}_{r} ] + \\ {\sum }_{k = 1}^{{n}_{p}} {}_{k} {q}_{k} , ( x , t ) ∈ Ω \times ( 0 , {t}_{max} ]$$

Auxiliary equations with saturation and capillary pressure:

Saturation equation

$${\sum }_{k = 1}^{{n}_{p}} {S}_{k} = 1 , ( x , t ) ∈ Ω \times ( 0 , {t}_{max} ]$$

Capillary pressure equation at α-β phase interface

p_{cαβ}(S_{w})=p_{α}-p_{β},(x,t)∈Ω×(0,T],α=1, . . . ,nₚ;β₁, . . . ,nₚ

Equilibrium equation:

The equilibrium constant of component i in α and β phase:

K_{iαβ}=C_{iα}/C_{iβ},α=1, . . . ,nₚ;β=1, . . . ,nₚ;i=1, . . . ,n_{c}

Mole percentage normalization condition of components in each phase:

$${\sum }_{i = 1}^{{n}_{c}} {C}_{ik} = 1 , k = 1 , ... , {n}_{p}$$

The total mole percent of component i:

$${Z}_{i} = {\sum }_{k = 1}^{{n}_{p}} {C}_{ik} , i = 1 , ... , {n}_{c}$$

Normalizing conditions for ratio of moles of each phase to the whole system:

$${\sum }_{i = 1}^{{n}_{c}} = 1 , k = 1 , ... , {n}_{p}$$

Boundary condition equation:

Boundary condition equation of pressure for each phase

$$( {c}_{k , 1} {p}_{k} + {c}_{k , 2} {λ}_{k} \frac{\partial {p}_{k}}{\partial {n}^{\partial Ω}} ) = {g}_{k} ( x , t ) , ( x , t ) ∈ \partial Ω \times ( 0 , {t}_{max} ] , k = 1 , ... , {n}_{p} \\ ( {d}_{1} T + {d}_{2} κ \frac{\partial T}{\partial {n}^{\partial Ω}} ) = w ( x , t ) , ( x , t ) ∈ \partial Ω \times ( 0 , {t}_{max} ]$$

Initial saturation equation:

Initial saturation equation of each phase

Sₖ(x,0)=lₖ(x),x∈Ω,k=1, . . . ,nₚ

Initial pressure equation:

Initial pressure equation of each phase:

pₖ(x,0)=ƒₖ(x),x∈Ω,k=1, . . . ,nₚ

Initial temperature equation:

T(x,0)=τ(x),x∈Ω

Variable symbols description in multi-component multi-phase flow simulation analysis equations: ϕ is porosity, which is the function of average pressure p̅, %; n_{c} is the total component number, dimensionless; nₚ is the total phase number, dimensionless; λₖ is the generalized mobility of k-phase, m²/(Pa·s); ρₖ, ρᵣ are densities of k-phase and rock, kg/m³; πₖ is enthalpy of k phase, J/kg; Uₖ, Uᵣ are internal energy of k-phase and rock, J/kg; Vi is adsorption amount of component i, dimensionless; Sk is the k-phase saturation; t is time, s; tₘₐₓ is the maximum of time, s; pₖ is the k-phase pressure, Pa; lₖ is the k-phase initial saturation distribution function qₖ is the source/sink term of k-phase, kg/(m³·s); ƒₖ is the k-phase initial pressure distribution function, Pa; K_{iαβ} is the phase equilibrium constant of component i in α and β phase, dimensionless; Cᵢₖ is the mole percent of component i in k-phase, dimensionless; Dᵢₖ is the diffusion coefficient of component i in k-phase, m²/s; Zᵢ is the total mole percent of component i, dimensionless; [symbol] is the ratio of k-phase to the whole system, dimensionless; gₖ is the boundary functions of k-phase on reservoir boundary, dimensionless; w is boundary function of temperature on reservoir boundary, dimensionless; τ is the initial temperature distribution function of reservoirs, K; pee is the capillary pressure at α-β phase interface, Pa; Ω is reservoir space; ∂Ω is reservoir boundary including internal boundary and outer boundary; c_{k,1} is the pressure term coefficients of k-phase on reservoir boundary, 1/Pa c_{k,2} is the k-phase coefficients of derivative terms along the outer normal direction on reservoir boundary condition, s/m; d₁ is the temperature term coefficient on reservoir boundary, 1/K; d₂ is temperature coefficients of derivative terms along the outer normal direction on reservoir boundary condition, s·m²/J; κ is coefficient of the thermal conductivity, J/(m·s·K); n^{∂Ω} is the outer normal direction on reservoir boundary, m; ∇ is the Hamilton operator; ∂ is the partial derivative sign;

(4) The analytical solution of above multi-component multi-phase flow simulation equations include direct solving method, Laplace transformation, Fourier transformation, and orthogonal transformation method; The numerical methods include finite difference method, finite volume method, boundary element method, and finite element method; After solving, the pressure, temperature, and saturation in multi-phase flow are obtained, including the pressure, temperature, saturation, and mole percent of each component in each phase at any time and at any position in the study area.

Wherein S3 (The corresponding application software are developed on the basis of multi-component multi-phase flow simulation analysis equations) includes:

(1) The application software described above includes 5 main parts: data pre-processing system, numerical simulation system, analytical analysis system, and analysis results output system, data input and output management system, etc. The key technologies include reservoir definition, setting of initial and boundary conditions, wellbore and fracture setting, numerical simulator selection or fluid type and composition setting, generalized mobility model definition (including defining generalized permeability or equivalent permeability, etc., in simplified cases), grid design of numerical simulation, wellbore storage model setting, flow period and regime definition, coordinate transformation, setting of models and their type curve analysis, parameter adjustment and history fitting, dynamic prediction. The details are as follows:

### (1.1) Reservoir Definition

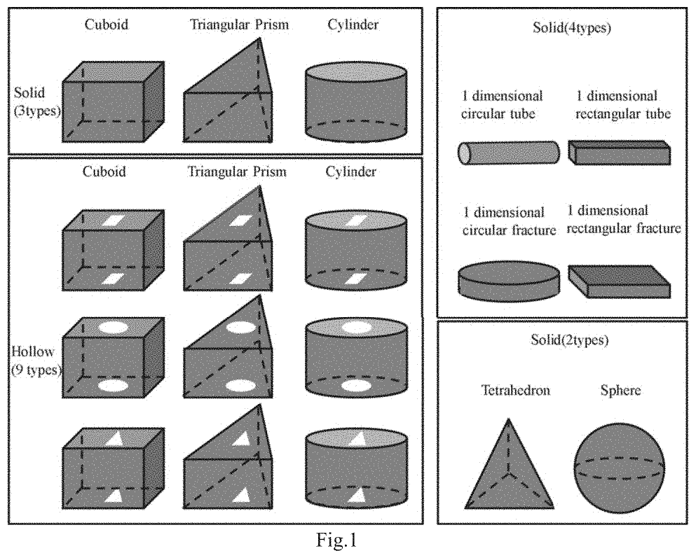

The basic reservoir structural unit is shown in FIG. 1. The reservoir is composed of a single or several basic reservoir structural units, which can be nested, stacked and spliced among each other.

Reservoir boundaries include constant pressure boundary, variable pressure boundary, sealed boundary, semi-permeable boundary, infinite acting boundary and so on.

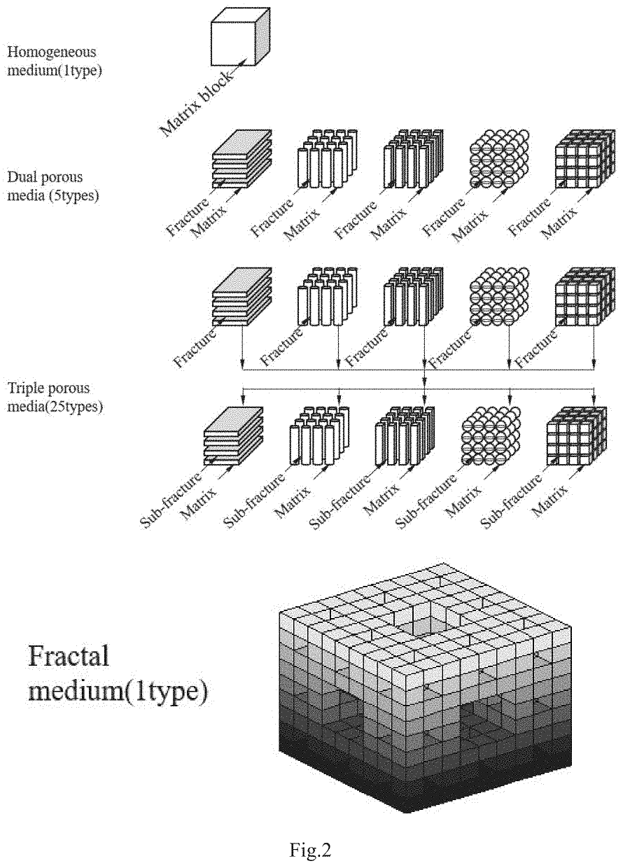

The reservoir types are as shown in FIG. 2. The reservoir types of basic reservoir structural unit include homogeneous, dual porous media, triple porous media, fractal media, cavities caves, caverns, fractures and so on.

### (1.2) Setting of Initial and Boundary Conditions

Initialization of pressure, temperature, saturation and internal and external boundary conditions. The Inner boundary models include effective wellbore diameter model, source function model and so on.

### (1.3) Wellbore and Fracture Setting

Well types include vertical well, horizontal well, inclined well, fractured well, multibranch well and so on.

The wellbore and fracture types include uniform flux, infinite conductivity, and finite conductivity and so on.

The wellbore and fracture opening degree includes fully open and partially open.

### (1.4) Numerical Simulator Selection or Fluid Type and Composition Setting

The numerical simulator selection includes black oil model, compositional model and thermal recovery model. The fluid phases (including composition) include oil single-phase, water single-phase, gas single-phase, oil-water two-phase, oil-gas two-phase, gas-water two-phase, oil-gas-water three phase, condensate gas, carbon dioxide, foam fluid, polymer and so on.

### (1.5) Generalized Mobility Model Definition (Including Defining Generalized Permeability or Equivalent Permeability, Etc., in Simplified Cases)

The generalized mobility models include: \textcircled{1} Newton fluid+Darcy flow, \textcircled{2} Newton fluid+Laminar tube flow, \textcircled{3} Newton fluid+High speed Non-Darcy flow, \textcircled{4} Newton fluid+turbulent tube flow, \textcircled{5} Newton fluid+pressure sensitive flow, \textcircled{6} Non-Newton fluid+Darcy flow, \textcircled{7} Non-Newton fluid+Laminar tube flow, \textcircled{8} Non-Newton fluid+pressure sensitive flow, \textcircled{9} Non-Newton fluid+turbulent tube flow, \textcircled{10} Newton fluid+low speed non-Darcy flow, \textcircled{11} Newton fluid+slippage effect, etc.

### EXAMPLES

\textcircled{1} Newton fluid+Darcy flow

On the basis of Darcy's percolation formula (1856), λ is written as:

$$λ = \frac{K}{μ}$$

Where μ is the viscosity of the fluid, K is the permeability,

For the form of considering the influence of gravity, λ is written as:

$$λ = \frac{K}{μ} ( 1 - \frac{ρ g cos α}{\vert \frac{\partial p}{\partial l} \vert} )$$

Where μ is the viscosity of the fluid, K is the permeability, ρ is the density of the fluid, g is the acceleration of gravity, p is the pressure, l is the distance, α is the angle between pressure gradient direction and gravity direction.

\textcircled{2} Newton fluid+Laminar tube flow

On the basis of Hagen-poiseuille's formula (1839,1840), λ is written as:

$$λ = \frac{{d}^{2}}{32 μ}$$

Where μ is the viscosity of the fluid, d is the hydraulic diameter of tubes.

\textcircled{3} Newton fluid+High speed Non-Darcy flow

On the basis of Forchheimer binomial high-speed Non-darcy formula (1901), λ is written as:

$$λ = \frac{1}{\frac{μ}{K} + βρ \vert v \vert}$$

Where μ is the viscosity of the fluid, K is the permeability, β is the high speed Non-Darcy factor, ρ is the density of the fluid, v is the velocity of the fluid.

\textcircled{4} Newton fluid+turbulent tube flow

On the basis of Darcy-Weisbach formula (1845) and Colebrook on-way resistance formula (1938), λ is written as:

$$λ = 0.0232 \frac{d}{ρ v} {( \frac{d ρ v }{d} \frac{ɛ}{d} - 18.574 W ( 0.199 \frac{d ρ v}{μ} {e}^{0.0538 \frac{d ρ v}{μ} \frac{ɛ}{d}} ) )}^{2}$$

Where μ is the viscosity of the fluid, d is the hydraulic diameter of tubelines, ρ is the density of the fluid, ε/d is the relative roughness, v is the velocity, W(g) is the Lambert W function or product logarithm function.

\textcircled{5} Newton fluid+pressure sensitive flow

On the basis of permeability modulus (pressure sensitivity) formula, λ is written as

$$λ = \frac{{K}_{i} {e}^{γ ( p - {p}_{i} )}}{μ}$$

Where μ is the viscosity of the fluid, Kᵢ is the initial permeability of reservoir, γ is the permeability modulus, P is the pressure, pᵢ is the initial reservoir pressure.

\textcircled{6} Non-Newton fluid+Darcy flow

On the basis of the Darcy's percolation formula, Qstwald-DeWaele power-law fluid viscosity formula (1923,1925) and Hirasaki-Pope shear rate formula (1974), λ is written as:

$$λ = ( k / {μ}_{eff} ) \cdot {\vert v \vert}^{1 - n}$$

$${μ}_{eff} = \frac{H}{12} {( 9 + \frac{3}{n} )}^{n} {( 150 K φ )}^{\frac{1 - n}{2}}$$

Where μ_{eff} is the effective viscosity, K is the permeability, n is the power-law index, v is the fluid flow velocity, H is the consistency coefficient, ϕ is the porosity.

\textcircled{7} Non-Newton fluid+Laminar tube flow

On the basis of Hagen-poiseuille laminar tube flow formula (1839,1840), Qstwald-DeWaele power-law fluid viscosity formula (1923,1925) and Hirasaki-Pope shear rate formula (1974), λ is written as:

$$λ = \frac{{d}^{2}}{32 {μ}_{eff} {v}^{n - 1}}$$

$${μ}_{e f f} = \frac{H}{12} {( 9 + \frac{3}{n} )}^{n} {( \frac{75 {d}^{2}}{16} )}^{\frac{1 - n}{2}}$$

Where μ_{eff} is the effective viscosity, d is the hydraulic diameter of tubes, n is the power-law index, v is the fluid flow velocity, H is the consistency coefficient.

\textcircled{8} Non-Newton fluid+pressure sensitive flow

On the basis of the permeability modulus(stress sensitivity) formula, Qstwald-DeWaele power-law fluid viscosity formula (1923,1925) and Hirasaki-Pope shear rate formula (1974), λ is written as:

$$λ = \frac{{K}_{i} {e}^{γ ( p - {p}_{i} )}}{{μ}_{eff} {v}^{n - 1}}$$

$${μ}_{eff} = \frac{H}{12} {( 9 + \frac{3}{n} )}^{n} {( 150 K φ )}^{\frac{1 - n}{2}}$$

Where μ_{eff} is the effective viscosity, Kᵢ is the initial permeability of reservoir, γ is the permeability modulus, p is the pressure, pᵢ is the initial reservoir pressure, v is the fluid flow velocity, n is the power-law index, H is the consistency coefficient, K is the permeability, ϕ is the porosity.

\textcircled{9} Non-Newton fluid+turbulent tube flow

On the basis of Darcy-Weisbach formula (1845), Colebrook resistance formula along the way (1938), Qstwald-DeWaele power-law fluid viscosity formula (1923,1925), and Hirasak-Pope shear rate formula (1974), λ is written as:

$$λ = 0.0232 \frac{d}{ρ v} {( \frac{d ρ}{{μ}_{eff} {v}^{n - 2}} \frac{ɛ}{d} - 18.574 W ( 0.199 \frac{d p}{{μ}_{eff} {v}^{n - 2}} {e}^{0.0538 \frac{d ρ}{{μ}_{eff} {v}^{n - 2}} \frac{ɛ}{d}} ) )}^{2}$$

$${μ}_{eff} = \frac{H}{12} {( 9 + \frac{3}{n} )}^{n} {( \frac{75 {d}^{2}}{16} )}^{\frac{1 - n}{2}}$$

Where μ_{eff} a is the effective viscosity, d is the hydraulic diameter of tubes, ρ is the density of the fluid,

$$\frac{ɛ}{d}$$

is the relative roughness, v is the velocity of the fluid, n is the power-law index, H is the consistency coefficient, W(g) is the Lambert W function or product logarithm function.
\textcircled{10} Newton fluid+low speed non-Darcy flow or Bingham (1919) Non-Newton fluid+Darcy percolation flow

λ is written as:

$$λ = \frac{K}{μ} ( 1 - \frac{G}{\vert \frac{\partial p}{\partial l} \vert} )$$

Where μ is the viscosity of the fluid, K is the permeability, G is the low-speed non-darcy factor or pseudo-threshold pressure gradient, p is the pressure, l is the distance.

\textcircled{11} Newton fluid+slippage effect

λ is written as:

$$λ = \frac{k ( 1 + b / p )}{μ}$$

Where μ is the viscosity of the fluid, K is the permeability, b is the Klinkenberg factor, p is the pressure.

For non-Darcy percolation in the above formula, besides Forchheimer (1901) binomial high-speed non-Darcy formula and permeability modulus formula (stress sensitivity), there are also formulas created as a replacement by Irmay (1968), Izbash (1971), Swartzendruber (1962). Huang Tingzhang (1997), Halex (1979) and so on. The Colebrook (1939)'s along-way resistance formula above can be replaced by other formulas such as Blasius (1913). Nikuradse (1933), Churchill (1977). The Qstwald-DeWaele (1923,1925)'s power-law fluid viscosity formula above can be replaced by other formulas such as Bingham (1919), Cross (1979). Carreau (1979). Meter (1964), Sisko (1958); The Hirasaki-Pope (1974) 's shear rate formula can be replaced by other formulas such as Gogarty (1967), W. Littmann (1988), Camillen (1987), Rabinowitsch (1929), Jennings (1971). In addition, for low-density gas flow cases, the generalized mobility expression can be obtained by correcting the non-Darcy effect with the Klinkenberg equation (1941).

### (1.6) Grid Design of Numerical Simulation

The design of grid types (orthogonal, corner, hybrid, etc.), grid directions (considering sediment source direction, flow direction, well location, etc.), grid boundaries, grid layers, grid sizes, grid density, etc.

### (1.7) Wellbore Storage Model Setting

Wellbore storage models include constant wellbore storage model, changing wellbore storage model [Fair model (1981), Hegeman model (1993), leaky packer model and near wellbore fracture storage model (Spivey, 1999.

### (1.8) Flow Period and Regime Definition

The flow period definition includes pressure build-up, pressure falloff, pressure drawdown, injection test, and slug flow. The flow regime definition includes linear flow, bilinear flow, radial flow and spherical flow.

### (1.9) Coordinate Transformation (Flow Rate History Influence Treatment)

The coordinate transformation methods include equivalent constant flow rate history Horner method, equivalent constant flow rate history Agarwal method, variable flow rate history Horner method, variable flow rate history Agarwal method, deconvolution method and so on.

### (1.10) Setting of Models and their Type Curve Analysis

The type curves of model analysis include various model type curves for pressure, flow and temperature analysis. The pressure analysis p type curves include full view pressure history plot, linear plot, semi-logarithmic plot, Gringarten-Bourdet log-log plot, linear flow plot, bilinear flow plot, (hemi)spherical flow plot, PPD plot, SLPD plot, early time plot, ζ function plot, curve comparison of previous single well or well group and so on.

The type curves of production analysis include blasingame plate, Agarwal Gardner plate, NPI plate and transient plate. The Type curves of temperature analysis include double logarithm diagram of temperature change and its derivative.

See Table 1 for the combination of tube flow (free flow)—percolation coupling model methods available in the numerical simulation and type curve analysis.

### (1.11) Parameter Adjustment and History Matching

The adjustable parameters include permeability, saturation and porosity. History matching indexes include pressure index, production index, temperature index, fluid property index and so on.

### (1.12) Dynamic Prediction

Dynamic prediction includes various development indexes of the prediction scheme for economic evaluation.

TABLE 1
The tube flow percolation coupling models combined in the software (Scope cases of Claims)

| Different combinations of models | | Application field | | |
|---|---|---|---|---|
| Well and reservoir coupling, | Combination | Transient well | Numerical | Numerical simulation |
| coupling between reservoirs, | of fluid types | analysis (pressure, | simulation of oil | of underground |
| boundary coupling, etc | and motion laws | rate and temperature) | and gas reservoir | water reservoir |
| Coupling of single/dual | Remark 1 | This invention | Ones published | Ones published by |
| medium homogeneous | | | by others limited | others limited to use |
| reservoir and vertical or | | | to use of | of equivalent |
| horizontal well | | | equivalent | percolation coefficient |
| | | | permeability | |
| | Remark 2 | This invention | This invention | This invention |
| Coupling of triple media | Remark 1 | This invention | This invention | Ones published by |
| hreservoir and vertical | | | | others limited to |
| or horizontal well | | | | use of equivalent |
| | | | | percolation coefficient |
| | Remark 2 | This invention | This invention | This invention |
| Coupling of different | Remark 3 | This invention | This invention | This invention |
| reservoirs and different | | | | |
| well types (the above | | | | |
| cases are not included) | | | | |
| Coupling of different | Remark 3 | This invention | This invention | This invention |
| reservoirs | | | | |
| Coupling of different | Remark 3 | This invention | This invention | This invention |
| reservoirs and different | | | | |
| types of boundaries | | | | |

| | |
|---|---|
| Remark 1 | Three cases of fluid type and motion law combinations: |
| | \textcircled{1}Newtonian fluid + Darcy flow; |
| | \textcircled{2}Newtonian fluid + laminar tube flow; |
| | \textcircled{4}Newtonian fluid + turbulent tube flow; |
| Remark 2 | Seven cases of fluid type and motion law combinations: |
| | \textcircled{3}Newtonian fluid + high speed non-Darcy flow; |
| | \textcircled{5}Newtonian fluid + stress-sensitive percolation; |
| | \textcircled{6}non-Newionian fluid + Darcy flow; |
| | \textcircled{7}non-Newtonian fluid + laminar tube flow; |
| | \textcircled{8}non-Newtonian fluid + stress-sensitive percolation; |
| | \textcircled{9}non-Newtonian fluid + turbulent tube flow; |
| | \textcircled{10}Newtonian fluid + low speed non-Darcy flow |
| | (or Binghamnon-Newtonian fluid + Darcy flow). |
| Remark 3 | Ten cases of fluid type and motion law combinations: |
| | \textcircled{1}Newtonian fluid + Darcy flow; |
| | \textcircled{2}Newtonian fluid + laminar tube flow; |
| | \textcircled{3}Newtonian fluid + high speed non-Darcy flow; |
| | \textcircled{4} Newtonian fluid + turbulent tube flow; |
| | \textcircled{5} Newtonian fluid + stress-sensitive percolation; |
| | \textcircled{6}Non-Newtonian fluid + Darcy flow; |
| | \textcircled{7}Non-Newtonian fluid + laminar tube flow; |
| | \textcircled{8}Non-Newtonian fluid + stress-sensitive percolation; |
| | \textcircled{9}Non-Newtonian fluid + turbulent tube flow; |
| | \textcircled{10}Newtonian fluid + low speed non-Darcy flow |
| | (or Bingham Non-Newtonian fluid + Darcy flow). |

| | |
|---|---|
| Remark 4 | (1)“Published by others” are limited to the use of |
| | equivalent permeability and equivalent percolation coefficient (or |
| | converted percolation coefficient) in the above numerical |
| | simulation models, where the use of generalized mobility (or |
| | equivalent mobility) belongs to this invention; |
| | (2) This invention includes characteristic methods for tube |
| | flow (free flow) or percolation cases realized by the method of |
| | this invention; |
| | (3) The permanent downhole monitoring data analysis is |
| | mainly based on models of “transient well analysis” (pressure |
| | or temperature) or/and “transient rate production data analysis”. |
| | (4) This invention includes above models that can be applied |
| | for geothermal reservoirs. |
| Remark 5 | The reservoirs refer to a reservoir of oil, gas or water. |
| | Reservoirs contains tubes, porous media, fracture media, caves, |
| | or their combinations, connected combinations or overlapping. |

(2) The software developed can be used for single and multi-well flow simulation of complex multi-component multi-component multi-phase flow reservoirs, multi-well interference analysis, deliverability analysis (i.e. steady well test analysis), transient pressure analysis (i.e. unsteady pressure well test analysis), transient rate analysis (i.e. production data analysis or rate decline analysis), transient temperature analysis (i.e. unsteady temperature analysis), well test design, and permanent downhole monitoring data analysis (including pressure, temperature, flow rate, and so on). The above complex multi-component multi-phase flow reservoirs refer to all types of reservoirs, reservoirs with fluid injection, underground gas storage, ground water reservoirs, geothermal reservoirs, etc.

Embodiment 1 is a general example that can be used to solve tube flow-percolation coupling problems and multi-phase flow problems for various complex reservoirs, embodiments 2 to 7 are simplified on the basis of embodiment 1 to reflect that the wellbore can be treated either as an inner boundary or as a reservoir, the specific solution methods of which can be solved according to the numerical methods given in embodiment 1. However, some embodiments are simple and can be solved by analytical methods. For example, embodiments 4 and 6 can be solved by Laplace integral transformation method and give analytical solutions in Laplace space. embodiments 8 to 12 are ones given where the generalized mobility is a constant and they have analytical solutions in Laplace space. embodiment 13 gives a situation where the generalized mobility is a non-constant. embodiment 14 is an example of multi-component condensate gas flow simulation analysis for complex reservoirs. Embodiment 15 is an example of multi-component carbon dioxide drive flow simulation analysis in complex reservoirs. Embodiment 16 is an example of multi-component polymer drive flow simulation analysis in complex reservoirs. Embodiment 17 is an example of multi-component three-phase flow simulation analysis considering non-isothermal process in complex reservoirs. Embodiment 18 is an example of transient temperature analysis of oil single-phase flow.

It should be noted that the generalized mobility is a constant (matrix) when only the fluid flow is Darcy flow or laminar tube flow. In general, the generalized mobility is a function of space position and time. In particular, the generalized mobility may be a function of variables such as fluid velocity, pressure gradient, and so on. If the generalized mobility can be expressed as the product of a constant matrix and a scalar function, the non-linear flow problem can be transformed into linear flow through defining pseudo-pressure and pseudo-time functions, which means to transform generalized mobility into a constant matrix; Otherwise, the problem cannot be transformed into a linear flow problem.

Let a function ƒ(t) be defined on [0,∞), then ƒ(t) is a real-valued function or a complex-valued function of a real variable t. The function

$$\overline{f} ( z ) = {\int }_{0}^{∞} f ( t ) {e}^{- zt} dt$$

determined by the Laplace integral

$${\int }_{0}^{∞} f ( t ) {e}^{- zt} dt$$

is called the Laplace transformation of the function ƒ(t). By applying the integral transformation above, the well testing models in embodiments 4, 6 and 8 to 12 can be transformed into homogeneous equation systems in Laplace space, which are used to obtain bottom hole pressure function solutions in Laplace space.

Let p̅_{wD}(z) be dimensionless bottom hole pressure solution function in Laplace space, then the real space dimensionless bottom hole pressure solution p_{wD}(t_{D}) can be obtained by Stehfest numerical inversion technique

$${p}_{wD} ( {t}_{D} ) = \frac{log 2}{{t}_{D}} {\sum }_{k = 1}^{N} ( {( - 1 )}^{\frac{N}{2} + k} {\sum }_{n = [ ( k + 1 ) / 2 ]}^{min ( k , N / 2 )} \frac{{n}^{N / 2} ( 2 n ) !}{( N / 2 - n ) ! n ! ( n - 1 ) ! ( k - n ) ! ( 2 n - k ) !} ) {\overline{p}}_{wD} ( k \frac{log 2}{{t}_{D}} )$$

where N is an even number, generally the value is between 8 and 16.

Other numerical inversion techniques can also be used here in addition to Stehfest numerical inversion technology.

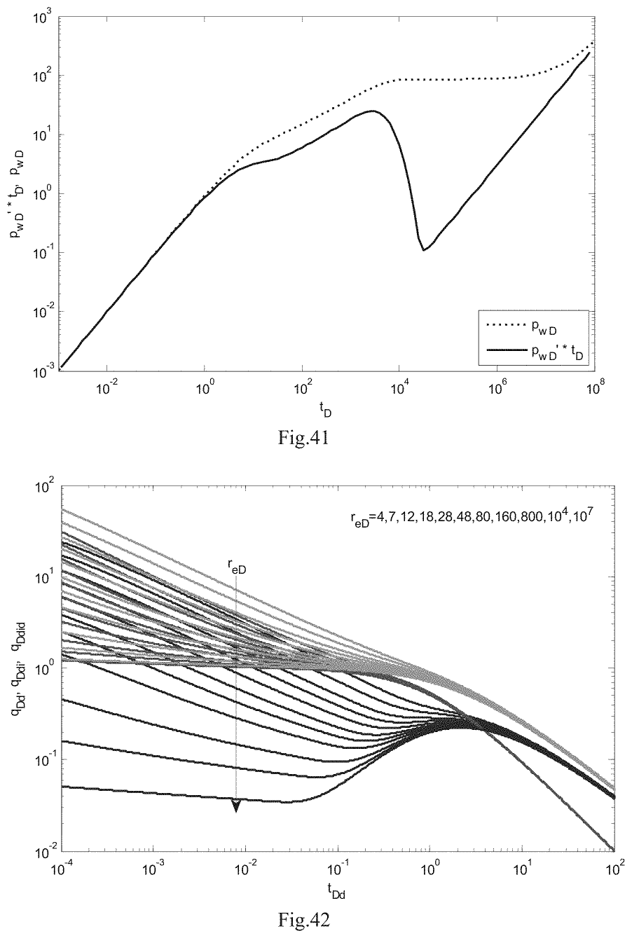

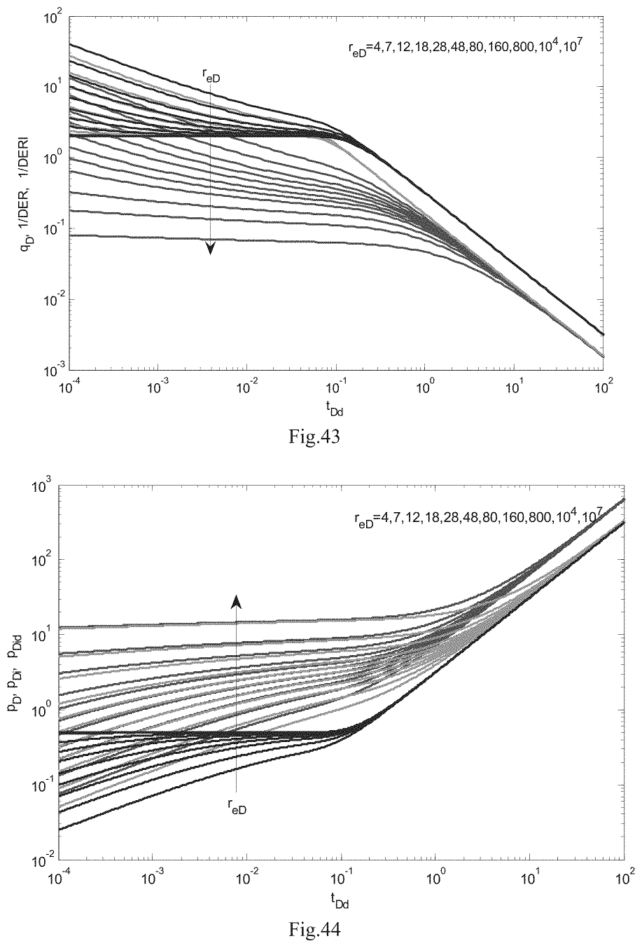

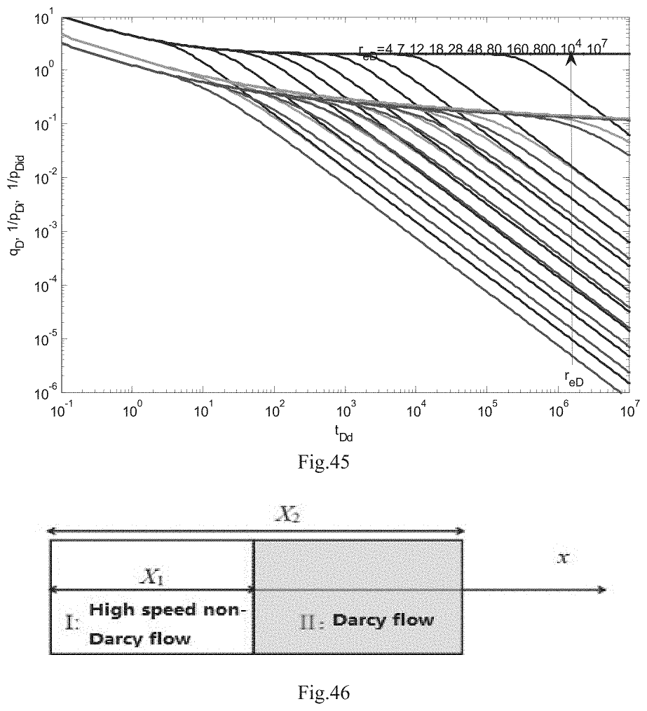

Embodiment of transient rate analysis (i.e., production data analysis) is shown in FIGS. 41 to 45. These figures are realized on the basis of a cylindrical reservoir model provided in embodiment 9 of this invention, which are vertical well Blasingame type curve, vertical well Agarwal-Gardner type curve, vertical well NPI type curve, and vertical well Transient type curve. Similarly, various kinds of analysis type curves of other analysis models can also be created. The basic principles of drawing type curves are detailed in the book “Modern production decline analysis methods for oil and gas wells and their application” written by Sun Hedong (2013).

For some layered reservoirs, the problem can be further simplified by defining the generalized flow coefficient or the equivalent transmissibility (Kh/μ) to facilitate the analysis and solution of some problems.

In addition, based on the above principle method, It can be similar to follow the traditional analytical model methods to establish the corresponding deliverability well test analysis, multi-well interference well test analysis, well test analysis method for wells in geothermal reservoirs and permanent downhole monitoring data analysis.

For example, with regard to the establishment of single-phase flow deliverability test analysis model method for steady-flow vertical wells in unsaturated layered reservoirs, the formula of production index is written as: follows:

$$J = \frac{q}{{P}_{e} - {P}_{wf}} - \frac{2 πλh}{B [ ln ( {r}_{e} / {r}_{w} ) + S ]}$$

B—Volume factor of the fluid, m³/m³; h—Reservoir thickness, m; pₑ-reservoir outer boundary pressure (average formation pressure of reservoir can be used in practical application), Pa; pwf-bottom hole flowing pressure, Pa; q—flow rate, m³/s; rₑ-outer radius of reservoir, m; r_{w}-wellbor radius, m S-skin factor; λ-generalized mobility of the reservoir fluid, m²/Pa·s.

### Embodiment 1

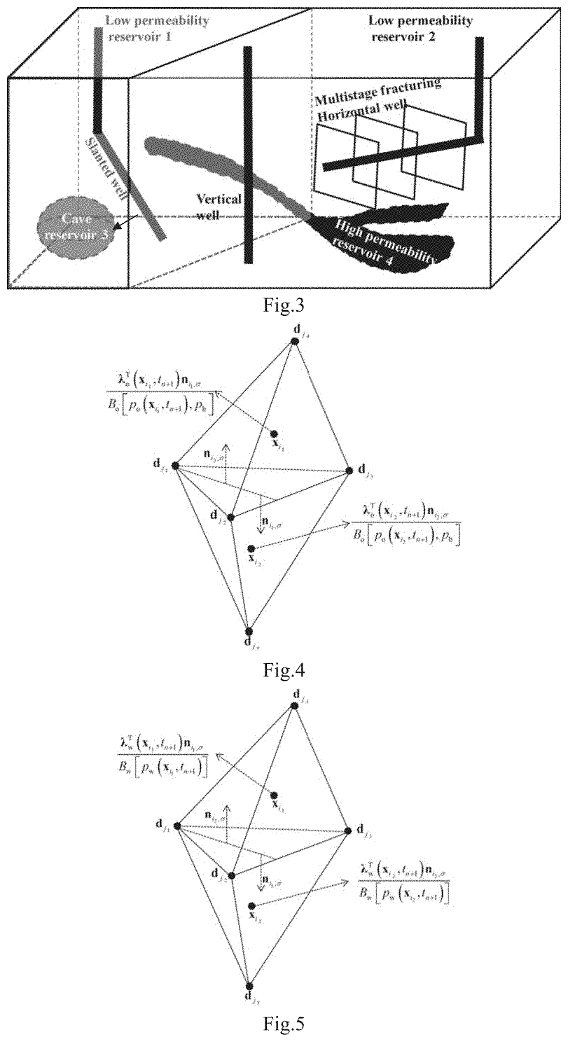

This embodiment provides a generalized oil/gas/water three-phase flow simulation analysis method for complex reservoirs. FIG. 3 is the physical model, which only denotes a special case of this embodiment.

Based on the mass conservation principle, the general equation of oil/gas/water three-phase flow can be established (Note: the volume factor is equal to the fluid density divided by the surface reference density and the surface reference density is a constant. Therefore, the two sides of the governing equation in the following examples can be converted into the fluid density by multiplying the surface reference density of each phase, respectively):

Oil phase governing equation considering source/sink term:

$$∇ \cdot [ \frac{1}{{B}_{o}} {λ}_{o} ∇ {p}_{o} ] = \frac{\partial }{\partial t} ( \frac{1}{{B}_{o}} {φ S}_{o} ) + \frac{{q}_{o}}{{ρ}_{osc}} , ( x , t ) ∈ Ω \times ( 0 , {t}_{max} ] \qquad ( 1 )$$

Water phase governing equation considering source/sink term:

$$∇ \cdot [ \frac{1}{{B}_{w}} {λ}_{w} ∇ {p}_{w} ] = \frac{\partial }{\partial t} ( \frac{1}{{B}_{w}} {φ S}_{w} ) + \frac{{q}_{w}}{{ρ}_{osc}} , ( x , t ) ∈ Ω \times ( 0 , {t}_{max} ] \qquad ( 2 )$$

Gas phase governing equation considering source/sink term:

$$∇ \cdot [ \frac{1}{{B}_{g}} {λ}_{g} {∇}_{g} ] + ∇ \cdot [ \frac{{R}_{g}}{{B}_{o}} {λ}_{o} ∇ {p}_{o} ] = \frac{\partial }{\partial t} ( \frac{1}{{B}_{g}} φ , {S}_{g} ) + \frac{{q}_{g}}{{ρ}_{gsc}} + \frac{\partial }{\partial t} ( \frac{{R}_{s}}{{B}_{o}} {φ S}_{o} ) , ( x , t ) ∈ Ω \times ( 0 , {t}_{max} ] \qquad ( 3 )$$

Auxiliary equations with saturation and capillary pressure:

Sₒ+S_{w}+S_{g}=1,(x,t)∈Ω×(0,tₘₐₓ] (4)

p_{cow}(S_{w})=pₒ−p_{w},(x,t)∈Ω×(0,tₘₐₓ] (5)

p_{cgo}(S_{w})=p_{g}−pₒ,(x,t)∈Ω×(0,tₘₐₓ] (6)

Boundary condition equations:

$$\begin{matrix}( {c}_{o , 1} {p}_{o} + {c}_{o , 2} {λ}_{o} \frac{\partial {p}_{o}}{\partial {n}^{\partial Ω}} ) = {g}_{o} ( x , t ) , ( x , t ) ∈ \partial Ω \times ( 0 , {t}_{max} ] & ( 7 ) \\ ( {c}_{w , 1} {p}_{w} + {c}_{w , 2} {λ}_{w} \frac{\partial {p}_{w}}{\partial {n}^{\partial Ω}} ) = {g}_{w} ( x , t ) , ( x , t ) ∈ \partial Ω \times ( 0 , {t}_{max} ] & ( 8 ) \\ ( {c}_{g , 1} {p}_{g} + {c}_{g , 2} {λ}_{g} \frac{\partial {p}_{g}}{\partial {n}^{\partial Ω}} ) = {g}_{g} ( x , t ) , ( x , t ) ∈ \partial Ω \times ( 0 , {t}_{max} ] & ( 9 )\end{matrix}$$

Initial condition equations:

Sₖ(x,0)=lₖ(x),x∈Ω (10)

pₖ(x,0)=ƒₖ(x),x∈Ω (11)

Where

Sₖ=Sₖ(x,t),k=o,w,g (12)

pₖ=pₖ(x,t),k=o,w,g (13)

qₖ=qₖ(x,t),k=o,w,g (14)

λₖ=λₖ(x,t),k=o,w,g (15)

ϕ is porosity, which is the function of average pressure p̅, %; B_{w}, Bₒ, B_{g} are volume factors of water/oil/gas, water volume factor is a function of water-phase pressure p_{w}, oil volume factor is a function of oil-phase pressure pₒ and bubble point pressure p_{b}, gas volume factor is a function of gas-phase pressure p_{g}, dimensionless; λ_{w}, λₒ, λ_{g} are generalized mobility for water/oil/gas, separately, m²/(Pa·s); ρ_{w}, ρₒ, ρ_{g} are densities of water/oil/gas, kg/m³; ρ_{o,o} is oil component density in oil-phase, kg/m³; ρ_{g,o} is gas component density in oil-phase, kg/m³; ρ_{wsc}, ρ_{osc}, ρ_{gsc} are surface reference densities of water/oil/gas, kg/m³; Rₛ is the dissolved gas-oil ratio, dimensionless; S_{w}, Sₒ, S_{g} are saturation of water/oil/gas; t is time, s; tₘₐₓ is the total time, s; p_{w}, pₒ, p_{g} are pressures of water/oil/gas, Pa; l_{w}, lₒ, l_{g} are distribution functions of water/oil/gas initial saturation; q_{w}, qₒ, q_{g} are source/sink terms of water/oil/gas, kg/(m³·s); ƒ_{w}, ƒₒ, ƒ_{g} are distribution functions of water/oil/gas initial pressure, Pa; g_{w}, gₒ, g_{g} are boundary functions of water/oil/gas on reservoir boundary, dimensionless; p_{cow}, p_{cgo} are capillary pressure of oil-water/gas-oil contact, Pa; Ω is reservoir space; ∂Ω is reservoir boundary including internal boundary and outer boundary; c_{w1}, c_{o,1}, c_{g,1} are pressure term coefficients of water/oil/gas on reservoir boundary, 1/Pa; c_{w,2}, c_{o,2}, c_{g,2} are respectively directional derivative coefficient of water, oil and gas along the normal direction outside the boundary on reservoir boundary condition, s/m; n^{∂Ω} is The direction of outer normal of reservoir boundary, m; ∇ is the Hamilton operator; ∂ is the partial derivative sign.

Problems can be optimized and discretely solved by applying the finite volume method. The following example of tetrahedral element is given to illustrate the process.

Firstly the region Ω is divided into a series of tetrahedrons Ωᵢ, which do not overlap each other. The control point of tetrahedrons Ωᵢ is marked as xᵢ and the boundary of tetrahedrons Ωᵢ is marked as ∂Ωᵢ. If the number of tetrahedrons that have a common surface with tetrahedrons Ωᵢ is 4, then xᵢ is called the internal control point, and the set of all internal control points is Ω_{I}. If the number of tetrahedrons that have a common surface with tetrahedrons is less than Ωᵢ then xᵢ is called the boundary control point, and the set of all boundary control points is called Ω_{B}.

Oil phase governing equation considering source/sink term is discretized as

$${\sum }_{σ ⋐ \partial {Ω}_{η}} {u}_{o , {i}_{2}} {a}_{o , {i}_{2}} {p}_{o} ( {x}_{{i}_{2}} , {t}_{n + 1} ) - {u}_{o , {i}_{1}} {a}_{o , {i}_{1}} {p}_{o} ( {x}_{{i}_{1}} , {i}_{n + 1} ) = {e}_{o , 2} {S}_{o} ( {x}_{{i}_{1}} , {i}_{n + 1} ) - {e}_{o , 1} {S}_{o} ( {x}_{{i}_{1}} , {t}_{n} ) + {V}_{{i}_{1}} \frac{{q}_{o} ( {x}_{{i}_{1}} , {t}_{n + 1} )}{{ρ}_{osc}} \qquad ( 16 )$$

Where xᵢ_{₁}∈Ω_{I}, xᵢ_{₂}∈Ω_{I} UΩ_{B}, and

$$\begin{matrix} {e}_{o , 1} = \frac{{V}_{{i}_{1}} φ [ \overline{p} ( {x}_{{i}_{1}} , {t}_{n} ) ]}{{B}_{o} [ {p}_{o} ( {x}_{{i}_{1}} , {t}_{n} ) , {p}_{b} ] ( {t}_{n + 1} - {t}_{n} )} & ( 17 ) \\ {e}_{o , 2} = \frac{{V}_{{i}_{1}} φ [ \overline{p} ( {x}_{{i}_{1}} , {t}_{n + 1} ) ]}{{B}_{o} [ {p}_{o} ( {x}_{{i}_{1}} , {t}_{n + 1} ) , {p}_{b} ] ( {t}_{n + 1} - {t}_{n} )} & ( 18 ) \\ {a}_{o , {i}_{1}} = {S}_{{i}_{1} , σ} ( {α}_{o , {i}_{1}} + {β}_{o , {i}_{1}} + {γ}_{o , {i}_{1}} ) & ( 19 ) \\ {α}_{o , {i}_{2}} = {S}_{{i}_{2} , σ} ( {α}_{o , {i}_{2}} + {β}_{o , {i}_{2}} + {γ}_{o , {i}_{2}} ) & ( 20 ) \\ {b}_{o , {i}_{1}} = {S}_{{i}_{1} , σ} [ {α}_{o , {i}_{1}} {p}_{o} ( {d}_{{j}_{1}} , {t}_{n + 1} ) + {β}_{o , {i}_{1}} {p}_{o} ( {d}_{{j}_{2}} , {t}_{n + 1} ) + {γ}_{o , {i}_{1}} {p}_{o} ( {d}_{{j}_{4}} , {t}_{n + 1} ) ] & ( 21 ) \\ {b}_{o , {i}_{2}} = {S}_{{i}_{2} , σ} [ {α}_{o , {i}_{2}} {p}_{o} ( {d}_{{j}_{2}} , {t}_{n + 1} ) + {β}_{o , {i}_{2}} {p}_{o} ( {d}_{{j}_{3}} , {t}_{n + 1} ) + {γ}_{o , {i}_{2}} {p}_{o} ( {d}_{{j}_{5}} , {t}_{n + 1} ) ] & ( 22 ) \\ {u}_{o , {i}_{1}} = \{ \begin{matrix}1 / 2 , & {b}_{o , {i}_{1}} + {b}_{o , {i}_{2}} = 0 \\ {b}_{o , {i}_{2}} / ( {b}_{o , {i}_{1}} + {b}_{o , {i}_{2}} ) , & {b}_{o , {i}_{1}} + {b}_{o , {i}_{2}} \neq 0\end{matrix} & ( 23 ) \\ {u}_{o , {i}_{2}} = \{ \begin{matrix}1 / 2 , & {b}_{o , {i}_{1}} + {b}_{o , {i}_{2}} = 0 \\ {b}_{o , {i}_{1}} / ( {b}_{o , {i}_{1}} + {b}_{o , {i}_{2}} ) , & {b}_{o , {i}_{1}} + {b}_{o , {i}_{2}} \neq 0\end{matrix} & ( 24 )\end{matrix}$$

The vertex pressures in the formulas [(21) and (22)] above are treated by the inverse distance weighting method, i. e,

$${p}_{o} ( {d}_{j} , {t}_{n + 1} ) = {\sum }_{i ∈ {D}_{j}} \frac{\vert \vert {d}_{j} - {x}_{i} {\vert \vert}_{2}^{l}}{{\sum }_{i ∈ {D}_{j}} \vert \vert {d}_{j} - {x}_{i} {\vert \vert}_{2}^{l}} {p}_{o} ( {x}_{i} , {t}_{n + 1} ) , j = {j}_{1} , {j}_{2} , {j}_{3} , {j}_{4} , {j}_{5} \qquad ( 25 )$$

Dⱼ denotes the number set of all discrete control body central points from the vertex dⱼ, l is a real number less than 0.

The coefficients α_{o,i}_{₁}, β_{o,i}_{₁}, γ_{o,i}_{₁} in the formulas [(19) and (21) above are determined by the following formula

$$\frac{{{λ}_{o}}^{T} ( {x}_{{i}_{1}} , {t}_{n + 1} ) {n}_{{i}_{1} , σ}}{{B}_{o} [ {p}_{o} ( {x}_{{i}_{1}} , {t}_{n + 1} ) , {p}_{b} ]} = {α}_{o , {i}_{1}} ( {d}_{{j}_{1}} - {x}_{{i}_{1}} ) + {β}_{o , {i}_{1}} ( {d}_{{j}_{2}} - {x}_{{i}_{1}} ) + {γ}_{o , {i}_{1}} ( {d}_{{j}_{4}} - {x}_{{i}_{1}} ) , {x}_{{i}_{1}} ∈ {Ω}_{i} \qquad ( 26 )$$

As shown in FIG. 4, the subscripts of vertices coordinates j₁, j₂, j₄, are intersected by a ray in the direction of

$$\frac{{{λ}_{o}}^{T} ( {x}_{{i}_{1}} , {t}_{n + 1} ) {n}_{{i}_{1} , σ}}{{B}_{o} [ {p}_{o} ( {x}_{{i}_{1}} , {t}_{n + 1} ) , {p}_{b} ]}$$

through the starting point xᵢ_{₁} with a sub-surface of the discrete control body Ωᵢ_{₁}. The three vertices coordinates of the sub-surface are dⱼ_{₁}, dⱼ_{₂}, dⱼ_{₄}, as shown in FIG. 4.

The coefficients α_{o,i}_{₂}, β_{o,i}_{₂}, γ_{o,i}_{₂} in the formulas Eq,20 and Eq.22 above are determined by the following formula

$$\frac{{{λ}_{o}}^{T} ( {x}_{{i}_{2}} , {t}_{n + 1} ) {n}_{{i}_{2} , σ}}{{B}_{o} [ {p}_{o} ( {x}_{{i}_{2}} , {t}_{n + 1} ) , {p}_{b} ]} = {α}_{o , {i}_{2}} ( {d}_{{j}_{2}} - {x}_{{i}_{2}} ) + {β}_{o , {i}_{2}} ( {d}_{{j}_{3}} - {x}_{{i}_{2}} ) + {γ}_{o , {i}_{2}} ( {d}_{{j}_{5}} - {x}_{{i}_{2}} ) \qquad ( 27 )$$

The subscripts of vertices coordinates j₂, j₃, j₅ are intersected by a ray in the direction of

$$\frac{{{λ}_{o}}^{T} ( {x}_{{i}_{2}} , {t}_{n + 1} ) {n}_{{i}_{2} , σ}}{{B}_{o} [ {p}_{o} ( {x}_{{i}_{2}} , {t}_{n + 1} ) , {p}_{b} ]}$$

through the starting point xᵢ_{₂} with a sub-surface of the discrete control body χᵢ_{₂}. The three vertices coordinates of the sub-surface are dⱼ_{₂}, dⱼ_{₃}, dⱼ_{₅}, as shown in FIG. 4.

Water phase governing equation considering source/sink term is discretized as

$${\sum }_{σ ⋐ \partial {Ω}_{η}} {u}_{w , {i}_{2}} {a}_{w , {i}_{2}} {p}_{w} ( {x}_{{i}_{2}} , {t}_{n + 1} ) - {u}_{w , {i}_{1}} {a}_{w , {i}_{1}} {p}_{w} ( {x}_{{i}_{1}} , {t}_{n + 1} ) = {e}_{w , 2} {S}_{w} ( {x}_{{i}_{1}} , {t}_{n + 1} ) - {e}_{w , 1} {S}_{w} ( {x}_{{i}_{1}} , {t}_{n} ) + {V}_{{i}_{1}} \frac{{q}_{w} ( {x}_{{i}_{1}} , {t}_{n + 1} )}{{ρ}_{wsc}} \qquad ( 28 )$$

Where xᵢ_{₁}∈Ω_{I},

$$\begin{matrix} {e}_{w , 1} = \frac{{V}_{{i}_{1}} φ [ \overline{p} ( {x}_{{i}_{1}} , {t}_{n} ) ]}{{B}_{w} [ {p}_{w} ( {x}_{{i}_{1}} , {t}_{n} ) ] ( {t}_{n + 1} - {t}_{n} )} & ( 29 ) \\ {e}_{w , 2} = \frac{{V}_{{i}_{1}} φ [ \overline{p} ( {x}_{{i}_{1}} , {t}_{n + 1} ) ]}{{B}_{w} [ {p}_{w} ( {x}_{{i}_{1}} , {t}_{n + 1} ) ] ( {t}_{n + 1} - {t}_{n} )} & ( 30 ) \\ {a}_{w , {i}_{1}} = {S}_{{i}_{1} , σ} ( {α}_{w , {i}_{1}} + {β}_{w , {i}_{1}} + {γ}_{w , {i}_{1}} ) & ( 31 ) \\ {α}_{w , {i}_{2}} = {S}_{{i}_{2} , σ} ( {α}_{w , {i}_{2}} + {β}_{w , {i}_{2}} + {γ}_{w , {i}_{2}} ) & ( 32 ) \\ {b}_{w , {i}_{1}} = {S}_{{i}_{1} , σ} [ {α}_{w , {i}_{1}} {p}_{w} ( {d}_{{j}_{1}} , {t}_{n + 1} ) + {β}_{w , {i}_{1}} {p}_{w} ( {d}_{{j}_{2}} , {t}_{n + 1} ) + {γ}_{w , {i}_{1}} {p}_{w} ( {d}_{{j}_{4}} , {t}_{n + 1} ) ] & ( 33 ) \\ {b}_{w , {i}_{2}} = {S}_{{i}_{2} , σ} [ {α}_{w , {i}_{2}} {p}_{w} ( {d}_{{j}_{2}} , {t}_{n + 1} ) + {β}_{w , {i}_{2}} {p}_{w} ( {d}_{{j}_{3}} , {t}_{n + 1} ) + {γ}_{w , {i}_{2}} {p}_{w} ( {d}_{{j}_{5}} , {t}_{n + 1} ) ] & ( 34 ) \\ {u}_{w , {i}_{1}} = \{ \begin{matrix}1 / 2 , & {b}_{w , {i}_{1}} + {b}_{w , {i}_{2}} = 0 \\ {b}_{w , {i}_{2}} / ( {b}_{w , {i}_{1}} + {b}_{w , {i}_{2}} ) , & {b}_{w , {i}_{1}} + {b}_{w , {i}_{2}} \neq 0\end{matrix} & ( 35 ) \\ {u}_{w , {i}_{2}} = \{ \begin{matrix}1 / 2 , & {b}_{w , {i}_{1}} + {b}_{w , {i}_{2}} = 0 \\ {b}_{o , {i}_{1}} / ( {b}_{w , {i}_{1}} + {b}_{w , {i}_{2}} ) , & {b}_{w , {i}_{1}} + {b}_{w , {i}_{2}} \neq 0\end{matrix} & ( 36 )\end{matrix}$$

The vertex pressures in the formulas Eq.37 and Eq.34 above are treated by the inverse distance weighting method, i. e,

$${p}_{w} ( {d}_{j} , {t}_{n + 1} ) = {\sum }_{i ∈ {D}_{j}} \frac{\vert \vert {d}_{j} - {x}_{i} {\vert \vert}_{2}^{l}}{{\sum }_{i ∈ {D}_{j}} \vert \vert {d}_{j} - {x}_{i} {\vert \vert}_{2}^{l}} {p}_{w} ( {x}_{i} , {t}_{n + 1} ) , j = {j}_{1} , {j}_{2} , {j}_{3} , {j}_{4} , {j}_{5} \qquad ( 37 )$$

Dⱼ denotes the number set of all discrete control body central points from the vertex dⱼ, l is a real number less than 0.

The coefficients α_{w,i}_{₁}, β_{w,i}_{₁}, γ_{w,i}_{₁} in the formulas [(31) and (33)] above are determined by the following formula

$$\frac{{λ}_{w}^{T} ( {ϰ}_{{i}_{1}} , {t}_{n + 1} ) {n}_{{i}_{1} , σ}}{{B}_{w} [ {p}_{w} ( {ϰ}_{{i}_{1}} , {t}_{n + 1} ) ]} = {α}_{w , {i}_{1}} ( {d}_{{j}_{1}} - {ϰ}_{{i}_{1}} ) + {β}_{w , {j}_{1}} ( {d}_{{j}_{2}} - {ϰ}_{{i}_{1}} ) + {γ}_{w , {j}_{1}} ( {d}_{{j}_{4}} - {ϰ}_{{i}_{1}} ) , {ϰ}_{{i}_{1}} ∈ {Ω}_{I} \qquad ( 38 )$$

The subscripts of vertices coordinates j₁, j₂, j₄ are intersected by a ray in the direction of

$$\frac{{λ}_{w}^{T} ( {ϰ}_{{i}_{1}} , {t}_{n + 1} ) {n}_{{i}_{1} , σ}}{{B}_{w} [ {p}_{w} ( {ϰ}_{{i}_{1}} , {t}_{n + 1} ) ]}$$

through the starting point xᵢ_{₁} with a sub-surface of the discrete control body Ωᵢ_{₁}. The three vertices coordinates of the sub-surface are dⱼ_{₁}, dⱼ_{₂}, dⱼ_{₄} as shown in FIG. 5.

The coefficients α_{w,i}_{₂}, β_{w,i}_{₂}, γ_{w,i}_{₂}, in the formulas [(32) and (34)] above are determined by the following formula

$$\frac{{λ}_{w}^{T} ( {ϰ}_{{i}_{2}} , {t}_{n + 1} ) {n}_{{i}_{2} , σ}}{{B}_{w} [ {p}_{w} ( {ϰ}_{{i}_{2}} , {t}_{n + 1} ) ]} = {α}_{w , {i}_{2}} ( {d}_{{j}_{2}} - {ϰ}_{{i}_{2}} ) + {β}_{w , {j}_{2}} ( {d}_{{j}_{3}} - {ϰ}_{{i}_{2}} ) + {γ}_{w , {i}_{2}} ( {d}_{{j}_{5}} - {ϰ}_{{i}_{2}} ) \qquad ( 39 )$$

The subscripts of vertices coordinates j₂, j₃, j₅ are intersected by a ray in the direction of

$$\frac{{λ}_{w}^{T} ( {ϰ}_{{i}_{2}} , {t}_{n + 1} ) {n}_{{i}_{2} , σ}}{{B}_{w} [ {p}_{w} ( {ϰ}_{{i}_{2}} , {t}_{n + 1} ) ]}$$

through the starting point xᵢ_{₂} with a sub-surface of the discrete control body Ωᵢ_{₂}. The three vertices coordinates of the sub-surface are dⱼ_{₂}, dⱼ_{₃}, dⱼ_{₅} as shown in FIG. 5.

Gas phase governing equation considering source/sink term (Eq.3) is discretized as

$${\sum }_{σ ⋐ \partial {Ω}_{{i}_{1}}} \{ \begin{matrix}{u}_{g , {i}_{2}} [ {a}_{g , {i}_{2}} {p}_{g} ( {ϰ}_{{i}_{2}} , {t}_{n + 1} ) + {a}_{o , {i}_{2}}^{′} {p}_{o} ( {ϰ}_{{i}_{2}} , {t}_{n + 1} ) ] - \\ {u}_{g , {i}_{1}} [ {a}_{g , {i}_{1}} {p}_{g} ( {ϰ}_{{i}_{1}} , {t}_{n + 1} ) + {a}_{o , {i}_{1}}^{′} {p}_{o} ( {ϰ}_{{i}_{1}} , {t}_{n + 1} ) ]\end{matrix} \} = [ \begin{matrix}{e}_{g , 2} {S}_{g} ( {ϰ}_{{t}_{1} , {t}_{n + 1}} ) - {e}_{g , 1} {S}_{g} ( {ϰ}_{{t}_{1}} , {t}_{n} ) + \\ {e}_{0 , 2}^{′} {S}_{0} ( {ϰ}_{{t}_{1}} , {t}_{n + 1} ) - {e}_{0 , 1}^{′} {S}_{0} ( {ϰ}_{{t}_{1}} , {t}_{n} )\end{matrix} ] + {V}_{{i}_{1}} \frac{{q}_{g} ( {ϰ}_{{i}_{1}} , {t}_{n + 1} )}{{ρ}_{gsc}} \qquad ( 40 )$$

Where xᵢ_{₁}∈Ω_{I},

$$\begin{matrix}{e}_{g , 1} = \frac{{V}_{{i}_{1}} φ [ \overline{p} ( {ϰ}_{{i}_{1}} , {t}_{n} ) ]}{{B}_{g} [ {p}_{g} ( {ϰ}_{{i}_{1}} , {t}_{n} ) ] ( {t}_{n + 1} - {t}_{n} )} & ( 41 ) \\ {e}_{g , 2} = \frac{{V}_{{i}_{1}} φ [ \overline{p} ( {ϰ}_{{i}_{1}} , {t}_{n + 1} ) ]}{{B}_{g} [ {p}_{g} ( {ϰ}_{{i}_{1}} , {t}_{n + 1} ) ] ( {t}_{n + 1} - {t}_{n} )} & ( 42 ) \\ {e}_{o , 1}^{′} = \frac{{V}_{{i}_{1}} φ [ \overline{p} ( {ϰ}_{{i}_{1}} , {t}_{n} ) ]}{{B}_{o} [ {p}_{o} ( {ϰ}_{{i}_{1}} , {t}_{n} ) , {p}_{b} ] ( {t}_{n + 1} - {t}_{n} )} & ( 43 ) \\ {e}_{o , 2}^{′} = \frac{{V}_{{i}_{1}} φ [ \overline{p} ( {ϰ}_{{i}_{1}} , {t}_{n} ) ]}{{B}_{o} [ {p}_{o} ( {ϰ}_{{i}_{1}} , {t}_{n + 1} ) , {p}_{b} ] ( {t}_{n + 1} - {t}_{n} )} & ( 44 ) \\ {a}_{g , {i}_{1}} = {S}_{{i}_{1} , σ} ( {α}_{g , {i}_{1}} + {β}_{g , {i}_{1}} + {γ}_{g , {i}_{1}} ) & ( 45 ) \\ {a}_{g , {i}_{2}} = {S}_{{i}_{2} , σ} ( {α}_{g , {i}_{2}} + {β}_{g , {i}_{2}} + {γ}_{g , {i}_{2}} ) & ( 46 ) \\ {a}_{o , {i}_{1}}^{′} = {S}_{{i}_{1} , σ} ( {α}_{o , {i}_{1}}^{′} + {β}_{o , {i}_{1}}^{′} + {γ}_{o , {i}_{1}}^{′} ) & ( 47 ) \\ {a}_{o , {i}_{2}}^{′} = {S}_{{i}_{2} , σ} ( {α}_{o , {i}_{2}}^{′} + {β}_{o , {i}_{2}}^{′} + {γ}_{o , {i}_{2}}^{′} ) & ( 48 ) \\ {b}_{g , {i}_{1}} = {S}_{{i}_{1} , σ} [ {α}_{g , {i}_{1}} {p}_{g} ( {d}_{{j}_{1}} , {t}_{n + 1} ) + {β}_{g , {i}_{1}} {p}_{g} ( {d}_{{j}_{3}} , {t}_{n + 1} ) + {γ}_{g , {i}_{1}} {p}_{g} ( {d}_{{j}_{1}} , {t}_{n + 1} ) ] & ( 49 ) \\ {b}_{g , {i}_{2}} = {S}_{{i}_{2} , σ} [ {α}_{g , {i}_{2}} {p}_{g} ( {d}_{{j}_{2}} , {t}_{n + 1} ) + {β}_{g , {i}_{2}} {p}_{g} ( {d}_{{j}_{3}} , {t}_{n + 1} ) + {γ}_{g , {i}_{2}} {p}_{g} ( {d}_{{j}_{5}} , {t}_{n + 1} ) ] & ( 50 ) \\ {b}_{o , {i}_{1}}^{′} = {S}_{{i}_{1} , σ} [ {α}_{o , {i}_{1}}^{′} {p}_{o} ( {d}_{{j}_{1}} , {t}_{n + 1} ) + {β}_{o , {i}_{1}}^{′} {p}_{o} ( {d}_{{j}_{2}} , {t}_{n + 1} ) + {γ}_{o , {i}_{1}}^{′} {p}_{o} ( {d}_{{j}_{4}} , {t}_{n + 1} ) ] & ( 51 ) \\ {b}_{o , {i}_{2}}^{′} = {S}_{{i}_{2} , σ} [ {α}_{o , {i}_{2}}^{′} {p}_{o} ( {d}_{{j}_{2}} , {t}_{n + 1} ) + {β}_{o , {i}_{2}}^{′} {p}_{o} ( {d}_{{j}_{3}} , {t}_{n + 1} ) + {γ}_{o , {i}_{2}}^{′} {p}_{o} ( {d}_{{j}_{5}} , {t}_{n + 1} ) ] & ( 52 ) \\ {u}_{g , {i}_{1}} = \{ \begin{matrix}1 / 2 , ( {b}_{g , {i}_{1}} + {b}_{o , {i}_{1}}^{′} ) + ( {b}_{g , {i}_{2}} + {b}_{o , {i}_{2}}^{′} ) = 0 \\ ( {b}_{g , {i}_{2}} + {b}_{o , {i}_{2}}^{′} ) / ( {b}_{g , {i}_{1}} + {b}_{o , {i}_{1}}^{′} + {b}_{g , {i}_{2}} + {b}_{o , {i}_{2}}^{′} ) , ( {b}_{g , {i}_{1}} + {b}_{o , {i}_{1}}^{′} ) + ( {b}_{g , {i}_{2}} + {b}_{o , {i}_{2}}^{′} ) \neq 0\end{matrix} & ( 53 ) \\ {u}_{g , {i}_{2}} = \{ \begin{matrix}1 / 2 , ( {b}_{g , {i}_{1}} + {b}_{o , {i}_{1}}^{′} ) + ( {b}_{g , {i}_{2}} + {b}_{o , {i}_{2}}^{′} ) = 0 \\ ( {b}_{g , {i}_{1}} + {b}_{o , {i}_{1}}^{′} ) / ( {b}_{g , {i}_{1}} + {b}_{o , {i}_{1}}^{′} + {b}_{g , {i}_{2}} + {b}_{o , {i}_{2}}^{′} ) , ( {b}_{g , {i}_{1}} + {b}_{o , {i}_{1}}^{′} ) + ( {b}_{g , {i}_{2}} + {b}_{o , {i}_{2}}^{′} ) \neq 0\end{matrix} & ( 54 )\end{matrix}$$

The vertex pressures in the formulas Eqs.49, 50, 51, 52 above are treated by the inverse distance weighting method, i.e,

$${p}_{g} ( {d}_{j} , {t}_{n + 1} ) = {\sum }_{i ∈ {D}_{j}}^{ } \frac{{‖ {d}_{j} - {ϰ}_{i} ‖}_{2}^{l}}{{\sum }_{i ∈ {D}_{j}}^{ } {‖ {d}_{j} - {ϰ}_{i} ‖}_{2}^{l}} {p}_{g} ( {ϰ}_{i} , {t}_{n + 1} ) , j = {j}_{1} , {j}_{2} , {j}_{3} , {j}_{4} , {j}_{5} \qquad ( 55 )$$

Dⱼ denotes the number set of all discrete control body central points from the vertex dⱼ, l is a real number less than 0.

The coefficients α_{o,i}_{₁}, β_{o,i}_{₁}, γ_{o,i}_{₁}, α_{o,i}_{₁}′, β_{o,i}_{₁}′, γ_{o,i}_{₁}′ in the formulas Eqs.45, 47, 49, 51 above are determined by the following formula

$$\begin{matrix}\frac{{λ}_{g}^{T} ( {ϰ}_{{i}_{1}} , {t}_{n + 1} ) {n}_{{i}_{1} , σ}}{{B}_{g} [ {p}_{g} ( {ϰ}_{{i}_{1}} , {t}_{n + 1} ) ]} = {α}_{g , {i}_{1}} ( {d}_{{j}_{1}} - {ϰ}_{{i}_{1}} ) + {β}_{g . {i}_{1}} ( {d}_{{j}_{3}} - {ϰ}_{{i}_{1}} ) + {γ}_{g , {i}_{1}} ( {d}_{{j}_{4}} - {ϰ}_{{i}_{1}} ) , {ϰ}_{{i}_{1}} ∈ {Ω}_{I} & ( 56 ) \\ \frac{{R}_{s} [ {p}_{o} ( {ϰ}_{{i}_{1}} , {t}_{n + 1} ) ] {λ}_{o}^{T} ( {ϰ}_{{i}_{1}} , {t}_{n + 1} ) {n}_{{i}_{1} , σ}}{{B}_{o} [ {p}_{o} ( {ϰ}_{{i}_{1}} , {t}_{n + 1} ) , {p}_{b} ]} = {α}_{o , {i}_{1}}^{′} ( {d}_{{j}_{1}} - {ϰ}_{{i}_{1}} ) + {β}_{o , {i}_{1}}^{′} ( {d}_{{j}_{2}} - {ϰ}_{{i}_{1}} ) + {γ}_{o , {i}_{1}}^{′} ( {d}_{{j}_{4}} - {ϰ}_{{i}_{1}} ) , {ϰ}_{{i}_{1}} ∈ {Ω}_{I} & ( 57 )\end{matrix}$$

The subscripts of vertices coordinates j₁, j₃, j₄ are intersected by a ray in the direction of

$$\frac{{λ}_{g}^{T} ( {ϰ}_{{i}_{1}} , {t}_{n + 1} ) {n}_{{i}_{1} , σ}}{{B}_{g} [ {p}_{g} ( {ϰ}_{{i}_{1}} , {t}_{n + 1} ) ]}$$

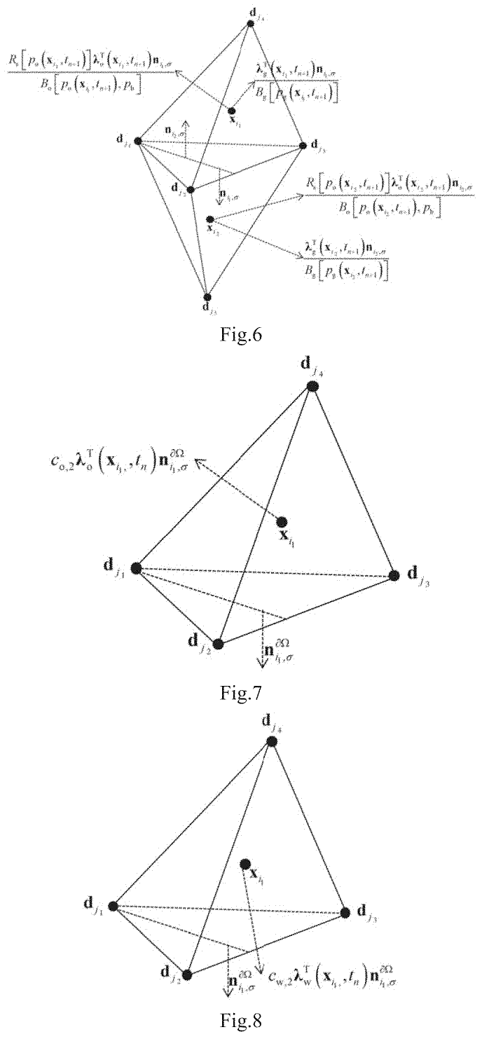

through the starting point xᵢ_{₁} with a sub-surface of the discrete control body Ωᵢ_{₁}. The three vertices coordinates of the sub-surface are dⱼ_{₁}, dⱼ_{₃}, dⱼ_{₄} as shown in FIG. 6. The subscripts of vertices coordinates j₁, j₂, j₄ are intersected by a ray in the direction of

$$\frac{{R}_{s} [ {p}_{o} ( {ϰ}_{{i}_{1}} , {t}_{n + 1} ) ] {λ}_{o}^{T} ( {ϰ}_{{i}_{1}} , {t}_{n + 1} ) {n}_{{i}_{1} , σ}}{{B}_{o} [ {p}_{o} ( {ϰ}_{{i}_{1}} , {t}_{n + 1} ) , {p}_{b} ]}$$

through the starting point xᵢ_{₁} with a sub-surface of the discrete control body Ωᵢ_{₁}. The three vertices coordinates of the sub-surface are dⱼ_{₁}, dⱼ_{₂}, dⱼ_{₄}, as shown in FIG. 6.

The coefficients α_{o,i}_{₂}, β_{o,i}_{₂}, γ_{o,i}_{₂}, α_{o,i}_{₂}′, β_{o,i}_{₂}′, γ_{o,i}_{₂}′, in the formulas [(46),(48),(50),(52)] above are determined by the following formula

$$\begin{matrix}\frac{{λ}_{g}^{T} ( {ϰ}_{{i}_{2}} , {t}_{n + 1} ) {n}_{{i}_{2} , σ}}{{B}_{g} [ {p}_{g} ( {ϰ}_{{i}_{2}} , {t}_{n + 1} ) ]} = {α}_{g , {i}_{2}} ( {d}_{{j}_{2}} - {ϰ}_{{i}_{2}} ) + {β}_{g . {i}_{2}} ( {d}_{{j}_{3}} - {ϰ}_{{i}_{2}} ) + {γ}_{g , {i}_{2}} ( {d}_{{j}_{5}} - {ϰ}_{{i}_{2}} ) & ( 58 ) \\ \frac{{R}_{s} [ {p}_{o} ( {ϰ}_{{i}_{2}} , {t}_{n + 1} ) ] {λ}_{o}^{T} ( {ϰ}_{{i}_{2}} , {t}_{n + 1} ) {n}_{{i}_{2} , σ}}{{B}_{o} [ {p}_{o} ( {ϰ}_{{i}_{2}} , {t}_{n + 1} ) , {p}_{b} ]} = {α}_{o , {i}_{2}}^{′} ( {d}_{{j}_{2}} - {ϰ}_{{i}_{2}} ) + {β}_{o , {i}_{1}}^{′} ( {d}_{{j}_{3}} - {ϰ}_{{i}_{2}} ) + {γ}_{o , {i}_{2}}^{′} ( {d}_{{j}_{5}} - {ϰ}_{{i}_{2}} ) & ( 59 )\end{matrix}$$

The subscripts of vertices coordinates j₂, j₃, j₅, are intersected by a ray in the direction of

$$\frac{{λ}_{g}^{T} ( {ϰ}_{{i}_{2}} , {t}_{n + 1} ) {n}_{{i}_{2} , σ}}{{B}_{g} [ {p}_{g} ( {ϰ}_{{i}_{2}} , {t}_{n + 1} ) ]}$$

through the starting point xᵢ_{₂} with a sub-surface of the discrete control body Ωᵢ_{₂}. The three vertices coordinates of the sub-surface are dⱼ_{₂}, dⱼ_{₃}, dⱼ_{₅}, as shown in FIG. 6. The subscripts of vertices coordinates j₂, j₃, j₅ are intersected by a ray in the direction of

$$\frac{{R}_{s} [ {p}_{o} ( {ϰ}_{{i}_{2}} , {t}_{n + 1} ) ] {λ}_{o}^{T} ( {ϰ}_{{i}_{2}} , {t}_{n + 1} ) {n}_{{i}_{2} , σ}}{{B}_{o} [ {p}_{o} ( {ϰ}_{{i}_{2}} , {t}_{n + 1} ) , {p}_{b} ]}$$

through the starting point xᵢ_{₂} with a sub-surface of the discrete control body Ωᵢ_{₂}. The three vertices coordinates of the sub-surface are dⱼ_{₂}, dⱼ_{₃}, dⱼ_{₅} as shown in FIG. 6.

Auxiliary equations Eq.4, 5, 6 with saturation and capillary pressure are discretized as

Sₒ(xᵢ_{₁},tₙ)+S_{w}(xₜ_{₁},tₙ)+S_{g}(xᵢ_{₁},tₙ)=1,xᵢ_{₁}∈Ω_{I}UΩ_{B} (60)

p_{cow}[S_{w}(xᵢ_{₁},tₙ)]=pₒ(xᵢ_{₁},tₙ)−p_{w}(xᵢ_{₁},tₙ),xᵢ_{₁}∈Ω_{I}UΩ_{B} (61)

p_{cgo}[S_{g}(xᵢ_{₁},tₙ)=p_{g}(xᵢ_{₁},tₙ)−pₒ(xᵢ_{₁},tₙ),xᵢ_{₁}∈Ω_{I}UΩ_{B} (62)

Oil phase boundary condition equation is discretized as

$$\begin{matrix}( {c}_{o , 1} - {α}_{o , {i}_{1}}^{\partial Ω} - {β}_{o , {i}_{1}}^{\partial Ω} - {γ}_{o , {i}_{1}}^{\partial Ω} ) {p}_{o} ( {ϰ}_{{i}_{1}} , {t}_{n} ) + {α}_{o , {i}_{1}}^{\partial Ω} {p}_{o} ( {d}_{{j}_{1}} , {t}_{n} ) + {β}_{o , {i}_{1}}^{\partial Ω} {p}_{o} ( {d}_{{j}_{2}} , {t}_{n} ) + {γ}_{o , {i}_{1}}^{\partial Ω} {p}_{o} ( {d}_{{j}_{4}} , {t}_{n} ) = {g}_{o} ( {ϰ}_{{i}_{1}} , {t}_{n} ) & ( 63 ) \\ {p}_{o} ( {d}_{j} , {t}_{n + 1} ) = {\sum }_{i ∈ {D}_{j}}^{ } \frac{{‖ {d}_{j} - {ϰ}_{i} ‖}_{2}^{l}}{{\sum }_{i ∈ {D}_{j}}^{ } {‖ {d}_{j} - {ϰ}_{i} ‖}_{2}^{l}} {p}_{o} ( {ϰ}_{i} , {t}_{n + 1} ) , j = {j}_{1} , {j}_{2} , {j}_{4} & ( 64 )\end{matrix}$$

Where xᵢ_{₁}∈Ω_{B}, Dⱼ denotes the number set of all discrete control body central points from the vertex dⱼ, l is a real number less than 0.

The coefficients α_{o,i}_{₁}^{∂Ω}, β_{o,i}_{₁}^{∂Ω}, γ_{o,i}_{₁}^{∂Ω} in the formulas above are determined by the formula below

c_{o,2}λₒ^{T}(xᵢ_{₁},tₙ)nᵢ_{₁}_{,σ}^{∂Ω}=α_{o,i}_{₁}^{∂Ω}(dⱼ_{₁}−xᵢ_{₁})+β_{o,i}_{₁}^{∂Ω}(dⱼ_{₂}−xᵢ_{₁})+γ_{o,i}_{₁}^{∂Ω}(dⱼ_{₄}−xᵢ_{₁}),xᵢ_{₁}∈Ω_{B} (65)

The subscripts of vertices coordinates j₁, j₂, j₄ are intersected by a ray in the direction of c_{o,2}λₒ^{T}(xᵢ_{₁},tₙ)nᵢ_{₁}_{,σ}^{∂Ω} and the starting point xᵢ_{₁} with a sub-surface of the discrete control body Ωᵢ_{₁}. The three vertices coordinates of the sub-surface are dⱼ_{₁}, dⱼ_{₂}, dⱼ_{₄} as shown in FIG. 7. Water phase boundary condition equation Eq.8 is discretized as

$$\begin{matrix}( {c}_{w , 1} - {α}_{w , {i}_{1}}^{\partial Ω} - {β}_{w , {i}_{1}}^{\partial Ω} - {γ}_{w , {i}_{1}}^{\partial Ω} ) {p}_{w} ( {ϰ}_{{i}_{1}} , {t}_{n} ) + {α}_{w , {i}_{1}}^{\partial Ω} {p}_{w} ( {d}_{{j}_{1}} , {t}_{n} ) + {β}_{w , {i}_{1}}^{\partial Ω} {p}_{w} ( {d}_{{j}_{2}} , {t}_{n} ) + {γ}_{w , {i}_{1}}^{\partial Ω} {p}_{w} ( {d}_{{j}_{3}} , {t}_{n} ) = {g}_{w} ( {ϰ}_{{i}_{1}} , {t}_{n} ) & ( 66 ) \\ {p}_{w} ( {d}_{j} , {t}_{n + 1} ) = {\sum }_{i ∈ {D}_{j}}^{ } \frac{{‖ {d}_{j} - {ϰ}_{i} ‖}_{2}^{l}}{{\sum }_{i ∈ {D}_{j}}^{ } {‖ {d}_{j} - {ϰ}_{i} ‖}_{2}^{l}} {p}_{w} ( {ϰ}_{i} , {t}_{n + 1} ) , j = {j}_{1} , {j}_{2} , {j}_{3} & ( 67 )\end{matrix}$$

Where xᵢ_{₁}∈ΩB, Dⱼ denotes the number set of all discrete control body central points from the vertex dⱼ, l is areal numberless than 0.

The coefficients α_{w,i}_{₁}^{∂Ω}, β_{w,i}_{₁}^{∂Ω}, γ_{w,i}_{₁}^{∂Ω} in the formula Eq.66 above are determined by the formula below

c_{w,2}λ_{w}^{T}(xᵢ_{₁},tₙ)nᵢ_{₁}_{,σ}^{∂Ω}=α_{w,i}_{₁}^{∂Ω}(dⱼ_{₁}−xᵢ_{₁})+β_{w,i}_{₁}^{∂Ω}(dⱼ_{₂}−xᵢ_{₁})+γ_{w,i}_{₁}^{∂Ω}(dⱼ_{₃}−xᵢ_{₁}),xᵢ_{₁}∈Ω_{B} (68)

The subscripts of vertices coordinates j₁, j₂, j₃ are intersected by a ray in the direction of c_{w,2}λ_{w}^{T}(xᵢ_{₁},tₙ)nᵢ_{₁}_{,σ}^{∂Ω} through the starting point xᵢ_{₁} with a sub-surface of the discrete control body Ωᵢ_{₁}. The three vertices coordinates of the sub-surface are dⱼ_{₁}, dⱼ_{₂}, dⱼ_{₃} as shown in FIG. 8.

Gas phase boundary condition equation is discretized as

$$\begin{matrix}( {c}_{g , 1} - {α}_{g , {i}_{1}}^{\partial Ω} - {β}_{g , {i}_{1}}^{\partial Ω} - {γ}_{g , {i}_{1}}^{\partial Ω} ) {P}_{g} ( {x}_{{i}_{1}} , {t}_{n} ) + {α}_{g , {i}_{1}}^{\partial Ω} {P}_{g} ( {d}_{{j}_{1}} , {t}_{n} ) + {β}_{g , {i}_{1}}^{\partial Ω} {P}_{g} ( {d}_{{j}_{2}} , {t}_{n} ) + {γ}_{g , {i}_{1}}^{\partial Ω} {P}_{g} ( {d}_{{j}_{4}} , {t}_{n} ) = {g}_{g} ( {x}_{{i}_{1}} , {t}_{n} ) & ( 69 ) \\ {P}_{g} ( {d}_{j} , {t}_{n + 1} ) = {\sum }_{i ∈ {D}_{j}} \frac{\vert \vert {d}_{j} - {x}_{i} {\vert \vert}_{2}^{l}}{{\sum }_{i ∈ {D}_{j}} \vert \vert {d}_{j} - {x}_{i} {\vert \vert}_{2}^{l}} {P}_{g} ( {x}_{i} , {t}_{n + 1} ) , j = {j}_{1} , {j}_{2} , {j}_{4} & ( 70 )\end{matrix}$$

Where xᵢ_{₁}∈Ω_{B}, Dⱼ denotes the number set of all discrete control body central points from the vertex dⱼ, l is a real number less than 0.

The coefficients α_{g,i}_{₁}^{∂Ω}, β_{g,i}_{₁}^{∂Ω}, γ_{g,i}_{₁}^{∂Ω} in the formula Eq.69 above are determined by the formula below

c_{g,2}λ_{g}^{T}(xᵢ_{₁},tₙ)nᵢ_{₁}_{,σ}^{∂Ω}=α_{g,i}_{₁}^{∂Ω}(dⱼ_{₁}−xᵢ_{₁})+β_{g,i}_{₁}^{∂Ω}(dⱼ_{₂}−xᵢ_{₁})+γ_{g,i}_{₁}^{∂Ω}(dⱼ_{₄}−xᵢ_{₁}),xᵢ_{₁}∈Ω_{B} (71)

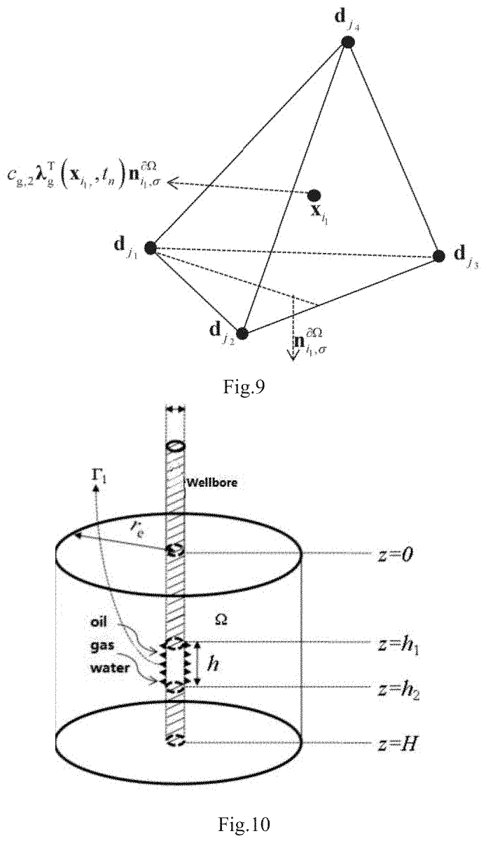

The subscripts of vertices coordinates j₁, j₂, j₄ are intersected by a ray in the direction of c_{g,2}λ_{g}^{T}(xᵢ_{₁},tₙ)nᵢ_{₁}_{,σ}^{∂Ω} through the starting point xᵢ_{₁} with a sub-surface of the discrete control body Ωᵢ_{₁}. The three vertices coordinates of the sub-surface are dⱼ_{₁}, dⱼ_{₂}, dⱼ_{₄} as shown in FIG. 9.

Initial condition equations Eqs.10 and 11 are discretized as

Sₒ(xᵢ_{₁},0)=lₒ(xᵢ_{₁}),xᵢ_{₁}∈Ω_{I}UΩ_{B} (72)

pₒ(xᵢ_{₁},0)=ƒₒ(xᵢ_{₁}),xᵢ_{₁}∈Ω_{I}UΩ_{B} (73)

S_{w}(xᵢ_{₁},0)=l_{w}(xᵢ_{₁}),xᵢ_{₁}∈Ω_{I}UΩ_{B} (74)

p_{w}(xᵢ_{₁},0)=ƒ_{w}(xᵢ_{₁}),xᵢ_{₁}∈Ω_{I}UΩ_{B} (75)

S_{g}(xᵢ_{₁},0)=l_{g}(xᵢ_{₁}),xᵢ_{₁}∈Ω_{I}UΩ_{B} (76)

p_{g}(xᵢ_{₁},0)=ƒ_{g}(xᵢ_{₁}),xᵢ_{₁}∈Ω_{I}UΩ_{B} (77)

Based on the above discrete control equations of oil, gas and water phase and the discrete boundary condition equations of oil, gas and water phase Eqs.16, 28, 40, 63, 66, 69, the following discrete equations are obtained

$$\{ \begin{matrix}\{ \begin{matrix}{\sum }_{σ ⋐ \partial {Ω}_{{i}_{1}}} {u}_{w , {i}_{2}} {a}_{w , {i}_{2}} {P}_{w} ( {x}_{{i}_{2}} , {t}_{n + 1} ) - {u}_{w , {i}_{1}} {a}_{w , {i}_{1}} {P}_{w} ( {x}_{{i}_{1}} , {t}_{n + 1} ) = {e}_{w , 2} {S}_{w} ( {x}_{{i}_{1}} , {t}_{n + 1} ) - {e}_{w , 1} {S}_{w} ( {x}_{{i}_{1}} , {t}_{n} ) + {V}_{{i}_{1}} \frac{{q}_{w} ( {x}_{{i}_{1}} , {t}_{n + 1} )}{{ρ}_{wsc}} , {x}_{{i}_{1}} ∈ {Ω}_{I} \\ ( {c}_{o , 1} - {α}_{o , {i}_{1}}^{\partial Ω} - {β}_{o , {i}_{1}}^{\partial Ω} - {γ}_{o , {i}_{1}}^{\partial Ω} ) {P}_{o} ( {x}_{{i}_{1}} , {t}_{n} ) + {α}_{o , {i}_{1}}^{\partial Ω} {P}_{o} ( {d}_{{j}_{1}} , {t}_{n} ) + {β}_{o , {i}_{1}}^{\partial Ω} {P}_{o} ( {d}_{{j}_{2}} , {t}_{n} ) + {γ}_{o , {i}_{1}}^{\partial Ω} {P}_{o} ( {d}_{{j}_{4}} , {t}_{n} ) = {g}_{o} ( {x}_{{i}_{1}} , {t}_{n} ) , {x}_{{i}_{1}} ∈ {Ω}_{B}\end{matrix} \\ \{ \begin{matrix}{\sum }_{σ ⋐ \partial {Ω}_{{i}_{1}}} {u}_{w , {i}_{2}} {a}_{w , {i}_{2}} {P}_{w} ( {x}_{{i}_{2}} , {t}_{n + 1} ) - {u}_{w , {i}_{1}} {a}_{w , {i}_{1}} {P}_{w} ( {x}_{{i}_{1}} , {t}_{n + 1} ) = {e}_{w , 2} {S}_{w} ( {x}_{{i}_{1}} , {t}_{n + 1} ) - {e}_{w , 1} {S}_{w} ( {x}_{{i}_{1}} , {t}_{n} ) + {V}_{{i}_{1}} \frac{{q}_{w} ( {x}_{{i}_{1}} , {t}_{n + 1} )}{{ρ}_{wsc}} , {x}_{{i}_{1}} ∈ {Ω}_{l} \\ ( {c}_{w , 1} - {α}_{w , {i}_{1}}^{\partial Ω} - {β}_{w , {i}_{1}}^{\partial Ω} - {γ}_{w , {i}_{1}}^{\partial Ω} ) {P}_{w} ( {x}_{{i}_{1}} , {t}_{n} ) + {α}_{w , {i}_{1}}^{\partial Ω} {P}_{w} ( {d}_{{j}_{1}} , {t}_{n} ) + {β}_{w , {i}_{1}}^{\partial Ω} {P}_{w} ( {d}_{{j}_{2}} , {t}_{n} ) + {γ}_{w , {i}_{1}}^{\partial Ω} {P}_{w} ( {d}_{{j}_{4}} , {t}_{n} ) = {g}_{w} ( {x}_{{i}_{1}} , {t}_{n} ) , {x}_{{i}_{1}} ∈ {Ω}_{B}\end{matrix} \\ \{ \begin{matrix}{\sum }_{σ ⋐ \partial {Ω}_{{i}_{1}}} \{ \begin{matrix}{u}_{g , {i}_{2}} [ {a}_{g , {i}_{2}} {P}_{g} ( {x}_{{i}_{2}} , {t}_{n + 1} ) + {a}_{o , {i}_{2}} {P}_{o} ( {x}_{{i}_{2}} , {t}_{n + 1} ) ] - \\ {u}_{g , {i}_{1}} [ {a}_{g , {i}_{1}} {P}_{g} ( {x}_{{i}_{1}} , {t}_{n + 1} ) + {a}_{o , {i}_{1}} {P}_{o} ( {x}_{{i}_{1}} , {t}_{n + 1} ) ]\end{matrix} \} = [ \begin{matrix}{e}_{g , 2} {S}_{g} ( {x}_{{i}_{1} , {t}_{n + 1}} ) - {e}_{g , 1} {S}_{g} ( {x}_{{i}_{1}} , {t}_{n} ) + \\ {e}_{o , 2} {S}_{o} ( {x}_{{i}_{1} , {t}_{n + 1}} ) - {e}_{o , 1} {S}_{o} ( {x}_{{i}_{1}} , {t}_{n} )\end{matrix} ] + {V}_{{i}_{1}} \frac{{q}_{g} ( {x}_{{i}_{1}} , {t}_{n + 1} )}{{ρ}_{gsc}} , {x}_{{i}_{1}} ∈ {Ω}_{f} \\ ( {c}_{g , 1} - {α}_{g , {i}_{1}}^{\partial Ω} - {β}_{g , {i}_{1}}^{\partial Ω} - {γ}_{g , {i}_{1}}^{\partial Ω} ) {P}_{g} ( {x}_{{i}_{1}} , {t}_{n} ) + {α}_{g , {i}_{1}}^{\partial Ω} {P}_{g} ( {d}_{{j}_{1}} , {t}_{n} ) + {β}_{g , {i}_{1}}^{\partial Ω} {P}_{g} ( {d}_{{j}_{2}} , {t}_{n} ) + {γ}_{g , {i}_{1}}^{\partial Ω} {P}_{g} ( {d}_{{j}_{4}} , {t}_{n} ) = {g}_{g} ( {x}_{{i}_{1}} , {t}_{n} ) , {x}_{{i}_{1}} ∈ {Ω}_{B }\end{matrix} \\ {S}_{o} ( {x}_{{i}_{1}} , {t}_{n} ) + {S}_{w} ( {x}_{{i}_{1}} , {t}_{n} ) + {S}_{g} ( {x}_{{i}_{1}} , {t}_{n} ) = 1 , {x}_{{i}_{1}} ∈ {Ω}_{I} {U Ω}_{B} \\ {P}_{cow} [ {S}_{w} ( {x}_{{i}_{1}} , {t}_{n} ) ] = {P}_{o} ( {x}_{{i}_{1}} , {t}_{n} ) - {P}_{w} ( {x}_{{i}_{1}} , {t}_{n} ) , {x}_{{i}_{1}} ∈ {Ω}_{I} {U Ω}_{B} \\ {P}_{cgo} [ {S}_{g} ( {x}_{{i}_{1}} , {t}_{n} ) ] = {P}_{g} ( {x}_{{i}_{1}} , {t}_{n} ) - {P}_{o} ( {x}_{{i}_{1}} , {t}_{n} ) , {x}_{{i}_{1}} ∈ {Ω}_{I} {U Ω}_{B}\end{matrix} \qquad ( 78 )$$

There are six unknowns pₒ, p_{w}, p_{g}, Sₒ, S_{w}, S_{g} to be found at any control point xᵢ_{₁} (xᵢ_{₁}∈Ω_{I}UΩ_{B}) in separating domain, and six equations are given by Eq.78 at any control point xᵢ_{₁}. Therefore, the equations system is complete. The equations can be solved by the Newton-raphson algorithm, which can further be applied to describe the pressure and saturation distribution of oil, gas and water at any time point in the solved region.

### Embodiment 2

This embodiment provides oil/gas/water three-phase flow simulation method through treating the wellbore as inner boundary for a partially open vertical well in a homogeneous reservoir. The physical model is shown in FIG. 10.

The general equation of oil/gas/water three-phase flow can be established by applying the mass conservation principle:

Oil phase governing equation:

$$∇ \cdot [ \frac{1}{{B}_{o}} {λ}_{o} ∇ {p}_{o} ] = \frac{\partial }{\partial t} ( \frac{1}{{B}_{o}} {φ S}_{o} ) , ( x , t ) ∈ Ω \times ( 0 , {t}_{max} ] \qquad ( 79 )$$

Water phase governing equation:

$$∇ \cdot [ \frac{1}{{B}_{w}} {λ}_{w} ∇ {p}_{w} ] = \frac{\partial }{\partial t} ( \frac{1}{{B}_{w}} {φ S}_{w} ) , ( x , t ) ∈ Ω \times ( 0 , {t}_{max} ] \qquad ( 80 )$$

Gas phase governing equation:

$$∇ \cdot [ \frac{1}{{B}_{g}} {λ}_{g} ∇ {p}_{g} ] + ∇ \cdot [ \frac{{R}_{s}}{{B}_{o}} {λ}_{o} ∇ {p}_{o} ] = \frac{\partial }{\partial t} ( \frac{1}{{B}_{g}} {φ S}_{g} ) + \frac{\partial }{\partial t} ( \frac{{R}_{s}}{{B}_{o}} {φ S}_{o} ) , ( x , t ) ∈ Ω \times ( 0 , {t}_{max} ] \qquad ( 81 )$$

Auxiliary equations with saturation and capillary pressure:

Sₒ+S_{w}+S_{g}=1,(x,t)∈Ω×(0,tₘₐₓ] (82)

p_{cow}(S_{w})=pₒ−p_{w}(x,t)∈Ω×(0,tₘₐₓ] (83)

p_{cgo}(S_{g})=p_{g}−pₒ(x,t)∈Ω×(0,tₘₐₓ] (84)

Boundary condition equations:

$$\begin{matrix}( {c}_{o , 1} {p}_{o} + {c}_{o , 2} {λ}_{o} \frac{\partial {p}_{o}}{\partial {n}^{\partial Ω}} ) = {g}_{o} ( x , t ) , ( x , t ) ∈ \partial Ω \times ( 0 , {t}_{max} ] & ( 85 ) \\ ( {c}_{w , 1} {p}_{w} + {c}_{w , 2} {λ}_{w} \frac{\partial {p}_{w}}{\partial {n}^{\partial Ω}} ) = {g}_{w} ( x , t ) , ( x , t ) ∈ \partial Ω \times ( 0 , {t}_{max} ] & ( 86 ) \\ ( {c}_{g , 1} {p}_{g} + {c}_{g , 2} {λ}_{g} \frac{\partial {p}_{g}}{\partial {n}^{\partial Ω}} ) = {g}_{g} ( x , t ) , ( x , t ) ∈ \partial Ω \times ( 0 , {t}_{max} ] & ( 87 )\end{matrix}$$

Initial condition equations:

Sₖ(x,0)=lₖ(x),x∈Ω (88)

pₖ(x,0)=ƒₖ(x),x∈Ω (89)

Where

$$\begin{matrix} {S}_{k} = {S}_{k} ( x , t ) , k = o , w , g & ( 90 ) \\ {p}_{k} = {p}_{k} ( x , t ) , k = o , w , g & ( 91 ) \\ {q}_{k} = {q}_{k} ( t ) , k = o , w , g & ( 92 ) \\ {λ}_{k} = [ \begin{matrix}{K}_{x} \frac{{K}_{Γ k}}{{μ}_{k}} & 0 & 0 \\ 0 & {K}_{y} \frac{{K}_{Γ k}}{{μ}_{k}} & 0 \\ 0 & 0 & {K}_{z} \frac{{K}_{Γ k}}{{μ}_{k}} ( 1 - {ρ}_{k} g \frac{\partial z}{\partial p} )\end{matrix} ] , k = o , w , g ; ( x , t ) ∈ Ω \times ( 0 , {t}_{max} ] & ( 93 ) \\ {c}_{k , 1} = 0 , k = o , w , g ; ( x , t ) ∈ \partial Ω \times ( 0 , {t}_{max} ] & ( 94 ) \\ {c}_{k , 2} = \{ \begin{matrix}- 2 {π r}_{w} h , & ( x , t ) ∈ {Γ}_{1} \times ( 0 , {t}_{max} ] \\ 1 , & ( x , t ) ∈ {Γ}_{2} \times ( 0 , {t}_{max} ]\end{matrix} , k = o , w , g & ( 95 ) \\ {g}_{k} ( x , t ) = \{ \begin{matrix}{q}_{k} ( t ) , & ( x , t ) ∈ {Γ}_{1} \times ( 0 , {t}_{max} ] \\ 0 , & ( x , t ) ∈ {Γ}_{2} \times ( 0 , {t}_{max} ]\end{matrix} , k = o , w , g & ( 96 ) \\ \partial Ω = {Γ}_{1} {U Γ}_{2} & ( 97 ) \\ {Γ}_{1} = \{ ( x , y , z ) \vert {x}^{2} + {y}^{2} = {r}_{w}^{2} , {h}_{1} \leq z \leq {h}_{2} \} & ( 98 ) \\ {Γ}_{2} = \{ ( x , y , z ) \vert {x}^{2} + {y}^{2} = {r}_{w}^{2} , 0 \leq z < {h}_{1} , {h}_{2} < z \leq H \} U \{ ( x , y , z ) \vert {x}^{2} + {y}^{2} < {r}_{w}^{2} , z = {h}_{1} or {h}_{2} \} U \{ ( x , y , z ) \vert {x}^{2} + {y}^{2} = {r}_{e}^{2} , 0 \leq z \leq H \} U \{ ( x , y , z ) \vert {r}_{w}^{2} < {x}^{2} + {y}^{2} < {r}_{e}^{2} , z = 0 or H \} & ( 99 )\end{matrix}$$

### Embodiment 3

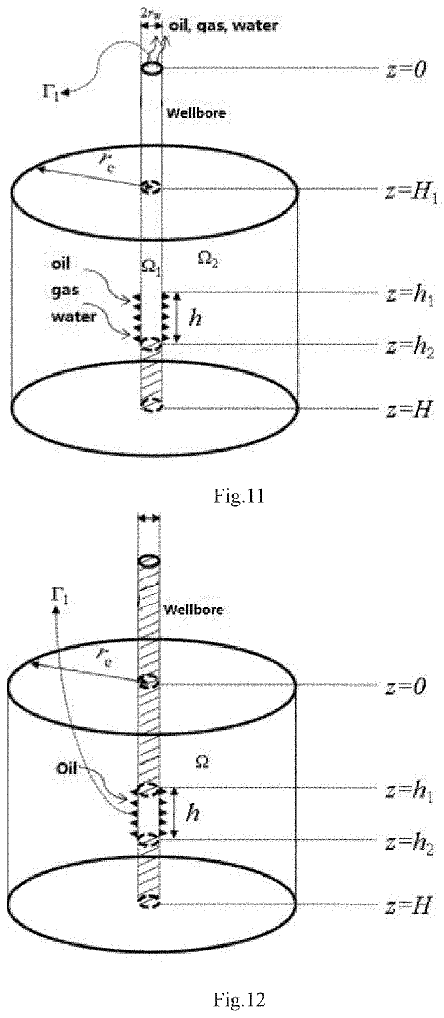

The embodiment provides oil/gas/water three-phase flow simulation method through treating the wellbore as reservoir for a partially open vertical well in a homogeneous reservoir. The physical model is shown in FIG. 11.

The general equation of oil/gas/water three-phase flow can be established by applying the mass conservation principle:

Oil phase governing equation:

$$∇ \cdot [ \frac{1}{{B}_{o}} {λ}_{o} ∇ {p}_{o} ] = \frac{\partial }{\partial t} ( \frac{1}{{B}_{o}} {φ S}_{o} ) , ( x , t ) ∈ Ω \times ( 0 , {t}_{max} ] \qquad ( 100 )$$

Water phase governing equation:

$$∇ \cdot [ \frac{1}{{B}_{w}} {λ}_{w} ∇ {p}_{w} ] = \frac{\partial }{\partial t} ( \frac{1}{{B}_{w}} {φ S}_{w} ) , ( x , t ) ∈ Ω \times ( 0 , {t}_{max} ] \qquad ( 101 )$$

Gas phase governing equation:

$$∇ \cdot [ \frac{1}{{B}_{g}} {λ}_{g} ∇ {p}_{g} ] + ∇ \cdot [ \frac{{R}_{s}}{{B}_{o}} {λ}_{o} ∇ {p}_{o} ] = \frac{\partial }{\partial t} ( \frac{1}{{B}_{g}} {φ S}_{g} ) + \frac{\partial }{\partial t} ( \frac{{R}_{s}}{{B}_{o}} {φ S}_{o} ) , ( x , t ) ∈ Ω \times ( 0 , {t}_{max} ] \qquad ( 102 )$$

Auxiliary equations with saturation and capillary pressure:

Sₒ+S_{w}+S_{g}=1,(x,t)∈Ω×(0,tₘₐₓ) (103)

p_{cow}(S_{w})=pₒ−p_{w}(x,t)∈Ω×(0,tₘₐₓ) (104)

p_{cgo}(S_{g})=p_{g}-pₒ,(x,t)∈Ω×(0,tₘₐₓ] (105)

Boundary condition equations:

$$\begin{matrix}( {c}_{o , 1} {p}_{o} + {c}_{o , 2} {λ}_{o} \frac{\partial {p}_{o}}{\partial {n}^{\partial Ω}} ) = {g}_{o} ( x , t ) , ( x , t ) ∈ \partial Ω \times ( 0 , {t}_{max} ] & ( 106 ) \\ ( {c}_{w , 1} {p}_{w} + {c}_{w , 2} {λ}_{w} \frac{\partial {p}_{w}}{\partial {n}^{\partial Ω}} ) = {g}_{w} ( x , t ) , ( x , t ) ∈ \partial Ω \times ( 0 , {t}_{max} ] & ( 107 ) \\ ( {c}_{g , 1} {p}_{g} + {c}_{g , 2} {λ}_{g} \frac{\partial {p}_{g}}{\partial {n}^{\partial Ω}} ) = {g}_{g} ( x , t ) , ( x , t ) ∈ \partial Ω \times ( 0 , {t}_{max} ] & ( 108 )\end{matrix}$$

Initial condition equations:

Sₖ(x,0)=lₖ(x),x∈Ω (109)

pₖ(x,0)=ƒₖ(x),x∈Ω (110)

Where

$$\begin{matrix} {S}_{k} = {S}_{k} ( x , t ) , k = o , w , g & ( 111 ) \\ {p}_{k} = {p}_{k} ( x , t ) , k = o , w , g & ( 112 ) \\ {q}_{k} = {q}_{k} ( t ) , k = o , w , g & ( 113 ) \\ {λ}_{k} = \{ \begin{matrix}[ \begin{matrix}{K}_{{x}_{1}} \frac{{K}_{Γ k}}{{μ}_{k}} & 0 & 0 \\ 0 & {K}_{{y}_{1}} \frac{{K}_{Γ k}}{{μ}_{k}} & 0 \\ 0 & 0 & {K}_{{z}_{1}} \frac{{K}_{Γ k}}{{μ}_{k}} ( 1 - {ρ}_{k} g \frac{\partial z}{\partial p} )\end{matrix} ] , ( x , t ) ∈ {Ω}_{1} \times ( 0 , {t}_{max} ] \\ [ \begin{matrix}{K}_{{x}_{2}} \frac{{K}_{Γ k}}{{μ}_{k}} & 0 & 0 \\ 0 & {K}_{{y}_{2}} \frac{{K}_{Γ k}}{{μ}_{k}} & 0 \\ 0 & 0 & {K}_{{z}_{2}} \frac{{K}_{Γ k}}{{μ}_{k}} ( 1 - {ρ}_{k} g \frac{\partial z}{\partial p} )\end{matrix} ] , ( x , t ) ∈ {Ω}_{2} \times ( 0 , {t}_{max} ]\end{matrix} , k = o , w , g & ( 114 ) \\ {c}_{k , 1} = 0 , k = o , w , g ; ( x , t ) ∈ \partial Ω \times ( 0 , {t}_{max} ] & ( 115 ) \\ {c}_{k , 2} = \{ \begin{matrix}- {π r}_{w} h , & ( x , t ) ∈ {Γ}_{1} \times ( 0 , {t}_{max} ] \\ 1 , & ( x , t ) ∈ {Γ}_{2} \times ( 0 , {t}_{max} ]\end{matrix} , k = o , w , g & ( 116 ) \\ {g}_{k} ( x , t ) = \{ \begin{matrix}{q}_{k} ( t ) , & ( x , t ) ∈ {Γ}_{1} \times ( 0 , {t}_{max} ] \\ 0 , & ( x , t ) ∈ {Γ}_{2} \times ( 0 , {t}_{max} ]\end{matrix} , k = o , w , g & ( 117 ) \\ Ω = {Ω}_{1} {U Ω}_{2} & ( 118 ) \\ {Ω}_{1} = \{ ( x , y , z ) \vert {x}^{2} + {y}^{2} \leq {r}_{w}^{2} , 0 < z < {h}_{2} \} & ( 119 ) \\ {Ω}_{2} = \{ ( x , y , z ) \vert {r}_{w}^{2} < {x}^{2} + {y}^{2} < {r}_{e}^{2} , {H}_{1} < z < H \} & ( 120 ) \\ \partial Ω = {Γ}_{1} {U Γ}_{2} & ( 121 ) \\ {Γ}_{1} = \{ ( x , y , z ) \vert {x}^{2} + {y}^{2} \leq {r}_{w}^{2} , z = 0 \} & ( 122 ) \\ {Γ}_{2} = \{ ( x , y , z ) \vert {x}^{2} + {y}^{2} = {r}_{w}^{2} , 0 < z < {h}_{1} , {h}_{2} < z \leq H \} U \{ ( x , y , z ) \vert {x}^{2} + {y}^{2} \leq {r}_{w}^{2} , z = {h}_{1} \} U \{ ( x , y , z ) \vert {x}^{2} + {y}^{2} = {r}_{e}^{2} , {H}_{1} \leq z \leq H \} U \{ ( x , y , z ) \vert {r}_{w}^{2} < {x}^{2} + {y}^{2} < {r}_{e}^{2} , z = {H}_{1} or H \} & ( 123 )\end{matrix}$$

### Embodiment 4

This embodiment provides oil phase flow simulation method through treating the wellbore as inner boundary for a partially open vertical well in a homogeneous reservoir. The physical model is shown in FIG. 12.

The general equation of oil phase flow can be established by applying the mass conservation principle:

Oil phase governing equation:

$$∇ \cdot [ \frac{1}{{B}_{o}} {λ}_{o} ∇ {p}_{o} ] = \frac{\partial }{\partial t} ( \frac{1}{{B}_{o}} {φ S}_{o} ) , ( x , t ) ∈ Ω \times ( 0 , {t}_{max} ] \qquad ( 124 )$$

Boundary condition equation:

$$( {c}_{o , 1} {p}_{o} + {c}_{o , 2} {λ}_{o} \frac{\partial {p}_{o}}{\partial {n}^{\partial Ω}} ) = {g}_{o} ( x , t ) , ( x , t ) ∈ \partial Ω \times ( 0 , {t}_{max} ] \qquad ( 125 )$$

Initial condition equation:

pₒ(x,0)=ƒₒ(x),x∈Ω (126)

Where

$$\begin{matrix} {p}_{o} = {p}_{o} ( x , t ) & ( 127 ) \\ {q}_{o} = {q}_{o} ( t ) & ( 128 ) \\ {λ}_{o} = \frac{1}{μ} [ \begin{matrix}{K}_{Γ} & 0 & 0 \\ 0 & {K}_{Γ} & 0 \\ 0 & 0 & {K}_{z}\end{matrix} ] , ( x , t ) ∈ Ω \times ( 0 , {t}_{max} ] & ( 129 ) \\ {c}_{o , 1} = 0 , ( x , t ) ∈ \partial Ω \times ( 0 , {t}_{max} ] & ( 130 ) \\ {c}_{o , 2} = \{ \begin{matrix}- 2 {π r}_{w} h , & ( x , t ) ∈ {Γ}_{1} \times ( 0 , {t}_{max} ] \\ 1 , & ( x , t ) ∈ {Γ}_{2} \times ( 0 , {t}_{max} ]\end{matrix} & ( 131 ) \\ {g}_{o} ( x , t ) = \{ \begin{matrix}{q}_{o} , & ( x , t ) ∈ {Γ}_{1} \times ( 0 , {t}_{max} ] \\ 0 , & ( x , t ) ∈ {Γ}_{2} \times ( 0 , {t}_{max} ]\end{matrix} & ( 132 ) \\ \partial Ω = {Γ}_{1} {U Γ}_{2} & ( 133 ) \\ {Γ}_{1} = \{ ( x , y , z ) \vert {x}^{2} + {y}^{2} = {r}_{w}^{2} , {h}_{1} \leq z \leq {h}_{2} \} & ( 134 ) \\ {Γ}_{2} = \{ ( x , y , z ) \vert {x}^{2} + {y}^{2} = {r}_{w}^{2} , 0 \leq z < {h}_{1} , {h}_{2} < z \leq H \} U \{ ( x , y , z ) \vert {x}^{2} + {y}^{2} < {r}_{w}^{2} , z = {h}_{1} or {h}_{2} \} U \{ ( x , y , z ) \vert {x}^{2} + {y}^{2} = {r}_{e}^{2} , 0 \leq z \leq H \} U \{ ( x , y , z ) \vert {r}_{w}^{2} < {x}^{2} + {y}^{2} < {r}_{e}^{2} , z = 0 or H \} & ( 135 )\end{matrix}$$

### Embodiment 5

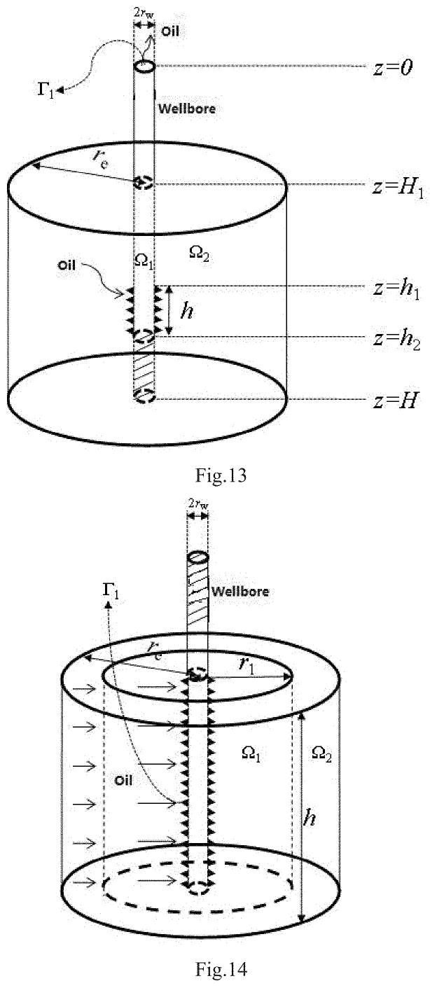

This embodiment provides oil phase flow simulation method through treating the wellbore as reservoir for a partially open vertical well in a homogeneous reservoir. The physical model is shown in FIG. 13.

The general equation of oil phase flow can be established by applying the mass conservation principle:
Oil phase governing equation:

$$∇ \cdot [ \frac{1}{{B}_{o}} {λ}_{o} ∇ {p}_{o} ] = \frac{\partial }{\partial t} ( \frac{1}{{B}_{o}} φ ) , ( x , t ) ∈ Ω \times ( 0 , {t}_{max} ] \qquad ( 136 )$$

Boundary condition Equation:

$$( {c}_{o , 1} {p}_{o} + {c}_{o , 2} {λ}_{o} \frac{\partial {p}_{o}}{\partial {n}^{\partial Ω}} ) = {g}_{o} , ( x , t ) , ( x , t ) ∈ Ω \times ( 0 , {t}_{max} ] \qquad ( 137 )$$

Initial condition equation:

pₒ(x,0)=ƒₒ(x),x∈Ω (138)

where

$$\begin{matrix} {p}_{o} = {p}_{o} ( x , t ) & ( 139 ) \\ {q}_{o} = {q}_{o} ( t ) & ( 140 ) \\ {λ}_{o} = \{ \begin{matrix}\frac{1}{μ} [ \begin{matrix} & & & \\ {K}_{{r}_{1}} & 0 & & 0 \\ 0 & {K}_{{r}_{2}} & & 0 \\ 0 & 0 & {K}_{{z}_{1}} & ( 1 - {ρ}_{o} g \frac{\partial z}{\partial p} )\end{matrix} ] , & ( x , t ) ∈ {Ω}_{1} \times ( 0 , {t}_{max} ] \\ \frac{1}{μ} [ \begin{matrix}{K}_{{r}_{2}} & 0 & 0 \\ 0 & {K}_{{r}_{2}} & 0 \\ 0 & 0 & {K}_{{z}_{2}}\end{matrix} ] , & ( x , t ) ∈ {Ω}_{2} \times ( 0 , {t}_{max} ]\end{matrix} & ( 141 ) \\ {c}_{o , 1} ≡ 0 , ( x , t ) ∈ Ω \times ( 0 , {t}_{max} ] & ( 142 ) \\ {c}_{o , 2} = \{ \begin{matrix}- π {r}_{w}^{2} , & ( x , t ) ∈ {Γ}_{1} \times ( 0 , {t}_{ma x} ] \\ 1 , & ( x , t ) ∈ {Γ}_{2} \times ( 0 , {t}_{max} ]\end{matrix} & ( 143 ) \\ {g}_{o} ( x , t ) = \{ \begin{matrix}q , & ( x , t ) ∈ {Γ}_{1} \times ( 0 , {t}_{max} ] \\ 0 , & ( x , t ) ∈ {Γ}_{2} \times ( 0 , {t}_{max} ]\end{matrix} & ( 144 ) \\ Ω = {Ω}_{1} U {Ω}_{2} & ( 145 ) \\ {Ω}_{1} = \{ ( x , y , z ) \vert {x}^{2} + {y}^{2} \leq {r}_{w}^{2} , 0 < z < H \} & ( 146 ) \\ {Ω}_{2} = \{ ( x , y , z ) \vert {r}_{w}^{2} < {x}^{2} + {y}^{2} < {r}_{e}^{2} , {H}_{1} < z < H \} & ( 147 ) \\ \partial Ω = {Γ}_{1} U {Γ}_{2} & ( 148 ) \\ {Γ}_{1} = \{ ( x , y , z ) \vert {x}^{2} + {y}^{2} \leq {r}_{w}^{2} , z = 0 \} & ( 149 ) \\ {Γ}_{2} = \{ ( x , y , z ) \vert {x}^{2} + {y}^{2} = {r}_{w}^{2} , 0 < z < {h}_{1} , {h}_{2} < z \leq H \} \\ U \{ ( x , y , z ) \vert {x}^{2} + {y}^{2} \leq {r}_{w}^{2} , z = {h}_{2} \} \\ U \{ ( x , y , z ) \vert {x}^{2} + {y}^{2} = {r}_{e}^{2} , {H}_{1} \leq z \leq H \} \\ U \{ ( x , y , z ) \vert {r}_{w}^{2} < {x}^{2} + {y}^{2} < {r}_{e}^{2} , z = {H}_{1} or H \} & ( 150 )\end{matrix}$$

### Embodiment 6

This embodiment provides oil phase flow simulation method through treating the wellbore as inner boundary for a fully open vertical well in a homogeneous radial 2-zone composite reservoir. The physical model is shown in FIG. 14.

The general equation of oil phase flow can be established by applying the mass conservation principle:
Oil phase governing equation:

$$∇ \cdot [ \frac{1}{{B}_{o}} {λ}_{o} ∇ {p}_{o} ] = \frac{\partial }{\partial t} ( \frac{1}{{B}_{o}} {φS}_{o} ) , ( x , t ) ∈ Ω \times ( 0 , {t}_{max} ] \qquad ( 151 )$$

Boundary condition equation:

$$( {c}_{o , 1} {p}_{o} + {c}_{o , 2} {λ}_{o} \frac{\partial {p}_{o}}{\partial {n}^{\partial Ω}} ) = {g}_{o} , ( x , t ) , ( x , t ) ∈ Ω \times ( 0 , {t}_{max} ] \qquad ( 152 )$$

Initial condition equation:

pₒ(x,0)=ƒₒ(x),x∈Ω (153)

Where

$$\begin{matrix}{p}_{o} = {p}_{o} ( x , t ) & ( 154 ) \\ {q}_{o} = {q}_{o} ( t ) & ( 155 ) \\ {λ}_{o} = \{ \begin{matrix}\frac{1}{{μ}_{1}} [ \begin{matrix}{K}_{r 1} & 0 \\ 0 & {K}_{r 1}\end{matrix} ] , & ( x , t ) ∈ {Ω}_{1} \times ( 0 , {t}_{max} ] \\ \frac{1}{{μ}_{2}} [ \begin{matrix}{K}_{r 2} & 0 \\ 0 & {K}_{r 2}\end{matrix} ] , & ( x , t ) ∈ {Ω}_{2} \times ( 0 , {t}_{max} ]\end{matrix} & ( 156 ) \\ {c}_{o , 1} ≡ 0 , ( x , t ) ∈ Ω \times ( 0 , {t}_{max} ] & ( 157 ) \\ {c}_{o , 2} = \{ \begin{matrix}- 2 π {r}_{w} h , & ( x , t ) ∈ {Γ}_{1} \times ( 0 , {t}_{max} ] \\ 1 , & ( x , t ) ∈ {Γ}_{2} \times ( 0 , {t}_{max} ]\end{matrix} & ( 158 ) \\ {g}_{o} ( x , t ) = \{ \begin{matrix}q , & ( x , t ) ∈ {Γ}_{1} \times ( 0 , {t}_{max} ] \\ 0 , & ( x , t ) ∈ {Γ}_{2} \times ( 0 , {t}_{max} ]\end{matrix} & ( 159 ) \\ Ω = {Ω}_{1} U {Ω}_{2} & ( 160 ) \\ {Ω}_{1} = \{ ( x , y ) \vert {r}_{w}^{2} < {x}^{2} + {y}^{2} \leq {r}_{1}^{2} \} & ( 161 ) \\ {Ω}_{2} = \{ ( x , y ) \vert {r}_{1}^{2} < {x}^{2} + {y}^{2} < {r}_{e}^{2} \} & ( 162 ) \\ \partial Ω = {Γ}_{1} U {Γ}_{2} & ( 163 ) \\ {Γ}_{1} = \{ ( x , y ) \vert {x}^{2} + {y}^{2} = {r}_{w}^{2} \} & ( 164 ) \\ {Γ}_{2} = \{ ( x , y ) \vert {x}^{2} + {y}^{2} = {r}_{e}^{2} \} & ( 165 )\end{matrix}$$

### Embodiment 7

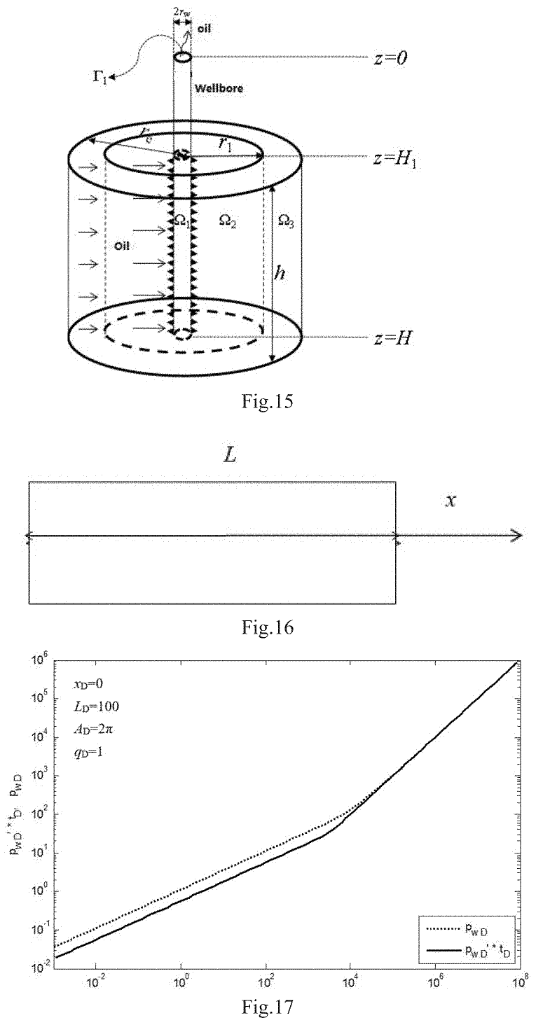

This embodiment provides oil phase flow simulation method through treating the wellbore as reservoir for a fully open vertical well in a homogeneous radial 2-zone composite reservoir. The physical model is shown in FIG. 15.

The general equation of oil phase flow can be established by applying the mass conservation principle:

Oil phase governing equation:

$$∇ \cdot [ \frac{1}{{B}_{o}} {λ}_{o} ∇ {p}_{o} ] = \frac{\partial }{\partial t} ( \frac{1}{{B}_{o}} φ {S}_{o} ) , ( x , t ) ∈ Ω \times ( 0 , {t}_{max} ] \qquad ( 166 )$$

Boundary condition equation:

$$( {c}_{o , 1} {p}_{o} + {c}_{o , 2} {λ}_{o} \frac{\partial {p}_{o}}{\partial {n}^{\partial Ω}} ) = {g}_{o} , ( x , t ) , ( x , t ) ∈ Ω \times ( 0 , {t}_{max} ] \qquad ( 167 )$$

Initial condition equation:

pₒ(x,0)=ƒₒ(x),x∈Ω (168)

Where

$$\begin{matrix} {p}_{o} = {p}_{o} ( x , t ) & ( 169 ) \\ {q}_{o} = {q}_{o} ( t ) & ( 170 ) \\ {λ}_{o} = \{ \begin{matrix}\frac{1}{μ} [ \begin{matrix} & & & \\ {K}_{{r}_{1}} & 0 & & 0 \\ 0 & {K}_{{r}_{2}} & & 0 \\ 0 & 0 & {K}_{{z}_{1}} & ( 1 - {ρ}_{o} g \frac{\partial z}{\partial p} )\end{matrix} ] & , ( x , t ) ∈ {Ω}_{1} \times ( 0 , {t}_{max} ] \\ \frac{1}{μ} [ \begin{matrix}{K}_{{r}_{2}} & 0 & 0 \\ 0 & {K}_{{r}_{2}} & 0 \\ 0 & 0 & {K}_{{z}_{2}}\end{matrix} ] & , ( x , t ) ∈ {Ω}_{2} \times ( 0 , {t}_{max} ] \\ \frac{1}{μ} [ \begin{matrix}{K}_{{r}_{3}} & 0 & 0 \\ 0 & {K}_{{r}_{3}} & 0 \\ 0 & 0 & {K}_{{z}_{3}}\end{matrix} ] & , ( x , t ) ∈ Ω \times ( 0 , {t}_{max} ]\end{matrix} & ( 171 ) \\ {c}_{o , 1} ≡ 0 , ( x , t ) ∈ Ω \times ( 0 , {t}_{max} ] & ( 172 ) \\ {c}_{o , 2} = \{ \begin{matrix}- π {r}_{w}^{2} , & ( x , t ) ∈ {Γ}_{1} \times ( 0 , {t}_{ma x} ] \\ 1 , & ( x , t ) ∈ {Γ}_{2} \times ( 0 , {t}_{max} ]\end{matrix} & ( 173 ) \\ {g}_{o} ( x , t ) = \{ \begin{matrix}q , & ( x , t ) ∈ {Γ}_{1} \times ( 0 , {t}_{max} ] \\ 0 , & ( x , t ) ∈ {Γ}_{2} \times ( 0 , {t}_{max} ]\end{matrix} & ( 174 ) \\ Ω = {Ω}_{1} U {Ω}_{2} U {Ω}_{3} & ( 175 ) \\ {Ω}_{1} = \{ ( x , y , z ) \vert {x}^{2} + {y}^{2} \leq {r}_{w}^{2} , 0 < z < H \} & ( 176 ) \\ {Ω}_{2} = \{ ( x , y ) \vert {r}_{w}^{2} < {x}^{2} + {y}^{2} \leq {r}_{1}^{2} \} & ( 177 ) \\ {Ω}_{3} = \{ ( x , y ) \vert {r}_{w}^{2} < {x}^{2} + {y}^{2} \leq {r}_{e}^{2} \} & ( 178 ) \\ \partial Ω = {Γ}_{1} U {Γ}_{2} & ( 179 ) \\ {Γ}_{1} = \{ ( x , y , z ) \vert {x}^{2} + {y}^{2} \leq {r}_{w}^{2} , z = 0 \} & ( 180 ) \\ {Γ}_{2} = \{ ( x , y , z ) \vert {x}^{2} + {y}^{2} = {r}_{w}^{2} , 0 < z < H \} \\ U \{ ( x , y , z ) \vert {x}^{2} + {y}^{2} = {r}_{e}^{2} , {H}_{1} \leq z \leq H \} \\ U \{ ( x , y , z ) \vert {r}_{w}^{2} < {x}^{2} + {y}^{2} < {r}_{e}^{2} , z = {H}_{1} or H \} & ( 181 )\end{matrix}$$

### Embodiment 8

This embodiment provides flow simulation and transient pressure well testing analysis methods for tube-shaped reservoir. The physical model corresponding to the pressure drawdown well testing model is assumed as follows:

The reservoir is composed of single closed tube-shaped reservoir as shown in FIG. 16,

2) In the initial state, the pressure everywhere in the reservoir is the original reservoir pressure,

3) The fluid flow in the reservoir follows linear flow law,

4) The fluid and rock in the reservoir are slightly compressible,

5) The wellbore storage effect as well as the skin effect are not considered,

The dimensionless mathematical model corresponding to the pressure drawdown well test model is written as

$$\begin{matrix}\frac{{\partial }^{2} {p}_{D}}{\partial {x}_{D}^{2}} = \frac{\partial {p}_{D}}{\partial {t}_{D}} & ( 182 ) \\ {p}_{D} ( {x}_{D} , {t}_{D} = 0 ) & ( 183 ) \\ \frac{{A}_{D}}{2 π} \frac{\partial {p}_{D}}{\partial {x}_{D}} {\vert}_{{x}_{D} = 0} = - {q}_{D} & ( 184 ) \\ \frac{\partial {p}_{D}}{\partial {x}_{D}} {\vert}_{{x}_{D} = {L}_{D}} = 0 & ( 185 )\end{matrix}$$

Dimensionless variables are defined as:

$$\begin{matrix}{t}_{D} = \frac{λ t}{φ {C}_{t} {l}^{2}} & ( 186 ) \\ {p}_{D} = \frac{2 π l λ}{{q}_{SC} B} ( {p}_{i} - p ) & ( 187 ) \\ {L}_{D} = \frac{L}{l} & ( 188 ) \\ {x}_{D} = \frac{x}{l} & ( 189 ) \\ {q}_{D} = q / {q}_{SC} & ( 190 )\end{matrix}$$

Laplace transformation of equations Eqs182-185 are performed based on t_{D}. The dimensionless pressure solution in the Laplace space is obtained as:

$${\overline{p}}_{D} = {\overline{q}}_{D} \frac{2 πcosh ( ( {L}_{D} - {x}_{D} ) \sqrt{u} )}{{A}_{D} \sqrt{u} sinh ( {L}_{D} \sqrt{u} )} \qquad ( 191 )$$

especially, setting x_{D}=0 as a reference point for bottom hole pressure, i. e.,

p̅_{wD}=p̅_{D}(x_{D}=0) (192)

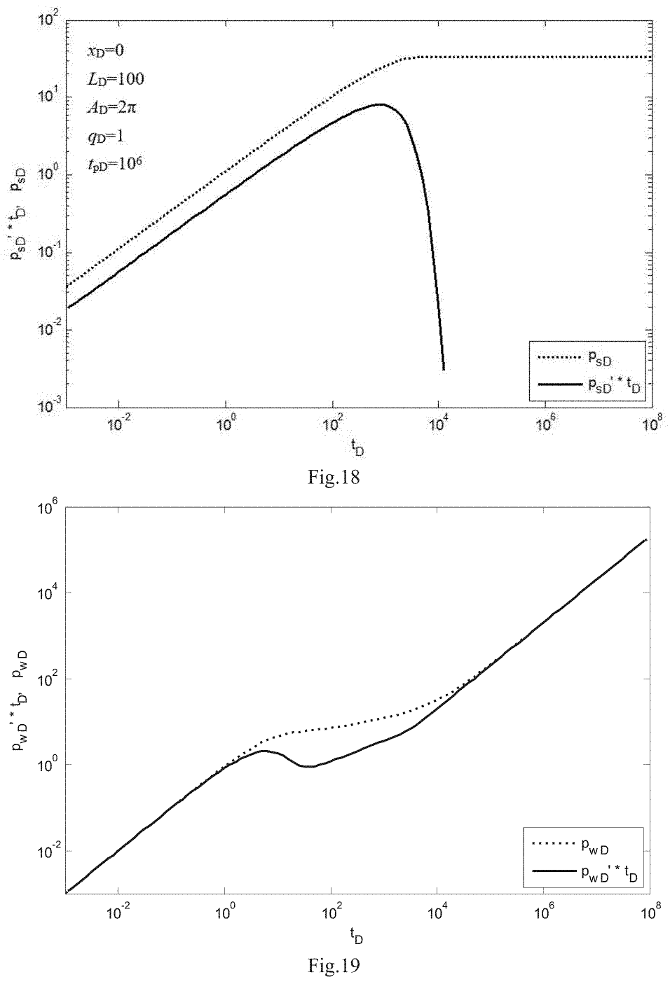

Typical type curves can be drawn by performing Stehfest numerical inversion as shown in FIGS. 17-19.

The specific meanings of the identifiers in embodiment 8 are shown as follows:

A—open flowing area of tube-shaped reservoir, m²; B—volume factor, m³/m³; Cₜ—compressibility of tube-shaped reservoir, 1/Pa; l—reference length, m; L—length of tube-shaped reservoir, m; p—pressure of tube-shaped reservoir, Pa; pᵢ—initial pressure of tube-shaped reservoir·Pa; p_{w}—bottom hole pressure, Pa; q—flow rate, m³/s; q_{sc}—reference flow rate, m³/s; t—time, s; u—Laplace variable of dimensionless time t_{D}; x—x-axis distance, m; λ—generalized mobility of tube-shaped reservoir, m²/Pa·s; ϕ—porosity of tube-shaped reservoir, %; ∂—partial differential operator.

### Embodiment 9

This embodiment provides flow simulation and transient pressure well testing analysis methods for a cylindrical reservoir. The physical model corresponding to the pressure drawdown well testing model is assumed as follows:

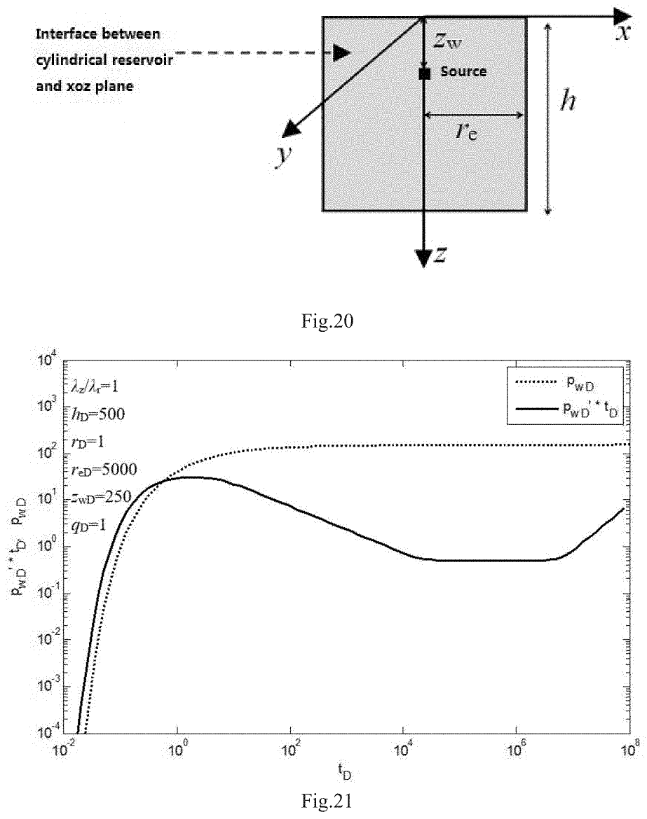

The reservoir is a cylindrical closed system and the point source is located on the axis of the cylindrical reservoir, which is shown in FIG. 20;

2) In the initial state, the pressure everywhere in the reservoir is the original reservoir pressure,

3) The fluid flow in the reservoir follows linear flow law,

4) The fluid and rock in the reservoir are slightly compressible,

5) The wellbore storage effect as well as the skin effect are not considered.

The dimensionless mathematical model corresponding to the pressure drawdown well test model is written as:

$$\begin{matrix}\frac{1}{{r}_{D}} \frac{\partial }{\partial {r}_{D}} ( {r}_{D} \frac{\partial {p}_{D}}{\partial {r}_{D}} ) + {κ}_{D} \frac{{\partial }^{2} {p}_{D}}{\partial {z}_{D}^{2}} = \frac{\partial {p}_{D}}{\partial {t}_{D}} & ( 193 ) \\ {p}_{D} ( {r}_{D} , {z}_{D} , {t}_{D} = 0 ) & ( 194 ) \\ {lim}_{{{ɛ}_{D} \to 0}_{{r}_{D} \to 0}} [ {ɛ}_{D} {r}_{D} \frac{\partial {p}_{D}}{\partial {r}_{D}} - \{ \begin{matrix}- {q}_{D} , & \vert {z}_{D} - {z}_{wD} \vert \leq \frac{{ɛ}_{D}}{2} \\ 0 , & otherwise\end{matrix} ] = 0 & ( 195 ) \\ \frac{\partial {p}_{D}}{\partial {z}_{D}} {\vert}_{{z}_{D} = 0} = 0 & ( 196 ) \\ \frac{\partial {p}_{D}}{\partial {z}_{D}} {\vert}_{{z}_{D} = {h}_{D}} = 0 & ( 197 ) \\ \frac{\partial {p}_{D}}{\partial {z}_{D}} {\vert}_{{r}_{D} = {r}_{eD}} = 0 & ( 198 )\end{matrix}$$

Dimensionless variables are defined as:

$$\begin{matrix}{p}_{D} = \frac{2 π l {λ}_{r}}{{q}_{SC} B} ( {p}_{i} - p ) & ( 199 ) \\ {t}_{D} = \frac{{λ}_{r} t}{φ {C}_{t} {l}^{2}} & ( 200 ) \\ {r}_{eD} = \frac{{r}_{e}}{l} & ( 201 ) \\ {h}_{D} = \frac{h}{l} & ( 202 ) \\ {z}_{D} = \frac{z}{l} & ( 203 ) \\ {z}_{wD} = \frac{{z}_{w}}{l} & ( 204 ) \\ {r}_{D} = \frac{r}{l} & ( 205 ) \\ {ɛ}_{D} = \frac{ɛ}{l} & ( 206 ) \\ {κ}_{D} = \frac{{λ}_{z}}{{λ}_{r}} & ( 207 ) \\ {q}_{D} = q / {q}_{SC} & ( 208 )\end{matrix}$$

Laplace transformation of equations Eqs.193 and 198 are performed based on t_{D}. The dimensionless pressure solution in the Laplace space by applying variable separation method is obtained as:

$${\overline{p}}_{D} = {\overline{q}}_{D} {\sum }_{n = 0}^{∞} {a}_{n} [ {K}_{0} ( {r}_{D} {b}_{n} ) + \frac{{K}_{1} ( {r}_{eD} {b}_{n} )}{{I}_{1} ( {r}_{eD} {b}_{n} )} {I}_{0} ( {r}_{D} {b}_{n} ) ] cos \frac{n {πz}_{D}}{{h}_{D}} \qquad ( 209 )$$

Where

$$\begin{matrix}{a}_{n} = \{ \begin{matrix}1 , & n = 0 \\ 2 cos \frac{n π {z}_{wD}}{{h}_{D}} , & n = 1 , 2 , … , ∞\end{matrix} & ( 210 ) \\ {b}_{n} = \sqrt{u + {λ}_{z} / {{λ}_{r} ( n π / {h}_{D} )}^{2}} , n = 0 , 1 , 2 , … , ∞ & ( 211 )\end{matrix}$$

I₀(g) and I₁(g) are the category I modified zero-order and first-order Bessel functions respectively, K₀(g) and K₁(g) are the category II modified zero-order and first-order Bessel functions respectively.

Especially, setting r_{D}=1, z_{D}=z_{wD} as reference points of bottom hole pressure, i. e.,

p̅_{wD}=p̅_{D}(r_{D}=1,z_{D}=z_{wD}) (212)

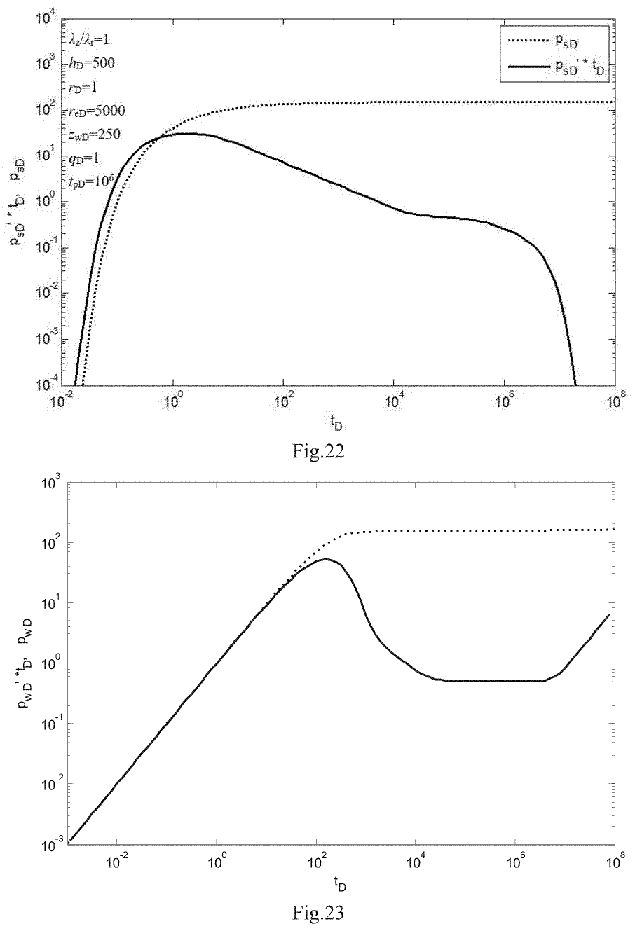

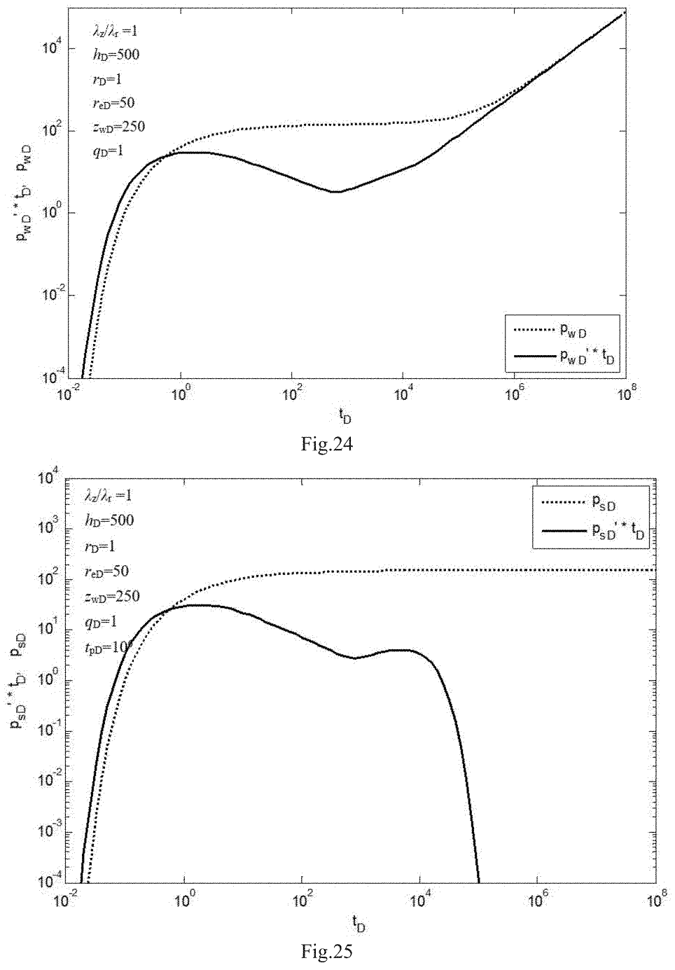

Typical type curves can be drawn by performing Stehfest numerical inversion as shown in FIGS. 21-26.

The specific meanings of the identifiers in embodiment 9 are shown as follows:

B—volume factor, m³/m; Cₜ—compressibility of cylindrical reservoir, 1/Pa; h—height of cylindrical reservoir, m; l—reference length, m; p—pressure of cylindrical reservoir, Pa; pᵢ—initial pressure of cylindrical reservoir, Pa; p_{w}—bottom hole pressure, Pa; q—flow rate, m³/s; q_{sc}—reference flow rate, m³/s; rₑ—radius of cylindrical reservoir, m; t—time, s; u—Laplace variable corresponding to dimensionless time t_{D}; z—z-axis distance, m; z_{w}—central point position of point source along z-axis, m; ε—height of the point source (tends to zero), m; λᵣ—radial generalized mobility of cylindrical reservoir, m²/Pa·s; λ_{z}—vertical generalized mobility of cylindrical reservoir, m²/Pa·s; ϕ—porosity of cylindrical reservoir, %; ∂—partial differential operator.

If necessary, the line source solution and cylindrical plane source solutions can be obtained through integrating the point source solution Eq.209. For example,
Horizontal well (line source):

$${\overline{p}}_{LD} = \frac{{\overline{q}}_{D }}{2 {L}_{D} } {\int }_{- {L}_{D}}^{{L}_{D}} {\sum }_{n = 0}^{∞} {a}_{n} [ \begin{matrix}{K}_{0} ( \sqrt{{( {x}_{D} - {x}_{wD} )}^{2} - {y}_{D}^{2}} {b}_{n} ) + \\ \frac{{K}_{1} ( {r}_{eD} {b}_{n} )}{{I}_{1} ( {r}_{eD} {b}_{n} )} {I}_{0} ( \sqrt{{( {x}_{D} - {x}_{wD} )}^{2} - {y}_{D}^{2}} {b}_{n} )\end{matrix} ] cos \frac{n π {z}_{D}}{{h}_{D}} d {x}_{wD} \qquad ( 213 )$$

Where L_{D} is the dimensionless half length of horizontal well.

Partially open hydraulic fractured vertical well (cylindrical plane source):

$${\overline{p}}_{fD} = \frac{{\overline{q}}_{D}}{2 {x}_{fD} ( {z}_{bD} - {z}_{aD} )} {\int }_{{z}_{aD}}^{{z}_{bD}} {\int }_{- {x}_{fD}}^{{x}_{fD}} {\sum }_{n = 0}^{∞} [ \begin{matrix}{K}_{0} ( \sqrt{{( {x}_{D} - {x}_{wD} )}^{2} - {y}_{D}^{2}} {b}_{n} ) + \\ \frac{{K}_{1} ( {r}_{eD} {b}_{n} )}{{I}_{1} ( {r}_{eD} {b}_{n} )} {I}_{0} ( \sqrt{{( {x}_{D} - {x}_{wD} )}^{2} - {y}_{D}^{2}} {b}_{n} )\end{matrix} ] cos \frac{n π {z}_{D}}{{h}_{D}} {dx}_{wD} {dz}_{wD} \qquad ( 214 )$$

Where x_{fD} is the dimensionless half length of hydraulic fractures, z_{aD}, z_{bD} are the top and bottom positions of hydraulic fractures.

### Embodiment 10

This embodiment provides flow simulation and transient pressure well testing analysis methods for a spherical reservoir. The physical model corresponding to the pressure drawdown well testing model is assumed as follows:

1) The reservoir is a spherical closed system and the point source is located inside the spherical reservoir as shown in FIG. 27,
2) In the initial state, the pressure everywhere in the reservoir is the original reservoir pressure,
3) The fluid flow in the reservoir follows linear flow law,
4) The fluid and rock in the reservoir are slightly compressible,
5) The wellbore storage effect as well as the skin effect are not considered,

The dimensionless mathematical model corresponding to the pressure drawdown well test model is written as:

$$\begin{matrix}\frac{1}{{r}_{D}^{2}} \frac{\partial }{\partial {r}_{D}} ( {r}_{D}^{2} \frac{\partial {p}_{D}}{\partial {r}_{D}} ) + \frac{1}{{r}_{D}^{2} sin θ} \frac{\partial }{\partial θ} ( sin θ \frac{\partial {p}_{D}}{\partial θ} ) = \frac{\partial {p}_{D}}{\partial {t}_{D}} & ( 215 ) \\ {p}_{D} ( {r}_{D} , θ , {t}_{D} = 0 ) = 0 & ( 216 ) \\ {lim}_{{r}_{D} -> 0} 2 {r}_{D}^{2} \frac{\partial {p}_{D}}{\partial {r}_{D}} = - {q}_{D} & ( 217 ) \\ \frac{\partial {p}_{D}}{\partial {r}_{D}} {\vert}_{{r}_{D} = \sqrt{{r}_{eD}^{2} + {r}_{aD}^{2} - 2 {r}_{eD} {r}_{aD} co s Φ}} = 0 & ( 218 )\end{matrix}$$

Dimensionless variables are defined as:

$$\begin{matrix}{t}_{D} = \frac{λ t}{φ {C}_{t} {l}^{2}} & ( 219 ) \\ {p}_{D} = \frac{2 π λ l}{{q}_{sc} B} ( {p}_{i} - p ) & ( 220 ) \\ {r}_{aD} = \frac{{r}_{a}}{l} & ( 221 ) \\ {r}_{bD} = \frac{{r}_{b}}{l} & ( 222 ) \\ {r}_{eD} = \frac{{r}_{e}}{l} & ( 223 ) \\ {r}_{D} = \sqrt{{r}_{bD}^{2} + {r}_{aD}^{2} - 2 {r}_{bD} {r}_{aD} cos Φ} & ( 224 ) \\ θ = arcsin \frac{{r}_{D}}{{r}_{bD} sin Φ} & ( 225 ) \\ {q}_{D} = q / {q}_{sc} & ( 226 )\end{matrix}$$

The dimensionless pressure solution of Eqs.215-218 in the Laplace space by applying Laplace integral transformation and boundary construction method is obtained as:

$${\overline{p}}_{D} = {\overline{q}}_{D} {\sum }_{n = 0}^{∞} \frac{n + 1 / 2}{\sqrt{{r}_{aD} {r}_{bD}}} {I}_{n + \frac{1}{2}} ( {r}_{aD} \sqrt{u} ) [ {K}_{n + \frac{1}{2}} ( {r}_{bD} \sqrt{u} ) - \frac{{nK}_{n + \frac{1}{2}} ( {r}_{eD} \sqrt{u} ) - {r}_{eD} \sqrt{u} {K}_{n + \frac{3}{2}} ( {r}_{eD} \sqrt{u} )}{{nI}_{n + \frac{1}{2}} ( {r}_{eD} \sqrt{u} ) + {r}_{eD} \sqrt{u} {I}_{n + \frac{3}{2}} ( {r}_{eD} \sqrt{u} )} {I}_{n + \frac{1}{2}} ( {r}_{bD} \sqrt{u} ) ] {P}_{n} ( cos Φ ) , {r}_{bD} > {r}_{aD} \qquad ( 227 )$$

Where

$${I}_{n + \frac{1}{2}} ( g )$$

is the category I modified n+½ order Bessel function,

$${K}_{n + \frac{1}{2}} ( g ) and {K}_{n + \frac{3}{2}} ( g )$$

are the category II modified n+½ order and n+3/2 order Bessel functions respectively. Pₙ is the category I nth order Legendre function.

In particular, setting r_{aD}=0, r_{bD}=1 as the reference points of bottom hole pressure, i. e.,

p̅_{wD}=p̅_{D}(r_{aD}=0,r_{bD}=1) (228)

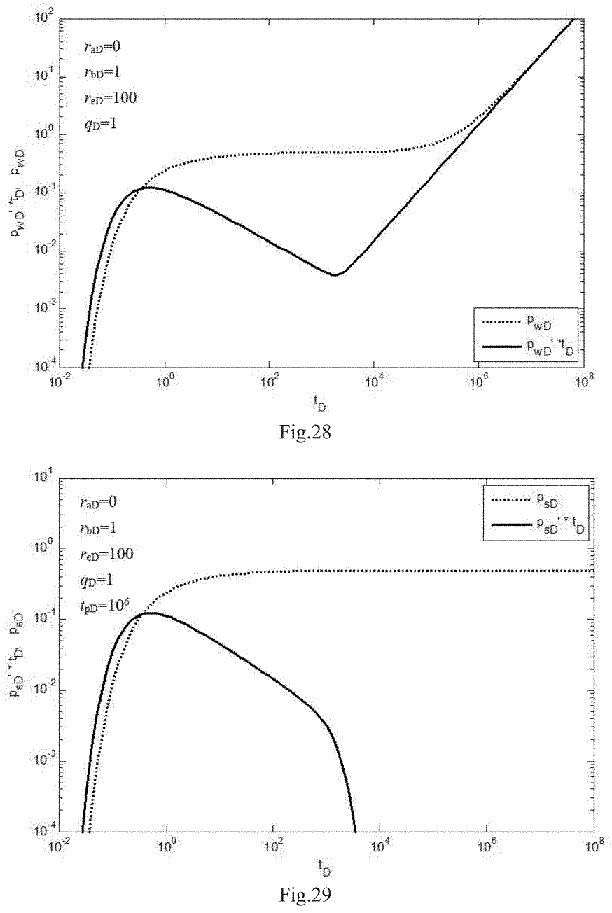

Typical type curves can be drawn by performing Stehfest numerical inversion as shown in FIGS. 28-30.

The specific meanings of the identifiers in embodiment 10 are shown as follows:

B—volume factor, m³/m³; Cₜ—compressibility of spherical reservoir, 1/Pa; l—reference length, m; p—pressure of spherical reservoir, Pa; pᵢ—initial pressure of spherical reservoir, Pa; p_{w}—bottom hole pressure, Pa; q—flow rate, m³/s; q_{sc}—reference flow rate, m³/s; r—distance from the point source to the observation point, m; rₐ—eccentric distance, m; r_{b}—the distance from the center of the spherical reservoir to the observation point, m; rₑ—radius of spherical reservoir, m; t—time, s; u—Laplace variable of dimensionless time t_{D}; λ—generalized mobility of spherical reservoir, m²/Pa·s; ϕ—porosity of spherical reservoir, %; Φ—angle between rₐ and r_{b}; ∂—partial differential operator.

If necessary, the line source solution and spherical plane source solutions can be obtained through integrating the point source solution Eq.227, but in the process of integration, we should pay attention to r_{bD}>r_{aD}.

### Embodiment 11

This embodiment provides a composite flow simulation and transient pressure well testing analysis methods for a compound body of hollow cylinder and cylindrical reservoir. The physical model corresponding to the pressure drawdown well testing model is assumed as follows:

1) The reservoir is a composite reservoir of hollow cylinder and cylinder. The cylindrical reservoir is nested in the middle of the hollow cylindrical reservoir, and the point source is located inside the cylindrical reservoir, which is shown in FIG. 31;
2) In the initial state, the pressure everywhere in the reservoir is the original reservoir pressure,
3) The fluid flow in the reservoir follows linear flow law,
4) The fluid and rock in the reservoir are slightly compressible,
5) The wellbore storage effect as well as the skin effect are not considered,

The dimensionless mathematical model corresponding to the pressure drawdown well test model is written as:

$$\begin{matrix} \frac{{\partial }^{2} {p}_{1 D}}{\partial {r}_{D}^{2}} + \frac{1}{{r}_{D}} \frac{\partial {p}_{1 D}}{\partial {r}_{D}} + \frac{1}{{h}_{1 D}^{2}} \frac{{\partial }^{2} {p}_{1 D}}{\partial {z}_{D}^{2}} = \frac{\partial {p}_{1 D}}{\partial {t}_{D}} & ( 229 ) \\ \frac{{\partial }^{2} {p}_{2 D}}{\partial {r}_{D}^{2}} + \frac{1}{{r}_{D}} \frac{\partial {p}_{2 D}}{\partial {r}_{D}} + \frac{1}{{h}_{2 D}^{2}} \frac{{\partial }^{2} {p}_{2 D}}{\partial {z}_{D}^{2}} = \frac{1}{σ} \frac{\partial {p}_{2 D}}{\partial {t}_{D}} \\ {p}_{1 D} ( {r}_{D} , {z}_{D} , 0 ) = {p}_{2 D} ( {r}_{D} , {z}_{D} , 0 ) = 0 & ( 230 ) \\ {lim}_{{{ɛ}_{D} -> 0}_{{r}_{D} -> 0}} [ {\int }_{{z}_{wD} - {ɛ}_{D} / 2}^{{z}_{wD} + {ɛ}_{D} / 2} {r}_{D} \frac{\partial {p}_{1 D}}{\partial {r}_{D}} {dz}_{D} - \{ \begin{matrix}- {q}_{D} , & \vert {z}_{D} - {z}_{wD} \vert \leq {ɛ}_{D} / 2 ; \\ 0 , & else .\end{matrix} \} ] = 0 & ( 231 ) \\ \frac{\partial {p}_{1 D}}{\partial {z}_{D}} {{\vert}_{{z}_{D} = {z}_{j2 D}} = \frac{\partial {p}_{2 D}}{\partial {z}_{D}} \vert}_{{z}_{D} = {h}_{D}} = 0 & ( 232 ) \\ \frac{\partial {p}_{1 D}}{\partial {z}_{D}} {{\vert}_{{z}_{D} = {z}_{j 1 D}} = \frac{\partial {p}_{2 D}}{\partial {z}_{D}} \vert}_{{z}_{D} = 0} = 0 & ( 233 ) \\ \{ \begin{matrix}\frac{\partial {p}_{1 D}}{\partial {r}_{D }} {{\vert}_{{r}_{D} = {r}_{1 D}} = {κ}_{D} \frac{\partial {p}_{2 D}}{\partial {r}_{D}} \vert}_{{r}_{D} = {r}_{1 D}} , ( {z}_{j 1 D} \leq {z}_{D} \leq {z}_{j 2 D} ) \\ \frac{\partial {p}_{2 D}}{\partial {r}_{D}} {\vert}_{{r}_{D} = {r}_{1 D}} = 0 , ( 0 \leq {z}_{D} < {z}_{j 1 D} ) \\ \frac{\partial {p}_{2 D}}{\partial D} {\vert}_{{r}_{D} = {r}_{1 D}} = 0 , ( {z}_{j 2 D} < {z}_{D} \leq {h}_{D} )\end{matrix} & ( 234 ) \\ {p}_{1 D} {{\vert}_{{r}_{D} = {r}_{1 D}} = {p}_{2 D} \vert}_{{r}_{D} = {r}_{1 D}} & ( 235 ) \\ \frac{\partial {p}_{2 D}}{\partial {r}_{D}} {\vert}_{{r}_{D} = {r}_{2 D}} = 0 & ( 236 )\end{matrix}$$

Dimensionless variables are defined as

$$\begin{matrix}{p}_{1 D} = \frac{2 π {λ}_{r 1} {h}_{1}}{{q}_{s c} B} ( {p}_{i} - {p}_{1} ) & ( 237 ) \\ {p}_{2 D} = \frac{2 π {λ}_{r 1} {h}_{1}}{{q}_{sc} B} ( {p}_{i} - {p}_{2} ) & ( 238 ) \\ {r}_{D} = \frac{r}{l} & ( 239 ) \\ {t}_{D} = \frac{{λ}_{r 1} t}{{φ}_{1} {C}_{t 1} {l}^{2}} & ( 240 ) \\ {z}_{D} = \frac{z}{{h}_{1}} & ( 241 ) \\ {z}_{wD} = \frac{{z}_{w}}{{h}_{1}} & ( 242 ) \\ {h}_{1 D} = \frac{{h}_{1}}{l} \sqrt{\frac{{λ}_{r 1}}{{λ}_{z 1}}} & ( 243 ) \\ {h}_{2 D} = \frac{{h}_{1}}{l} \sqrt{\frac{{λ}_{r 2}}{{λ}_{z 2}}} & ( 244 ) \\ σ = \frac{{λ}_{r 2}}{{φ}_{2} {C}_{t 2}} / \frac{{λ}_{r 1}}{{φ}_{1} {C}_{t 1}} & ( 245 ) \\ {κ}_{D} = \frac{{λ}_{r 2}}{{λ}_{r 1}} & ( 246 ) \\ {z}_{j 1 D} = \frac{{z}_{j}}{{h}_{1}} & ( 247 ) \\ {z}_{j 2 D} = \frac{{h}_{1} + {z}_{j}}{{h}_{1}} & ( 248 ) \\ {h}_{D} = \frac{{h}_{2}}{{h}_{1}} & ( 249 ) \\ {q}_{D} = q / {q}_{sc} & ( 250 )\end{matrix}$$

The dimensionless pressure solution of Eqs.229-236 in the Laplace space by applying Laplace integral transformation and Fourier finite cosine transformation is obtained as:

$${\overline{p}}_{1 D} = {\overline{q}}_{D} \{ \begin{matrix}{K}_{0} ( {r}_{D} {δ}_{10} ) + {g}_{0} {I}_{0} ( {r}_{D} {δ}_{10} ) + \\ \begin{matrix}{\sum }_{m = 1}^{∞} 2 cos ( {ξ}_{1 m} ( {z}_{j 1 D} - {z}_{wd} ) ) cos ( {ξ}_{1 m} ( {z}_{j 1 D} - {z}_{D} ) ) \\ [ {K}_{0} ( {r}_{D} {δ}_{1 m} ) + {g}_{m} {I}_{0} ( {r}_{D} {δ}_{1 m} ) ]\end{matrix}\end{matrix} \} \qquad ( 251 )$$

Where

$$\begin{matrix} {g}_{m} = \frac{{F}_{n m} {K}_{1} ( {r}_{1 D} {δ}_{1 m} ) - cos ( {ξ}_{1 m} ( {z}_{D} - {z}_{j 1 D} ) ) {K}_{0} ( {r}_{1 D} {δ}_{1 m} )}{{F}_{n m} {I}_{1} ( {r}_{1 D} {δ}_{1 m} ) + cos ( {ξ}_{1 m} ( {z}_{D} - {z}_{j 1 D} ) ) {I}_{0} ( {r}_{1 D} {δ}_{1 m} )} & ( 252 ) \\ {F}_{n m} = {\sum }_{n = 0}^{∞} \frac{4 {ξ}_{2 n} ( \begin{matrix}{ξ}_{1 m} sin ( {ξ}_{1 m} ) cos ( {ξ}_{2 n} ( {z}_{j 1 D} + 1 ) ) + \\ {ξ}_{2 n} ( sin ( {ξ}_{2 n} {z}_{j 1 D} ) - cos ( {ξ}_{1 m} ) sin ( {ξ}_{2 n} ( {z}_{j 1 D} + 1 ) ) )\end{matrix} )}{( {ξ}_{1 m} - {ξ}_{2 n} ) ( {ξ}_{1 m} + {ξ}_{2 n} ) ( 2 {h}_{D} {ξ}_{2 n} + sin ( 2 {h}_{D} {ξ}_{2 n} ) )} \times \frac{{δ}_{1 m} ( \begin{matrix}{K}_{0} ( {r}_{1 D} {δ}_{2 n} ) + \\ {K}_{1} ( {r}_{eD} {δ}_{2 n} ) / {I}_{1} ( {r}_{eD} {δ}_{2 n} ) {I}_{0} ( {r}_{1 D} {δ}_{2 n} )\end{matrix} ) cos ( {ξ}_{2 n} {z}_{D} )}{{κ}_{D} {δ}_{2 n} ( {K}_{1} ( {r}_{1 D} {δ}_{2 n} ) - {K}_{1} ( {r}_{eD} {δ}_{2 n} ) / {I}_{1} ( {r}_{eD} {δ}_{2 n} ) {I}_{1} ( {r}_{1 D} {δ}_{2 n} ) )} & ( 253 ) \\ {δ}_{1 m} = \sqrt{u + \frac{{ξ}_{1 m}^{2}}{{h}_{1 D}^{2}}} & ( 254 ) \\ {δ}_{2 n} = \sqrt{\frac{u}{σ} + \frac{{ξ}_{2 n}^{2}}{{h}_{2 D}^{2}}} & ( 255 ) \\ {ξ}_{1} = m π & ( 256 ) \\ {ξ}_{2 } = \frac{n π}{{h}_{D}} & ( 257 )\end{matrix}$$

I₀(g) and I₁(g) are the category I modified zero-order and first-order Bessel functions respectively, K₀(g) and K₁(g) are the category II modified zero-order and first-order Bessel functions respectively.

Especially, setting r_{D}=1, z_{D}=z_{wD} as reference points of bottom hole pressure, i. e.,

p̅_{wD}=p̅_{D}(r_{D}=1,z_{D}=z_{wD}) (258)

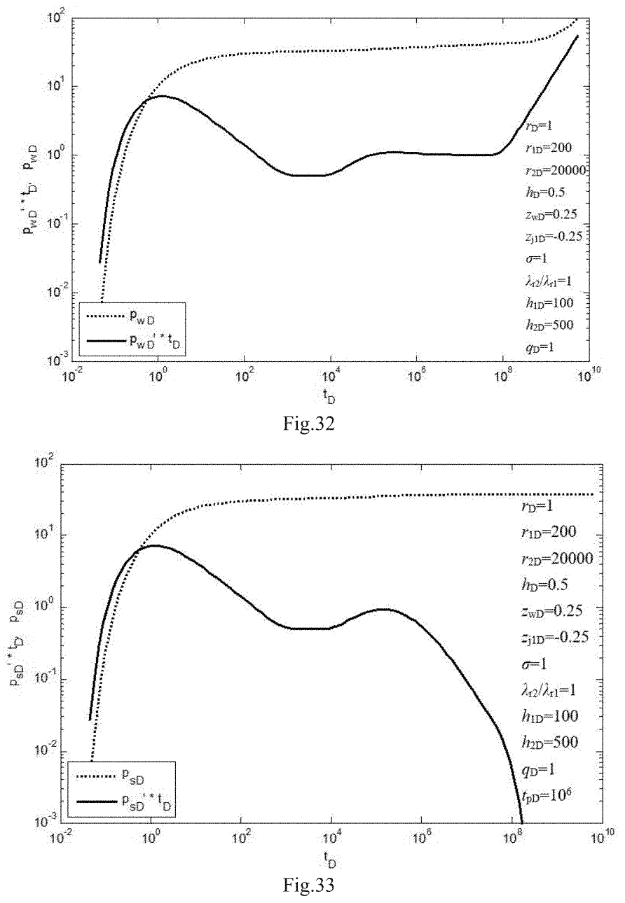

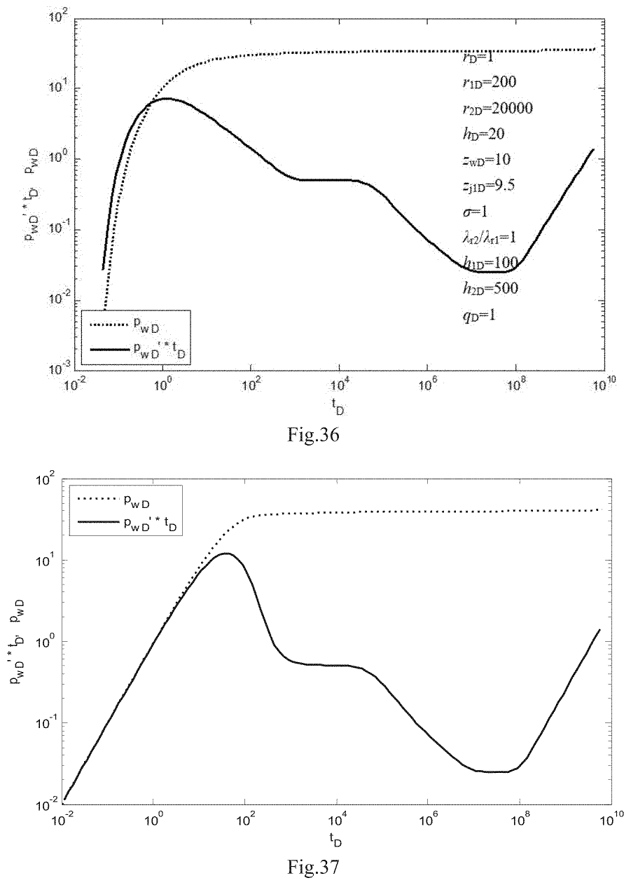

Typical type curves can be drawn by performing Stehfest numerical inversion as shown in FIGS. 32-37.

The specific meanings of the identifiers in embodiment 11 are shown as follows:

B—volume factor, m³/m³; Cₜ₁,Cₜ₂—compressibility of cylindrical reservoir and hollow cylindrical reservoir respectively, 1/Pa; h₁,h₂—height of cylindrical reservoir and hollow cylindrical reservoir respectively, m; l—reference length, m; p₁, p₂—pressure of cylindrical reservoir and hollow cylindrical reservoir, Pa; pᵢ—initial pressure of reservoir, Pa: p_{w}—bottom hole pressure, Pa: q—flow rate, m³/s; q_{sc}—reference flow rate, m³/s; r—radial distance from the point source to the axis of cylindrical reservoir, m: r₁,r₂—radius of cylindrical reservoir and hollow cylindrical reservoir, m; t—time, s; u—Laplace variable of dimensionless time t_{D}; z—z-axis distance, m; z_{w}—central point position of point source on z-axis, m; zⱼ—vertical position of the low end of the cylindrical reservoir, m; ε—height of the point source (tends to zero), m; λᵣ₁,λᵣ₂—generalized mobility of cylindrical reservoir and hollow cylindrical reservoir respectively, m²/Pa·s; ϕ₁,ϕ₂—porosity of cylindrical reservoir and hollow cylindrical reservoir, %; ∂—partial differential operator.

If necessary, the line source solution and spherical plane source solutions can be obtained through integrating the point source solution Eq.251.

### Embodiment 12

This embodiment provides a composite flow simulation and transient pressure well testing analysis methods for a compound body of tube-shaped and spherical reservoir. The physical model corresponding to the pressure drawdown well testing model is assumed as follows:

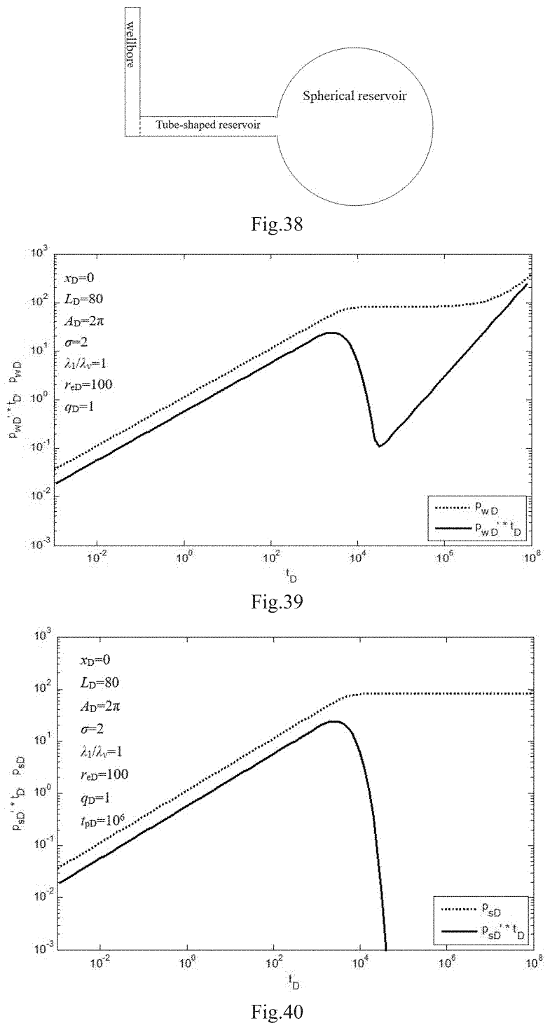

1) The reservoir is a composite reservoir of a compound body of tube-shaped and spherical reservoir as shown in FIG. 38;
2) In the initial state, the pressure everywhere in the reservoir is the original reservoir pressure,
3) The fluid flow in the reservoir follows linear flow law,
4) The fluid and rock in the reservoir are slightly compressible,
5) The wellbore storage effect as well as the skin effect are not considered,

The dimensionless mathematical model corresponding to the pressure drawdown well test model is written as:

$$\begin{matrix}\frac{1}{{r}_{D}^{2}} \frac{\partial }{\partial {r}_{D}} ( {r}_{D}^{2} \frac{\partial {p}_{vD}}{\partial {r}_{D}} ) + \frac{1}{{r}_{D}^{2} sin θ} \frac{\partial }{\partial θ} ( sin θ \frac{\partial {p}_{vD}}{\partial θ} ) = \frac{1}{σ} \frac{\partial {p}_{vD}}{\partial {t}_{D}} & ( 259 ) \\ {p}_{vD} = ( {r}_{D} , θ = 0 , {t}_{D} = 0 ) = 0 & ( 260 ) \\ - {q}_{vD} = {lim}_{{r}_{D} -> 0} 2 {r}_{D}^{2} \frac{{λ}_{v}}{{λ}_{1}} \frac{\partial {p}_{vD}}{\partial {r}_{D}} & ( 261 ) \\ \frac{\partial {p}_{vd}}{\partial {r}_{D}} {\vert}_{{r}_{D} = \sqrt{{r}_{eD}^{2} + {r}_{aD}^{2} - 2 {r}_{eD} {r}_{aD} co s Φ}} = 0 & ( 262 ) \\ \frac{{\partial }^{2} {p}_{1 D}}{\partial {x}_{D}^{2}} = \frac{\partial {p}_{1 D}}{\partial {t}_{D}} & ( 263 ) \\ {p}_{1 D} ( {x}_{D} , {t}_{D} = 0 ) = 0 & ( 264 ) \\ \frac{{A}_{D}}{2 π} \frac{\partial {p}_{1 D}}{\partial {x}_{D}} {\vert}_{{x}_{D} = 0} = - {q}_{D} & ( 265 ) \\ \frac{{A}_{D}}{2 π} \frac{\partial {p}_{1 D}}{\partial {x}_{D}} {\vert}_{{x}_{D} = {L}_{D}} = - {q}_{vD} & ( 266 ) \\ {p}_{1 D} {\vert}_{{x}_{D} = {L}_{D}} = {p}_{vD} {\vert}_{{r}_{bD} = {r}_{eD} , {r}_{aD} = {r}_{eD} - 1 , Φ = 0} & ( 267 )\end{matrix}$$

Dimensionless variables are defined as

$$\begin{matrix}{t}_{D} = \frac{{λ}_{1} t}{{φ}_{1} {C}_{t 1} {l}^{2}} & ( 268 ) \\ {p}_{1 D} = \frac{2 π {λ}_{1} l}{{q}_{sc} B} ( {p}_{i} - {p}_{1} ) & ( 269 ) \\ {p}_{vD} = \frac{2 π {λ}_{1} l}{{q}_{sc} B} ( {p}_{i} - {p}_{v} ) & ( 270 ) \\ σ = \frac{{λ}_{v}}{{φ}_{v} {C}_{tv}} / \frac{{λ}_{1}}{{φ}_{1} {C}_{t 1}} & ( 271 ) \\ {A}_{D} = \frac{A}{l} & ( 272 ) \\ {x}_{D} = \frac{x}{l} & ( 273 ) \\ {L}_{D} = \frac{L}{l} & ( 274 ) \\ {r}_{aD} = \frac{{r}_{a}}{l} & ( 275 ) \\ {r}_{bD} = \frac{{r}_{b}}{l} & ( 276 ) \\ {r}_{eD} = \frac{{r}_{e}}{l} & ( 277 ) \\ {r}_{D} = \sqrt{{r}_{bD}^{2} + {r}_{aD}^{2} - 2 {r}_{bD} {r}_{aD} cos Φ} & ( 278 ) \\ θ = arcsin \frac{{r}_{D}}{{r}_{bD} sin Φ} & ( 279 ) \\ {q}_{vD} = {q}_{v} / {q}_{s c} & ( 280 ) \\ {q}_{D} = q / {q}_{sc} & ( 281 )\end{matrix}$$

The dimensionless pressure solution of equations Eqs.259 and 267 in the Laplace space by applying Laplace integral transformation and boundary construction method is obtained as:

$$\begin{matrix}{\overline{p}}_{D} = {\overline{q}}_{D} \frac{2 π ( {A}_{D} \overline{f} \sqrt{u} cosh ( ( {L}_{D} - {x}_{D} ) \sqrt{u} ) - 2 π sinh ( ( {L}_{D} - {x}_{D} ) \sqrt{u} ) )}{{A}_{D} \sqrt{u} ( {A}_{D} \overline{f} \sqrt{u} sinh ( {L}_{D} \sqrt{u} ) - 2 π cosh ( {L}_{D} \sqrt{u} ) )} \\ where & ( 282 ) \\ \overline{f} = - \frac{{λ}_{\text{?}}}{{λ}_{\text{?}}} {\sum }_{n = 0}^{∞} \frac{n + 1 / 2}{\sqrt{( {r}_{eD} - 1 ) {r}_{eD}}} {I}_{n + \frac{1}{2}} ( ( {r}_{eD} - 1 ) \sqrt{u / σ} ) [ {K}_{n + \frac{1}{2}} ( {r}_{eD} \sqrt{u / σ} ) - \frac{{nK}_{n + \frac{1}{2}} ( {r}_{eD} \sqrt{u / σ} ) - {r}_{eD} \sqrt{u / σ } {K}_{n + \frac{3}{2}} ( {r}_{eD} \sqrt{u / σ} )}{{nI}_{n + \frac{1}{2}} ( {r}_{eD} \sqrt{u / σ} ) + {r}_{eD} \sqrt{u / σ} {I}_{n + \frac{3}{2}} ( {r}_{eD} \sqrt{u / σ} )} {I}_{n + \frac{1}{2}} ( {r}_{eD} \sqrt{u / σ} ) ] \\ \text{?} \text{indicates text missing or illegible when filed} & ( 283 )\end{matrix}$$

$${I}_{n + \frac{1}{2}} ( g )$$

is the category I modified n+½ order Bessel function,

$${K}_{n + \frac{1}{2}} ( g ) and {K}_{n + \frac{3}{2}} ( g )$$

are the category II modified n+½ order and n+3/2 order Bessel functions respectively.

Especially, setting x_{D}=0 as the reference points of bottom hole pressure, i. e.,

p̅_{wD}=p̅_{D}(x_{D}=0) (284)

Typical type curves can be drawn by performing Stehfest numerical inversion as shown in FIG. 39-41.

The specific meanings of the identifiers in embodiment 12 are shown as follows:

A—open flowing area of tube-shaped reservoir, m²: B—volume factor, m³/m³; Cₜ₁,Cₜᵥ—compressibility of tube-shaped reservoir and spherical reservoir respectively, 1/Pa; l—reference length, m; L—length of tube-shaped reservoir, m; p₁,pᵥ—pressure of tube-shaped reservoir and spherical reservoir, Pa; pᵢ—initial pressure of tube-shaped and spherical reservoir, Pa; p_{w}—bottom hole pressure, Pa; q—flow rate, m³/s; q_{sc}—reference flow rate, m³/s; qᵥ—flow rate from spherical reservoir to tube-shaped reservoir, m³/s; r—distance from the point source to the observation point, m; rₐ—eccentric distance, m; r_{b}—the distance from the center of the spherical reservoir to the observation point, m; rₑ—radius of spherical reservoir, m; t—time, s; u—Laplace variable of dimensionless time t_{D}; x—x-axis distance, m; λ₁,λᵥ—generalized mobility of tube-shaped reservoir and spherical reservoir respectively, m²/Pa·s; ϕ₁,ϕ₂—porosity of tube-shaped reservoir and spherical reservoir, %; Φ—angle between rₐ and r_{b}; ∂—partial differential operator.

### Embodiment 13

This embodiment provides flow simulation and transient pressure well testing analysis methods for one-dimensional tube-shaped reservoir. The physical model corresponding to the pressure drawdown well testing model is assumed as follows:

1) The reservoir is composed of a single tube-shaped reservoir as shown in FIG. 46;
2) In the initial state, the pressure everywhere in the reservoir is the original reservoir pressure,
3) The fluid flow in the reservoir follows linear flow law or non-linear flow law (in this case, the non-linear flow refers to high-speed non-Darcy flow, but the turbulent flow and non-Newton flow can be solved in the similar way),
4) The fluid and rock in the reservoir are slightly compressible,
5) The wellbore storage effect as well as the skin effect are not considered,

The dimensionless mathematical model corresponding to the pressure drawdown well test model is written as:

$$\begin{matrix}\frac{\partial }{\partial x} ( ρλ \frac{\partial p}{\partial x} ) = \frac{\partial ( ρφ )}{\partial t} & ( 285 ) \\ λ = \{ \begin{matrix}\frac{1}{\frac{μ}{K} + βρ \vert v \vert} , & 0 \leq x < {X}_{1} \\ α \frac{K}{μ} , & {X}_{1} \leq x \leq {X}_{2}\end{matrix} & ( 286 ) \\ ρ = {ρ}_{1} {e}^{{C}_{L} ( p - {p}_{i} )} & ( 287 ) \\ φ = {φ}_{i} {e}^{{C}_{f} ( p - {p}_{i} )} & ( 288 ) \\ A λ \frac{\partial p}{\partial x} {\vert}_{x = 0} = {q}_{0} ( t ) & ( 289 ) \\ A λ \frac{\partial p}{\partial x} {\vert}_{x = {x}_{2}} = {q}_{2} ( t ) & ( 290 ) \\ P {\vert}_{t = 0} = {p}_{i} & ( 291 )\end{matrix}$$

Eq.292 can be obtained by Substituting Eqs.287-288 into Eq.285 and simplifying

$$λ \frac{{\partial }^{2} p}{\partial {x}^{2}} + \frac{\partial λ}{\partial x} \frac{\partial p}{\partial x} = {φ}_{i} ( {C}_{f} + {C}_{L} ) \frac{\partial p}{\partial t} \qquad ( 293 )$$

Note: When the piecewise generalized mobility function is discontinuous at certain point x₀,

$$\frac{\partial λ}{\partial x}$$

takes the average value of the left and right limits at x₀. The above equations are discretized as follows

$$\begin{matrix} {A λ}_{1}^{( k + 1 )} \frac{{p}_{2}^{( k + 1 )} - {p}_{1}^{( k + 1 )}}{{x}_{2} - {x}_{1}} = {q}_{0}^{( k + 1 )} ; k = 1 , 2 , … , K - 1 & ( 294 ) \\ {A λ}_{M}^{( k + 1 )} \frac{{p}_{M}^{( k + 1 )} - {p}_{M - 1}^{( k + 1 )}}{{x}_{M} - {x}_{M - 1}} = {q}_{2}^{( k + 1 )} ; k = 1 , 2 , … , K - 1 & ( 295 ) \\ {P}_{m}^{( 1 )} = {p}_{i} ; m = 1 , 2 , … , M & ( 296 ) \\ {λ}_{m + 1}^{( k + 1 )} [ \frac{2 {p}_{m}^{( k + 1 )}}{( {x}_{m} - {x}_{m + 1} ) ( {x}_{m} - {x}_{m + 2} )} + \frac{2 {p}_{m + 1}^{( k + 1 )}}{( {x}_{m + 1} - {x}_{m} ) ( {x}_{m + 1} - {x}_{m + 2} )} + \frac{2 {p}_{m + 2}^{( k + 1 )}}{( {x}_{m + 2} - {x}_{m} ) ( {x}_{m + 2} - {x}_{m + 1} )} ] + ξ [ {λ}_{m + 1}^{( k + 1 )} ] ξ [ {p}_{m + 1}^{( k + 1 )} ] = {φ}_{i} ( {C}_{f} + {C}_{L} ) \frac{{p}_{m + 1}^{( k + 1 )} - {p}_{m + 1}^{( k )}}{{t}_{k + 1} - {t}_{k}} ; m = 1 , 2 , … , M - 2 ; k = 1 , 2 , … , K - 1 & ( 297 )\end{matrix}$$

Where

$$ξ [ {f}_{m + 1}^{( k + 1 )} ] = \frac{( {x}_{m + 1} - {x}_{m + 2} ) {f}_{m}^{( k + 1 )}}{( {x}_{m} - {x}_{m + 1} ) ( {x}_{m} - {x}_{m + 2} )} + \frac{( {x}_{m} - 2 {x}_{m + 1} + {x}_{m + 2} ) {f}_{m + 1}^{( k + 1 )}}{( {x}_{m} - {x}_{m + 1} ) ( {x}_{m + 1} - {x}_{m + 2} )} + \frac{( {x}_{m + 1} - {x}_{m} ) {f}_{m + 2}^{( k + 1 )}}{( {x}_{m + 2} - {x}_{m} ) ( {x}_{m + 2} - {x}_{m + 1} )} \qquad ( 298 )$$

Eq. 286 is discretized as follows

$${λ}_{m + 1}^{( k + 1 )} = \{ \begin{matrix}{[ \frac{μ}{K} + {βρ}_{i} \vert {v}_{m + 1}^{( k + 1 )} \vert ]}^{- 1} , & 0 \leq {x}_{m + 1} < {X}_{1} \\ α \frac{K}{μ} , & {X}_{1} \leq {x}_{m + 1} \leq {X}_{2}\end{matrix} ; m = 0 , 1 , 2 , … , M - 1 ; k = 1 , 2 , … , κ - 1 \qquad ( 299 )$$

Since the flow velocity vₘ₊₁^{(k+1)} at k+1 step in Eq.298 is unknown, the exact value of λₘ₊₁^{(k+1)} cannot be obtained, which needs further approximate evaluation. For simplicity, the flow rate vₘ₊₁^{(k)} at k step is used to approximate the flow rate vₘ₊₁^{(k+1)} at k+1 step, i.e.,

vₘ₊₁^{(k+1)}≈vₘ₊₁^{(k)}=−λₘ₌₁^{(k)}ξ[pₘ₊₁^{(k+1)}];m=0,2, . . . ,M−1;k=1,2, . . . ,κ−1 (300)

Furthermore

$${λ}_{m + 1}^{( k + 1 )} \approx \{ \begin{matrix}{[ \frac{μ}{K} + {βρ}_{i} \vert {λ}_{m + 1}^{( k )} ξ [ {p}_{m + 1}^{( k + 1 )} ] \vert ]}^{- 1} , & 0 \leq {x}_{m + 1} < {X}_{1} \\ α \frac{K}{μ} , & {X}_{1} \leq {x}_{m + 1} \leq {X}_{2}\end{matrix} ; m = 0 , 1 , 2 , … , M - 1 ; k = 1 , 2 , … , κ - 1 \qquad ( 301 )$$

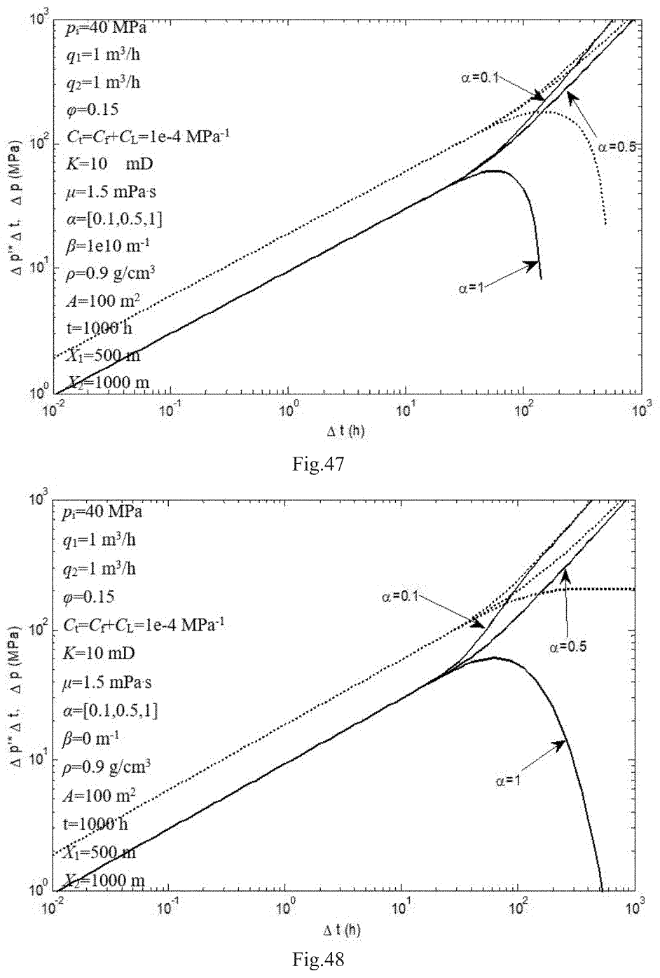

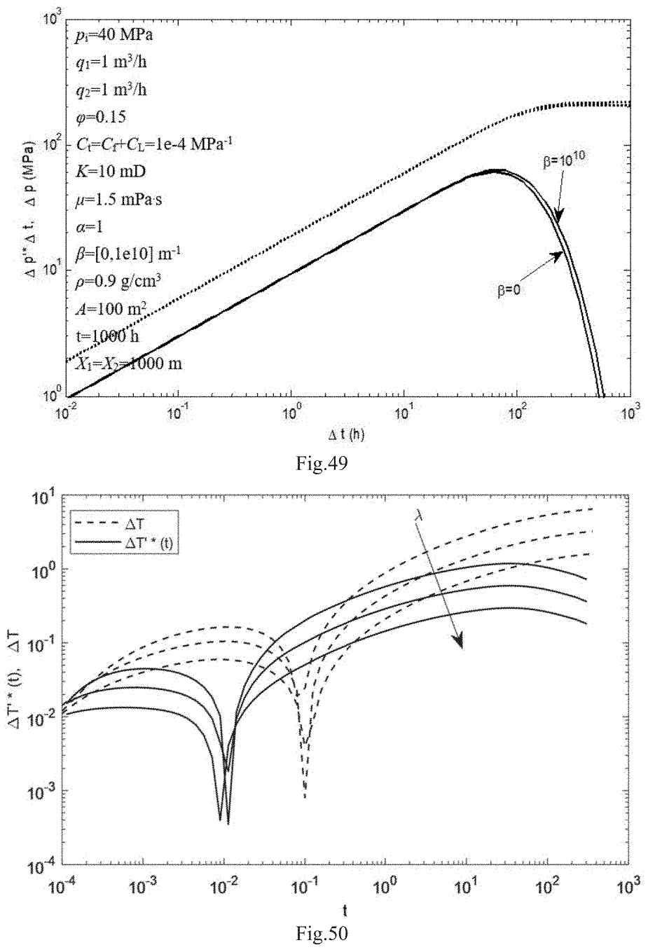

Eq.300 is substituted into Eqs.293-296 to obtain pₘ^{(k+1)}=1, 2, . . . , M is the M-order linear equations of the unknown variables. The pressure distribution at k+1 is obtained by solving the above equations. The relationship between time and pressure can be plotted as shown in FIG. 47-49.

The specific meanings of the identifiers in embodiment 13 ar shown as follows:

A—open flowing area of tube-shaped reservoir, m²; C_{f}—compressibility of rock, 1/Pa; C_{L}—compressibility of fluid, 1/Pa; L—length of tube-shaped reservoir, m; P—pressure of tube-shaped reservoir, Pa; pᵢ—initial pressure of tube-shaped reservoir, Pa; q₀—flow rate at x=0, m³/s; q₂—flow rate at x=X₂, m³/s; t—time, s; x—x-axis distance, m; λ—generalized mobility of tube-shaped reservoir, m²/Pa·s; K—permeability, m²; μ—viscosity of the fluid, Pa·s; α—equation coefficient; β—non-Darcy flow coefficient, 1/m; v—fluid flow velocity, m/s; ϕ, ϕᵢ—porosity and initial porosity in tube-shaped reservoir respectively, %; ρ, ρᵢ—fluid density and initial density in tube-shaped reservoir respectively, kg/m³; m, k—distance and time index number respectively; M, κ—maximum distance and time index number respectively; ∂—partial differential operator.

The shut-in pressure build-up type curves in embodiment 8-12 are calculated by the formula (301) and plotted by performing Stehfest numerical inversion

p̅_{sD}(u)=p̅_{wD}(u)+p̅_{wD}(uₜ_{_{pD}})−p̅_{wD}(uₜ_{_{pD}}₊ₜ_{_{D}}) (302)

where t_{pD} is the dimensionless production time before shut-in, explanation of p̅_{wD} refers embodiments 8 to 12.

The wellbore storage effect and skin effect are considered in the bottom hole pressure expression in embodiment 8-12 by Duhamel principle as

$${\overline{P}}_{wD , {C}_{D} , S} = \frac{{\overline{P}}_{wD} u + S}{u + {u}^{2} {C}_{D} ( {\overline{P}}_{wD} u + S )} \qquad ( 303 )$$

where explanation of p̅_{wD} refers embodiments 8 to 12.

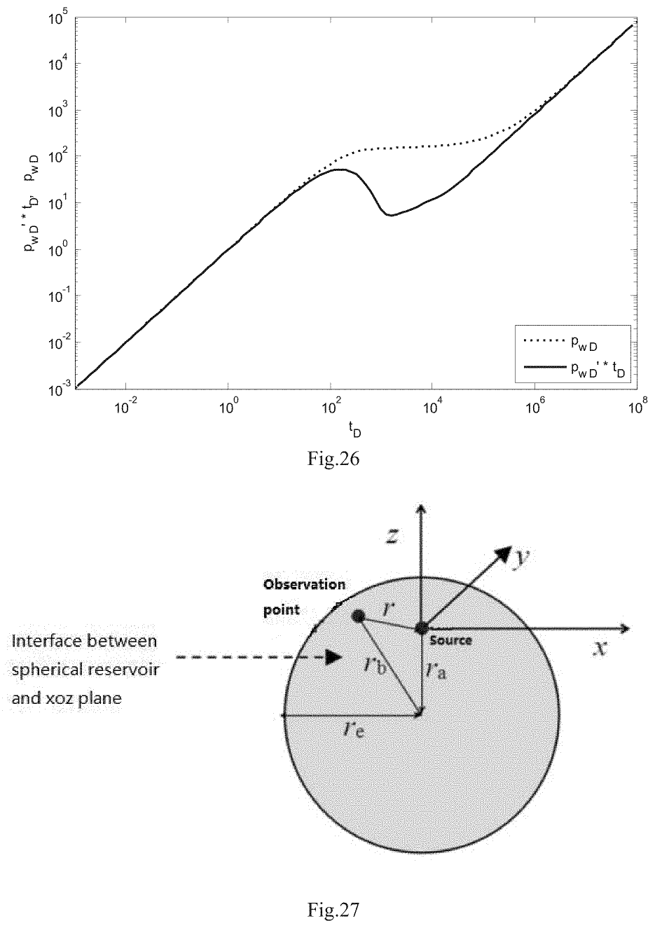

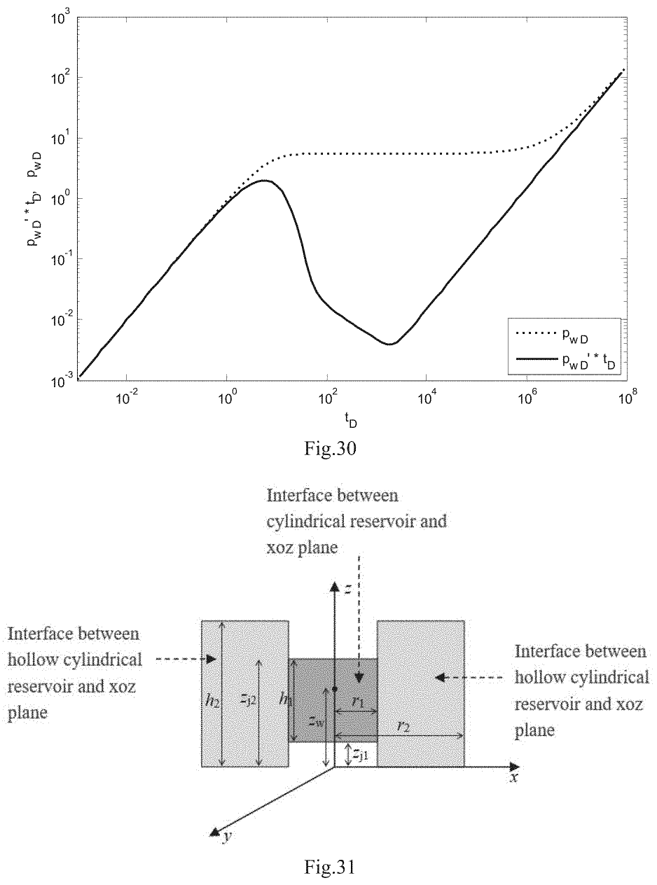

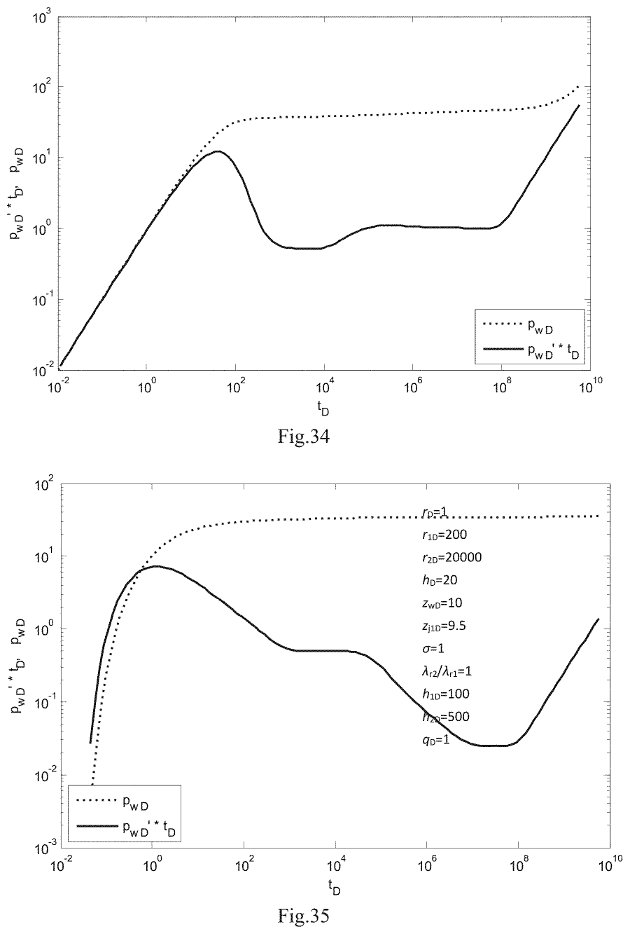

By applying this method, typical pressure draw-down type curves with consideration of skin effect and wellbore storage effects from embodiment 8 to 12 can be plotted as FIG. 19, FIG. 23, FIG. 26. FIG. 30, FIG. 34, FIG. 37, and FIG. 41. Typical pressure build-up type curves can also be plotted in the same way by using Eq.301.

### Embodiment 14

This embodiment provides a multi-component condensate gas flow simulation analysis method for complex reservoirs. The model assumptions are as follows:

(1) Oil/gas/water three phases fluids are in the reservoir. The fluid flow is an isothermal process,
(2) The phase equilibrium of hydrocarbon components in oil and gas phase is completed in a flash,
(3) Water is an independent component and there is no mass exchange between hydrocarbons and water.
(4) Rocks are slightly compressible.
(5) Heterogeneity and anisotropy of the reservoirs are considered.

The multi-component condensate gas flow simulation analysis for complex reservoirs are created based on the assumptions above:

Water phase governing equation:

$$[ ∇ \cdot ( {ρ}_{w} {λ}_{w} ∇ {p}_{w} ) ] = \frac{\partial }{\partial t} [ φ ( {ρ}_{w} {S}_{w} ) ] + {q}_{w} , ( x , t ) ∈ Ω \times ( 0 , {t}_{max} ] \qquad ( 304 )$$

Hydrocarbon components governing equation in oil and gas phase

$$[ ∇ \cdot {\sum }_{k = o , g} ( {ρ}_{k} {C}_{ik} {λ}_{k} ∇ {p}_{k} ) ] = \frac{\partial }{\partial t} [ φ {\sum }_{k = o , g} ( {ρ}_{k} {S}_{k} {C}_{k} ) ] + {\sum }_{k = o , g} {q}_{ik} , ( x , t ) ∈ Ω \times ( 0 , {t}_{max} ] , i = 1 , 2 , … , {n}_{c} \qquad ( 305 )$$

Auxiliary equations with saturation and capillary pressure:

Saturation equation

$${\sum }_{k = o , g , w} {S}_{k} = 1 , ( x , t ) ∈ Ω \times ( 0 , {t}_{max} ] \qquad ( 306 )$$

Capillary pressure equation at α-β phase interface

p_{cαβ}(S_{w})=p_{α}p_{β},(x,t)∈Ω×(0,tₘₐₓ],α=o,g,w;β=o,g,w (307)

Phase equilibrium equation:

The equilibrium constant of hydrocarbon component i in oil and gas phase:

K_{iog}=Cᵢₒ/C_{ig},i=1, . . . ,n_{c} (308)

The total mole percent of hydrocarbon component i in oil and gas phase:

$${Z}_{i} = {\sum }_{k = o , g} {C}_{ik} {n}_{k}^{\%} , i = 1 , … , {n}_{c} \qquad ( 309 )$$

Mole percentage normalization condition of hydrocarbon components in each phase:

$${\sum }_{i = 1}^{{n}_{c}} {C}_{ik} = 1 , k = o , g \qquad ( 31 )$$

Normalizing conditions for ratio of moles of each phase to the whole system:

$${\sum }_{i = 1}^{{n}_{c}} {n}_{k}^{\%} = 1 , k = o , g \qquad ( 311 )$$

Boundary condition equation:

Boundary condition equation of each phase

$$( {c}_{k , 1} {p}_{k} + {c}_{k , 2} {λ}_{k} \frac{\partial {p}_{k}}{\partial {n}^{\partial Ω}} ) = {g}_{k} ( ϰ , t ) , ( ϰ , t ) ∈ \partial Ω \times ( 0 , {t}_{max} ] , k = 0 , g , w \qquad ( 312 )$$

Initial saturation equation:

Initial saturation equation of each phase

Sₖ(x,0)=lₖ(x),x∈Ω,k=o,g,w (313)

Initial pressure equation:

Initial pressure equation of each phase

pₖ(x,0)=ƒₖ(x),x∈Ω,k=o,g,w (314)

Variable symbols description in multi-component multi-phase flow simulation analysis equations: ϕ is porosity, which is the function of average pressure p̅, %; n_{c} is the total component number, dimensionless; λₖ is the generalized mobility of k-phase, m²/(Pa·s); ρₖ is density of k-phase, kg/m³; Sₖ is the k-phase saturation, t is time, s; tₘₐₓ is the total time, s; pₖ is the k-phase pressure, Pa; lₖ is the k-phase initial saturation distribution function; qᵢₖ is the source/sink term of hydrocarbon component i in k-phase, kg/(m³·s); ƒₖ is the k-phase initial pressure distribution function, Pa; K_{iog} is the hydrocarbon equilibrium constant of component i in α and β phase, dimensionless; Cᵢₖ is the mole percent of hydrocarbon component i in k-phase, dimensionless; Zᵢ is the total mole percent of component i, dimensionless; [symbol] is the ratio of k-phase to the whole system, dimensionless; gₖ is the boundary functions of k-phase on reservoir boundary, dimensionless; p_{cαβ} is the capillary pressure at α-β phase interface, Pa; Ω is reservoir space; ∂Ω is reservoir boundary including internal boundary and outer boundary; c_{k,1} is the pressure term coefficients of k-phase on reservoir boundary, 1/Pa; c_{k,2} is the k-phase coefficients of directional derivative term along the normal direction outside the boundary on reservoir boundary condition, s/m; n^{∂Ω} is outer normal direction on reservoir boundary, m; ∇ is the Hamilton operator; ∂ is the partial derivative sign.

### Embodiment 15

This embodiment provides a multi-component carbon dioxide driven flow simulation analysis method for complex reservoirs. The model assumptions are as follows:

(1) Oil/gas/water three phases fluids are in the reservoir. The fluid flow is a isothermal process,
(2) The phase equilibrium of hydrocarbon components in oil and gas phase is completed in a flash,
(3) Rocks are slightly compressible.
(4) Heterogeneity and anisotropy of the reservoirs are considered.
(5) Carbon dioxide diffusion is considered.

The multi-component carbon dioxide drive flow simulation analysis for complex reservoirs are created based on the assumptions above:

$$[ ∇ \cdot {\sum }_{k = o , g , w} ( {ρ}_{k} {C}_{ik} {λ}_{k} ∇ {p}_{k} ) ] + [ ∇ \cdot {\sum }_{k = o , g , w} ( φ {ρ}_{k} {S}_{k} {D}_{ik} ∇ {C}_{ik} ) ] = \frac{\partial }{\partial t} [ φ {\sum }_{k = o , g , w} ( {ρ}_{k} {S}_{k} {C}_{ik} ) ] + {\sum }_{k = o , g , w} {q}_{ik} , ( ϰ , t ) ∈ Ω \times ( 0 , {t}_{max} ] , i = 1 , 2 , … , {n}_{c} \qquad ( 315 )$$

Auxiliary equations with saturation and capillary pressure:

Saturation equation

$${\sum }_{k = o , g , w} {S}_{k} = 1 , ( ϰ , t ) ∈ Ω \times ( 0 , {t}_{max} ] \qquad ( 316 )$$

Capillary pressure equation at α-β phase interface

p_{cαβ}(S_{w})=pₐ-p_{β},(x,t)∈Ω×(0,tₘₐₓ],α=o,g,w;β=o,g,w (317)

Phase equilibrium equation:

The equilibrium constant of component i in α and β phase:

K_{iαβ}=C_{iα}/C_{iβ},α=o,g,w;β=o,g,w;i=1, . . . ,n_{c} (318)

The total mole percent of component i:

$${Z}_{i} = {\sum }_{k = o , g , w} {C}_{lk} {n}_{k}^{\%} , i = 1 , … , {n}_{c} \qquad ( 319 )$$

Mole percentage normalization condition of components in each phase:

$${\sum }_{i = 1}^{{n}_{c}} {C}_{ik} = 1 , k = o , g , w \qquad ( 320 )$$

Normalizing conditions for ratio of moles of each phase to the whole system:

$${\sum }_{i = 1}^{{n}_{c}} {n}_{k}^{\%} = 1 , k = o , g , w \qquad ( 321 )$$

Boundary condition equation:

Boundary condition equation of each phase

$$( {c}_{k , 1} {p}_{k} + {c}_{k , 2} {λ}_{k} \frac{\partial {p}_{k}}{\partial {n}^{\partial Ω}} ) = {g}_{k} ( ϰ , t ) , ( ϰ , t ) ∈ \partial Ω \times ( 0 , {t}_{max} ] , k = o , g , w \qquad ( 322 )$$

Initial saturation equation:

Initial saturation equation of each phase

Sₖ(x,0)=lₖ(x),x∈Ω,k=o,g,w (323)

Initial pressure equation:

Initial pressure equation of each phase

pₖ(x,0)=ƒₖ(x),x∈Ω,k=o,g,w (324)

Variable symbols description in multi-component multi-phase flow simulation analysis equations: ϕ is porosity, which is the function of average pressure p̅, %; n_{c} is the total component number, dimensionless; λₖ is the generalized mobility of k-phase, m²/(Pa·s); ρₖ is density of k-phase, kg/m³; Vᵢ is adsorption amount of component i, dimensionless; Sₖ is the k-phase saturation; t is time, s; tₘₐₓ is the total time, s; pₖ is the k-phase pressure, Pa; lₖ is the k-phase initial saturation distribution function; qᵢₖ is the source/sink term of component i in k-phase, kg/(m³·s); ƒₖ is the k-phase initial pressure distribution function, Pa; K_{ioβ} is the equilibrium constant of component i in α and β phase, dimensionless; Cᵢₖ is the mole percent of component i in k-phase, dimensionless; Dᵢₖ is the diffusion coefficient of component i in k-phase, m²/s; Zᵢ is the total mole percent of component i, dimensionless; [symbol] is the ratio of k-phase to the whole system, dimensionless; gₖ is the boundary functions of k-phase on reservoir boundary, dimensionless; p_{cαβ} is the capillary pressure at α-β phase interface, Pa; Ω is reservoir space; ∂Ω is reservoir boundary including internal boundary and outer boundary; c_{k,1} is the pressure term coefficients of k-phase on reservoir boundary, 1/Pa; c_{k,2} is the k-phase coefficients of directional derivative term along the normal direction outside the boundary on reservoir boundary condition, s/m; n^{∂Ω} is outer normal direction on reservoir boundary, m; ∇ is the Hamilton operator; ∂ is the partial derivative sign.

### Embodiment 16

This embodiment provides a multi-component polymer driven flow simulation analysis method for complex reservoirs. The model assumptions are as follows:

(1) Oil/gas/water three phases fluids are in the reservoir. The fluid flow is a isothermal process,
(2) The fluid flow phase equilibrium is completed in a flash,
(3) Rocks are slightly compressible.
(4) Heterogeneity and anisotropy of the reservoirs are considered.
(5) Diffusion and adsorption of polymer are considered.

The multi-component polymer driven flow simulation analysis for complex reservoirs are created based on the assumptions above:

$$[ ∇ \cdot {\sum }_{k = o , g , w} ( {ρ}_{k} {C}_{ik} {λ}_{k} ∇ {p}_{k} ) ] + [ ∇ \cdot {\sum }_{k = o , g , w} ( φ {ρ}_{k} {S}_{k} {D}_{ik} ∇ {C}_{ik} ) ] = \frac{\partial }{\partial t} [ φ {\sum }_{k = o , g , w} ( {ρ}_{k} {S}_{k} {C}_{ik} ) ] + \frac{\partial }{\partial t} [ ( 1 - φ ) {ρ}_{r} {V}_{i} ] + {\sum }_{k = o , g , w} {q}_{ik} , \\ ( ϰ , t ) ∈ Ω \times ( 0 , {t}_{max} ] , i = 1 , 2 , … , {n}_{c} \qquad ( 325 )$$

Auxiliary equations with saturation and capillary pressure:

Saturation equation

$${\sum }_{k = o , g , w} {S}_{k} = 1 , ( ϰ , t ) ∈ Ω \times ( 0 , {t}_{max} ] \qquad ( 326 )$$

Capillary pressure equation at α-β phase interface

p_{cαβ}(S_{w})=ρ_{α}-ρ_{β},(x,t)∈Ω×(0,tₘₐₓ],α=o,g,w;β=o,g,w (327)

Phase equilibrium equation:

The equilibrium constant of component i in α and β phase:

K_{iαβ}=C_{iα}/C_{iβ},α=o,g,w,β=o,g,w,i=, . . . ,n_{c} (328)

The total mole percent of component i:

$${Z}_{i} = {\sum }_{k = o , g , w}^{ } {c}_{lk} {n}_{k}^{\%} , i = 1 , … , {n}_{c} \qquad ( 329 )$$

Mole percentage normalization condition of components in each phase:

$${\sum }_{i = 1}^{{n}_{c}} {C}_{ik} = 1 , k = o , g , w \qquad ( 330 )$$

Normalizing conditions for ratio of moles of each phase to the whole system:

$${\sum }_{i = 1}^{{n}_{c}} {n}_{k}^{\%} = 1 , k = o , g , w \qquad ( 331 )$$

Boundary condition equation

Boundary condition equation of each phase

$$( {c}_{k , 1} {p}_{k} + {c}_{k , 2} {λ}_{k} \frac{\partial {p}_{k}}{\partial {n}^{\partial Ω}} ) = {g}_{k} ( ϰ , t ) , ( ϰ , t ) ∈ \partial Ω \times ( 0 , {t}_{max} ] , k = o , g , w \qquad ( 332 )$$

Initial saturation equations:
Initial saturation equation of each phase

Sₖ(x,0)=lₖ(x),x∈Ω,k=o,g,w (333)
Initial pressure equation:
Initial pressure equation of each phase

pₖ(x,0)=ƒₖ(x),x∈Ω,k=o,g,w (334)

Variable symbols description in multi-component multi-phase flow simulation analysis equations: ϕ is porosity, which is the function of average pressure p̅, %; n_{c} is the total component number, dimensionless; λₖ is the generalized mobility of k-phase, m²/(Pa·s); ρₖ, ρᵣ are densities of k-phase and rock, kg/m³; Vᵢ is adsorption amount of component i, dimensionless; Sₖ is the k-phase saturation; t is time, s; tₘₐₓ is the total time, s; pₖ is the k-phase pressure, Pa; lₖ is the k-phase initial saturation distribution function; qᵢₖ is the source/sink term of component i in k-phase, kg/(m³·s); ƒₖ is the k-phase initial pressure distribution function, Pa; K_{iαβ} is the equilibrium constant of component i in α and β phase, dimensionless; Cᵢₖ is the mole percent of component i in k-phase, dimensionless; Dᵢₖ is the diffusion coefficient of component i in k-phase, m²/s; Zᵢ is the total mole percent of component i, dimensionless; [symbol] is the ratio of k-phase to the whole system, dimensionless; gₖ is the boundary functions of k-phase on reservoir boundary, dimensionless; p_{cαβ} is the capillary pressure at α-β phase interface, Pa; Ω is reservoir space; ∂Ω is reservoir boundary including internal boundary and outer boundary; c_{k,1} is the pressure term coefficients of k-phase on reservoir boundary, 1/Pa; c_{k,2} is the k-phase coefficients of directional derivative term along the normal direction outside the boundary on reservoir boundary condition, s/m; n^{∂Ω} is outer normal direction on reservoir boundary, m; ∇ is the Hamilton operator; ∂ is the partial derivative sign.

### Embodiment 17

This embodiment provides a multi-component three-phase flow simulation analysis method considering non-isothermal process in complex reservoirs.

(1) Oil/gas/water three phases fluids are in the reservoir. The fluid flow is a non-isothermal process,
(2) The fluid flow phase equilibrium is is completed in a flash,
(3) Rocks are slightly compressible,
(4) Heterogeneity and anisotropy of the reservoirs are considered.

The multi-component three-phase flow simulation analysis for complex reservoirs considering temperature change are created based on the assumptions above:

Component governing equations:

$$[ ∇ \cdot {\sum }_{k = o , g , w} ( {ρ}_{k} {C}_{ik} {λ}_{k} ∇ {p}_{k} ) ] = \frac{\partial }{\partial t} [ φ {\sum }_{k = o , g , w} ( {ρ}_{k} {S}_{k} {C}_{ik} ) ] , \\ ( ϰ , t ) ∈ Ω \times ( 0 , {t}_{max} ] , i = 1 , 2 , … , {n}_{c} \qquad ( 335 )$$

Energy conservation equation:

$$[ ∇ \cdot {\sum }_{k = 0 , w , g} ( {π}_{k} {ρ}_{k} {λ}_{k} ∇ {p}_{k} ) ] + [ ∇ \cdot κ ∇ T ] = \frac{\partial }{\partial t} [ φ {\sum }_{k = o , w , g} ( {ρ}_{k} {S}_{k} {U}_{k} ) ] + \frac{\partial }{\partial t} [ ( 1 - φ ) {ρ}_{r} {U}_{r} ] , \\ ( x , t ) ∈ Ω \times ( 0 , {t}_{max} ] \qquad ( 336 )$$

Auxiliary equations with saturation and capillary pressure:

Saturation equation

$${\sum }_{k = o , w , g} {S}_{k} = 1 , ( x , t ) ∈ Ω \times ( 0 , T ] \qquad ( 337 )$$

Capillary pressure equation at α-β phase interface

p_{cαβ}(S_{w})=p_{α}−p_{β},(x,t)∈Ω×(0,T],α=o,w,gₚ;β=o,w,g (338)

Phase equilibrium equation:

The equilibrium constant of component i in α and β phase:

K_{iαβ}=C_{iα}/C_{iβ},α=o,w,g;β=o,w,g;i=, . . . ,n_{c} (339)

Mole percentage normalization condition of components in each phase:

$${\sum }_{i = 1}^{{n}_{c}} {C}_{ik} = 1 , k = o , w , g \qquad ( 340 )$$

The total mole percent of component i:

$${Z}_{i} = {\sum }_{k = o , w , g} {C}_{ik} , i = 1 , … , {n}_{c} \qquad ( 341 )$$

Normalizing conditions for ratio of moles of each phase to the whole system:

$${\sum }_{i = 1}^{{n}_{c}} = 1 , k = o , w , g \qquad ( 342 )$$

Boundary condition equations:

Boundary condition equation of pressure for each phase

$$( {c}_{k , 1} {p}_{k} + {c}_{k , 2} {λ}_{k} \frac{\partial {p}_{k}}{\partial {n}^{\partial Ω}} ) = {g}_{k} ( x , t ) , ( x , t ) ∈ \partial Ω \times ( 0 , {t}_{max} ] , k = o , w , g \qquad ( 343 )$$

Boundary condition equation of temperature

$$( {d}_{1} T + {d}_{2} κ \frac{\partial T}{\partial {n}^{\partial Ω}} ) = w ( x , t ) , ( x , t ) ∈ \partial Ω \times ( 0 , {t}_{max} ] \qquad ( 344 )$$

Initial saturation equation:

Initial saturation equation of each phase

Sₖ(x,0)=lₖ(x),x∈Ω,k=o,w,g (345)

Initial pressure equation:

Initial pressure equation of each phase

pₖ(x,0)=ƒₖ(x),x∈Ω,k=o,w,g (346)

Initial temperature equation:

T(x,0)=τ(x),x∈Ω (347)

Variable symbols description in thermal multi-component three-phase flow simulation analysis equations: ϕ is porosity, which is the function of average pressure p̅, %; n_{c} is the total component number, dimensionless; λₖ is the generalized mobility of k-phase, m²/(Pa·s); ρₖ, ρᵣ are densities of k-phase and rock, kg/m³; πₖ is enthalpy of k phase, J/kg; Uₖ, Uᵣ are internal energy of k-phase and rock, J/kg; Sₖ is the k-phase saturation; t is time, s; tₘₐₓ is the maximum of time, s; pₖ is the k-phase pressure, Pa; lₖ is the k-phase initial saturation distribution function; ƒₖ is the k-phase initial pressure distribution function, Pa; K_{iαβ} is the equilibrium constant of component i in α and β phase, dimensionless; Cᵢₖ is the mole percent of component i in k-phase, dimensionless; Zᵢ is the total mole percent of component i, dimensionless; [symbol] is the ratio of k-phase to the whole system, dimensionless; gₖ is the boundary functions of k-phase on reservoir boundary, dimensionless; w is boundary function of temperature on reservoir boundary, dimensionless; τ is the initial temperature distribution function of reservoirs, K; p_{cαβ} is the capillary pressure at α-β phase interface, Pa; Ω is reservoir space; ∂Ω is reservoir boundary including internal boundary and outer boundary; c_{k,1} is the pressure term coefficients of k-phase on reservoir boundary, 1/Pa; c_{k,2} is the k-phase coefficients of derivative terms along the outer normal line on reservoir boundary condition, s/m; d₁ is the temperature term coefficient on reservoir boundary, 1/K; d₂ is temperature coefficients of directional derivative term along the normal direction outside the boundary on reservoir boundary condition, s·m²/J; κ is the thermal conductivity, J/(m·s·K); n^{∂Ω} is outer normal direction on reservoir boundary, m; ∇ is the Hamilton operator; ∂ is the partial derivative sign.

### Embodiment 18

This embodiment provides a transient temperature analysis method for single oil phase flow.

(1) oil single phase fluid in the reservoir, the fluid flow is a non-isothermal process,
(2) both fluids and rocks are slightly compressible,
(3) the same thickness in the reservoir,
(4) well is a vertical well, fully penetrating the entire formation thickness,
(5) there exists no heat transfer to over- and under-burden strata from the reservoir.

The transient temperature analysis model for oil single-phase is created based on the assumptions above:

Governing equations:

$$\frac{1}{r} \frac{\partial }{\partial r} ( r \frac{\partial p}{\partial r} ) = \frac{φ {C}_{i}}{λ} \frac{\partial p}{\partial t} \qquad ( 348 )$$

Energy conservation equation:

$$\frac{\partial T}{\partial t} - {C}_{pR} λ \frac{\partial p}{\partial r} \frac{\partial T}{\partial r} - \frac{{α}_{t}}{r} \frac{\partial }{\partial r} ( r \frac{\partial T}{\partial r} ) = ϕ * \frac{\partial p}{\partial t} - {ɛ}_{JT} {C}_{pR} λ \frac{\partial p}{\partial r} \frac{\partial p}{\partial r} \qquad ( 349 )$$

Boundary condition equation of pressure

$$\{ \begin{matrix}2 π hr λ \frac{\partial p}{\partial r} {\vert}_{r = {r}_{w}} = qB + C \frac{\partial {p}_{w}}{\partial t} \\ {p}_{w} = ( p - Sr \frac{\partial p}{\partial r} ) {\vert}_{r = {r}_{w}} \\ {lim}_{r ∞} p = {p}_{i}\end{matrix} \qquad ( 350 )$$

Boundary condition equation of temperature

$$\{ \begin{matrix}r \frac{\partial T}{\partial r} {\vert}_{r = {r}_{w}} = 0 \\ {lim}_{r ∞} T = {T}_{i}\end{matrix} \qquad ( 351 )$$

Initial pressure equation:

P|ₜ₌₀=pᵢ (352)

Initial temperature equation:

T|ₜ₌₀=Tᵢ (353)

Model solution:

Defining the dimensionless pressure distribution function

$${p}_{D} = \frac{2 πλ h ( {p}_{i} - p )}{qB} ,$$

dimensionless bottom-hole pressure function

$${p}_{wD} = \frac{2 πλ h ( {p}_{i} - {p}_{w} )}{qB} ,$$

dimension time

$${t}_{D} = \frac{λ t}{φ {C}_{t} {r}_{w}^{2}} ,$$

dimensionless radial distance

$${r}_{D} = \frac{r}{{r}_{w}} ,$$

dimensionless wellbore storage coefficient

$${C}_{D} = \frac{C}{2 {πφ C}_{t} {hr}_{w}^{2}} ,$$

then convert Eqs.347, 349, 351 into dimensionless equations.

$$\begin{matrix}\frac{1}{{r}_{D}} \frac{\partial }{\partial {r}_{D}} ( {r}_{D} \frac{\partial {p}_{D}}{\partial {r}_{D}} ) = \frac{\partial {p}_{D}}{\partial {t}_{D}} & ( 354 ) \\ \{ \begin{matrix}{r}_{D} \frac{\partial {p}_{D}}{\partial {r}_{D}} {\vert}_{{r}_{D} = 1} = - 1 + {C}_{D} \frac{\partial {p}_{wD}}{\partial {t}_{D}} \\ {p}_{wD} = ( {p}_{D} - {Sr}_{D} \frac{\partial {p}_{D}}{\partial {r}_{D}} ) {\vert}_{{r}_{D} = 1} \\ {lim}_{{r}_{D} \to ∞} {p}_{D} = 0\end{matrix} & ( 355 ) \\ {p}_{D} {\vert}_{{t}_{D} = 0} = 0 & ( 356 )\end{matrix}$$

The Laplace space pressure distribution function can be obtained by conducting Laplace transformation to Eqs.353, 354, 355 based on to as

$${\overline{p}}_{D} = \frac{{K}_{0} ( \sqrt{u} {r}_{D} )}{u ( \sqrt{u} {C}_{D} {SuK}_{1} ( \sqrt{u} ) + {C}_{D} {uK}_{0} ( \sqrt{u} ) + \sqrt{u} {K}_{1} ( \sqrt{u} ) )} \qquad ( 357 )$$

The pressure distribution function p_{D} in real space can be obtained through Laplace inverse transformation of Eq.356, then the pressure p_{D} is converted to dimensional form as

$$p = {p}_{i} - \frac{qB}{2 λ h} {p}_{D} \qquad ( 358 )$$

Substitute Eq.357 into Eq. 348 to obtain the differential equation of temperature about time and radial distance, which cannot be solved by analytical solutions so that it need to be solved through numerical methods to obtain numerical solutions that satisfy solution conditions of Eqs.350 and 352.

Variable symbols description in single oil phase flow transient temperature analysis equations: ϕ is porosity, %; λ is the generalized mobility, m²/(Pa·s); ρ is the density, kg/m³; t is time, s; tₘₐₓ is the maximum of time, s; p is the pressure, Pa; T is the temperature, K; Tᵢ is the initial temperature, K; q is he flow rate, m³/s; B is the volume factor, dimensionless; h is the reservoir thickness, m; p_{w} is the bottom-hole pressure, Pa; Cₜ is the total compressibility, 1/MPa; pᵢ is the initial pressure, Pa; ∇ is the Hamilton operator; ∂ is the partial derivative sign; C_{pR} is the ratio of volumetric heat capacity of a fluid to that of a saturated fluid rock, dimensionless; αₜ is the thermal diffusion of saturated fluid rocks, m²/s; φ* is the effective heat expansion coefficient, K/Pa; ε_{JT} is the Joule-Thomson coefficient, K/Pa; C is the wellbore storage coefficient, m³/Pa; S is the skin factor, dimensionless; r_{w} is the wellbore radius, m; u is the Laplace variable corresponding to dimensionless time t_{D}.

The embodiments given above are some typical examples of realizing this invention, but this invention is not limited to these examples. Any non-essential addition or substitution based on the technical features of the invention made by the technicians in the field all belong to the protection range of this invention.

1. A flow simulation and transient well analysis method based on generalized tube flow and percolation coupling, characterized in comprising the following steps:
S1: Based on defining the generalized mobility, fluid flow laws in different subset of study area are characterized by using the generalized mobility models with the same form;
S2: On the basis of generalized mobility, the multi-component multi-phase flow governing equations are established by considering convection term, diffusion term, accumulation term, adsorption term, and source/sink term. Then a whole set of multi-component multi-phase flow simulation equations are formed through combining energy conservation equation, auxiliary equations with saturation and capillary pressure, initial saturation equation, initial pressure equation, initial temperature equation, phase equilibrium equation, and boundary condition equations;
The pressure, temperature and saturation of multi-phase fluid as well as the mole percentage of each component in each phase at any point in the study areas are obtained by solving the above-mentioned multi-component multi-phase flow simulation equations;
S3: The corresponding application software are formed by using the established multi-component multi-phase flow simulation and analysis equations.

2. The flow simulation and transient well analysis method based on generalized tube flow and percolation coupling as claimed according to claim 1, characterized in that the details of step S1 is as follows:
S11: For any type of fluid motion equation, if it can be written as v=−λ∇p, λ is called generalized mobility. where v denotes the fluid flow velocity, ∇p denotes the pressure gradient, and the generalized mobility λ is a function of space position and time;
S12 The general mobility models with the same form are used to characterize the flow laws of fluid in the tube flow area of wellbores, pipes, fractures, vugs, holes, cavities, caves, fracture caves, karst caves and caverns, and the percolation area of porous media.

3. The flow simulation and transient well analysis method based on generalized tube flow and percolation coupling as claimed according to claim 1, characterized in that the details of step S2 is as follows:
S21: The generalized mobility of three-dimensional multi-phase flow
$${λ}_{k} = [ \begin{matrix}{λ}_{k , xx} ( x , t ) & {λ}_{k , xy} ( x , t ) & {λ}_{k , xz} ( x , t ) \\ {λ}_{k , yx} ( x , t ) & {λ}_{k , yy} ( x , t ) & {λ}_{k , yz} ( x , t ) \\ {λ}_{k , zx} ( x , t ) & {λ}_{k , zy} ( x , t ) & {λ}_{k , zz} ( x , t )\end{matrix} ] ,$$
where k=1, 2, . . . , nₚ, nₚ denotes the total phase number, x denotes space position, t denotes time, 9 components of generalized mobility λ_{k,xx}, λ_{k,xy}, λ_{k,xz}, λ_{k,yx}, λ_{k,yy}, λ_{k,yz}, λ_{k,zx}, λ_{k,zy}, λ_{k,zz} are all functions of space position x and time t;
S22: Rewriting the three-dimensional multi-phase flow motion equation into a standard form vₖ=−λₖ∇pₖ by applying three-dimensional multi-phase flow generalized mobility, where k=1, 2, . . . , nₚ, nₚ denotes the total phase number,
$$∇ = {( \frac{\partial }{\partial x} , \frac{\partial }{\partial y} , \frac{\partial }{\partial z} )}^{T}$$
is Hamilton operator, vₖ is fluid velocity of k-phase, pₖ is pressure of k-phase;
S23: Multi-component multi-phase flow simulation equations
The multi-component multi-phase flow equations considering convection term, diffusion term, accumulation term, adsorption term, and source/sink term are written as:
Component governing equation:
$$[ ∇ \cdot {\sum }_{k = 1}^{{n}_{p}} ( {ρ}_{k} {C}_{ik} {λ}_{k} ∇ {p}_{k} ) ] + [ ∇ \cdot {\sum }_{k = 1}^{{n}_{p}} ( {φρ}_{k} {S}_{k} {D}_{ik} ∇ {C}_{ik} ) ] = \frac{\partial }{\partial t} [ φ {\sum }_{k = 1}^{{n}_{p}} ( {ρ}_{k} {S}_{k} {C}_{ik} ) ] + \frac{\partial }{\partial t} [ ( 1 - φ ) {ρ}_{r} {V}_{i} ] + { \sum }_{k = 1}^{{n}_{p}} {C}_{ik} {q}_{k} , \\ ( x , t ) ∈ Ω \times ( 0 , {t}_{max} ] , i = 1 , 2 , ... , {n}_{c}$$
Energy conservation equation:
$$[ ∇ \cdot {\sum }_{k = 1}^{{n}_{p}} ( {}_{k} {ρ}_{k} {λ}_{k} ∇ {p}_{k} ) ] + [ ∇ \cdot κ ∇ T ] = \frac{\partial }{\partial t} [ φ {\sum }_{k = 1}^{{n}_{p}} ( {ρ}_{k} {S}_{k} {U}_{k} ) ] + \frac{\partial }{\partial t} [ ( 1 - φ ) {ρ}_{t} {U}_{r} ] + { \sum }_{k = 1}^{{n}_{p}} {}_{k} {q}_{k} , \\ ( x , t ) ∈ Ω \times ( 0 , {t}_{max} ]$$
Auxiliary equations with saturation and capillary pressure:
Saturation equation
$${\sum }_{k = 1}^{{n}_{p}} {S}_{k} = 1 , ( x , t ) ∈ Ω \times ( 0 , {t}_{max} ]$$
Capillary pressure equation at α-β phase interface
p_{cαβ}(S_{w})=p_{α}-p_{β},(x,t)∈Ω×(0,T],α=1, . . . ,nₚ;β=1, . . . ,nₚ
Phase equilibrium equation:
The phase equilibrium constant of component i in α and β phase:
K_{iαβ}=C_{iα}/C_{iβ},α=1, . . . ,nₚ;β=1, . . . ,nₚ;i=1, . . . ,n_{c}
Mole percentage normalization condition of components in each phase:
$${\sum }_{i = 1}^{{n}_{c}} {C}_{ik} = 1 , k = 1 , ... , {n}_{p}$$
The total mole percent of component i:
$${Z}_{i} = {{\sum }_{k = 1}}^{{n}_{p}} {C}_{ik} , i = 1 , ... , {n}_{c}$$
Normalization conditions for ratio of moles of each phase to the whole system:
$${\sum }_{i = 1}^{{n}_{c}} = 1 , k = 1 , ... , {n}_{p}$$
Boundary condition equations:
Boundary condition equation of pressure for each phase
$$( {c}_{k , 1} {p}_{k} + {c}_{k , 2} {λ}_{k} \frac{\partial {p}_{k}}{\partial {n}^{\partial Ω}} ) = {g}_{k} ( x , t ) , ( x , t ) ∈ \partial Ω \times ( 0 , {t}_{max} ] , \\ k = 1 , ... , {n}_{p}$$
Boundary condition equation of temperature
$$( {d}_{1} T + {d}_{2} κ \frac{\partial T}{\partial {n}^{\partial Ω}} ) = w ( x , t ) , ( x , t ) ∈ \partial Ω \times ( 0 , {t}_{max} ]$$
Initial saturation equation:
Initial saturation equation of each phase
Sₖ(x,0)=lₖ(x),x∈Ω,k=1, . . . ,nₚ
Initial pressure equation:
Initial pressure equation of each phase
pₖ(x,0)=ƒₖ(x),x∈Ω,k=1, . . . ,nₚ
Initial temperature equation:
T(x,0)=τ(x),x∈Ω
Variable symbols description in multi-component multi-phase flow simulation analysis equations: ϕ is porosity, which is the function of average pressure p̅, %; n_{c} is the total component number, dimensionless; nₚ is the total phase number, dimensionless; λₖ is the generalized mobility of k-phase, m²/(Pa·s); ρk, ρᵣ are densities of k-phase and rock, kg/m³; πₖ is enthalpy of k phase, J/kg; Uₖ, Uᵣ are internal energy of k-phase and rock, J/kg; Vᵢ is adsorption amount of component i, dimensionless; Sₖ is the k-phase saturation; t is time, s; tₘₐₓ is the maximum of time, s; pₖ is the k-phase pressure, Pa; lₖ is the k-phase initial saturation distribution function; qₖ is the source/sink term of k-phase, kg/(m³·s); ƒₖ is the k-phase initial pressure distribution function, Pa; K_{iαβ} is the phase equilibrium constant of component i in α and δ phase, dimensionless; Cᵢₖ is the mole percent of component i in k-phase, dimensionless; Dᵢₖ is the diffusion coefficient of component i in k-phase, m²/s; Zᵢ is the total mole percent of component i, dimensionless; [symbol] is the ratio of k-phase to the whole system, dimensionless; gₖ is the boundary functions of k-phase on reservoir boundary, dimensionless; w is boundary function of temperature on reservoir boundary, dimensionless; τ is the initial temperature distribution function of reservoirs, K; pcαβ is the capillary pressure at α-β phase interface, Pa; Ω is reservoir space; ∂Ω is reservoir boundary including internal boundary and outer boundary; c_{k,1} is the pressure term coefficients of k-phase on reservoir boundary, 1/Pa; c_{k,2} is the k-phase coefficients of derivative terms along the outer normal direction on reservoir boundary condition, s/m; d₁ is the temperature term coefficient on reservoir boundary, 1/K; d₂ is temperature coefficients of derivative terms along the outer normal direction on reservoir boundary condition, s·m²/J; κ is coefficient of the thermal conductivity, J/(m·s·K); n^{∂Ω} is the outer normal direction on reservoir boundary, m; ∇ is the Hamilton operator; ∂ is the partial derivative sign;
S24: The analytical solution algorithms of above multi-component multi-phase flow simulation equations include direct solving method, Laplace transformation, Fourier transformation, and orthogonal transformation method Their numerical methods include finite difference method, finite volume method, boundary element method, and finite element method; After solving, the pressure, temperature, and saturation in multi-phase flow are obtained, including the pressure, temperature, saturation, and mole percent of each component in each phase at any time and at any position in the study area.

4. The flow simulation and transient well analysis method based on generalized tube flow and percolation coupling as claimed according to claim 1, characterized in that the details of step S3 is as follows:
S31: The application software described above includes 5 main parts: data pre-processing system, numerical simulation system, analytical analysis system, and analysis results output system, data input and output management system. Its analysis process includes reservoir definition, setting of initial and boundary conditions, wellbore and fracture setting, numerical simulator selection or fluid type and composition setting, generalized mobility model definition, grid design of numerical simulation, wellbore storage model setting, flow period and regime definition, coordinate transformation, setting of models and their type curve analysis, parameter adjustment and history matching, dynamic prediction;
S32: The application software described above can be used for single and multi-well flow simulation of complex multi-component multi-phase flow reservoirs, multi-well interference analysis, deliverability analysis, transient pressure analysis, transient rate analysis, transient temperature analysis, well test design, and permanent downhole monitoring data analysis. The complex multi-component multi-phase flow reservoirs mentioned above include all types of fluid reservoirs, oil and gas reservoirs with fluid injection, underground gas storage, ground water reservoirs, and geothermal reservoirs.
